(19) United States
(12) Patent Application Publication
(10) Pub. No.: US 2026/0173877 A1
(43) Pub. Date: Jun. 18, 2026

(54) VAPOR CHAMBER, ELECTRONIC APPARATUS AND BODY SHEET FOR VAPOR CHAMBER

(71) Applicant: DAI NIPPON PRINTING CO., LTD., Tokyo-to (JP)

(72) Inventors: Takayuki OTA, Tokyo-to (JP); Toshihiko TAKEDA, Tokyo-to (JP); Shinya KIURA, Tokyo-to (JP); Kazunori ODA, Tokyo-to (JP); Makoto YAMAKI, Tokyo-to (JP); Takayuki TERAUCHI, Tokyo-to (JP); Naohiro TAKAHASHI, Tokyo-to (JP); Shinichiro TAKAHASHI, Tokyo-to (JP); Youji KOZURU, Tokyo-to (JP)

(73) Assignee: DAI NIPPON PRINTING CO., LTD., Tokyo-to (JP)

(21) Appl. No.: 18/707,906

(22) PCT Filed: Nov. 11, 2022
(86) PCT No.: PCT/JP2022/042105

§ 371 Date: Aug. 22, 2024

(30) Foreign Application Priority Data
Nov. 12, 2021 (JP) 2021-185161
Dec. 6, 2021 (JP) 2021-198039
Dec. 16, 2021 (JP) 2021-204523
Dec. 22, 2021 (JP) 2021-208635
Feb. 25, 2022 (JP) 2022-028635
Sep. 30, 2022 (WO) PCT/JP2022/036767

(51) Int. Cl. H10W 40/73

(52) U.S. Cl. CPC H10W 40/73

(57) ABSTRACT

A plurality of first grooves located in a land part of a vapor chamber according to the present disclosure include a plurality of main flow grooves extending in a first direction, and a plurality of communication grooves extending in a direction different from the first direction. Communication-groove rows each include communication grooves arrayed in the first direction. The communication-groove rows located in the land part include an adjacent communication-groove row. The adjacent communication-groove row includes the communication grooves that provide communication between a space part and one of the main flow grooves that is adjacent to the space part. The adjacent communication-groove row includes a low-density region, and a high-density region in which a unit communication-groove count is greater than the unit communication-groove count in the low-density region. The high-density region of the adjacent communication-groove row is located in a bend region, and overlaps a bend line.

### TECHNICAL FIELD

The present disclosure relates to a vapor chamber, an electronic apparatus, and a body sheet for a vapor chamber.

### BACKGROUND ART

Electronic apparatuses such as mobile terminals employ electronic devices that are prone to heat generation. Examples of the electronic devices include a central processing unit (CPU), a light-emitting diode (LED), and a power semiconductor. Examples of the mobile terminals include a portable terminal, and a tablet terminal.

Such an electronic device is cooled by a heat dissipation device such as a heat pipe. Recent years have seen increasing demand for thinner heat dissipation devices to achieve thinner electronic apparatuses. This had led to the ongoing development of vapor chambers, which are heat dissipation devices that can be made thinner than heat pipes. In such a vapor chamber, a working fluid sealed within the vapor chamber absorbs heat from the electronic device, and diffuses the absorbed heat inside the vapor chamber to thereby efficiently cool the electronic device.

More specifically, the working liquid within the vapor chamber receives heat at a location (evaporation part) proximate to the electronic device. Upon receiving the heat, the working liquid evaporates into a working vapor. Within a vapor channel part defined within the vapor chamber, the working vapor is diffused away from the evaporation part. The diffused working vapor is then cooled to condense into a working liquid. The vapor chamber includes a liquid channel part defined therein. The liquid channel part serves as a capillary structure (wick). The working liquid is transported through the liquid channel part toward the evaporation part. Once transported to the evaporation part, the working liquid receives heat and evaporates again in the evaporation part. As the working fluid undergoes refluxing within the vapor chamber while repeating phase changes, that is, evaporation and condensation as described above, the working fluid diffuses the heat from the electronic device. This results in improved heat dissipation efficiency of the vapor chamber.

A vapor chamber may undergo bending in some cases, depending on the internal structure of an electronic apparatus into which the vapor chamber is to be incorporated. In such cases, the vapor channel becomes bent, and thus the vapor channel tends to collapse. This results in increased channel resistance, and consequently impedes the flow of the working vapor within the vapor channel part.

### CITATION LIST

### Patent Literature

PTL 1: Japanese U.S. Pat. No. 6,877,513

PTL 2: Japanese Patent Laid-Open No. 2018-204841

### SUMMARY OF INVENTION

### Technical Problem

An object of the present disclosure is to provide a vapor chamber that can exhibit improved heat dissipation efficiency even in its bent state, an electronic apparatus, and a body sheet for a vapor chamber.

### Solution to Problem

[1] According to the present disclosure, there may be provided a vaper chamber in which a working fluid is sealed, the vapor chamber including:
   a body sheet including a first body face and a second body face, the second body face being located opposite from the first body face;
   a first sheet located on the first body face of the body sheet;
   a second sheet located on the second body face of the body sheet;
   a space part disposed in the body sheet, the space part being covered by the first sheet and the second sheet; and
   a plurality of first grooves communicating with the space part,
   in which the body sheet includes a land part, the land part being located within the space part and extending in a first direction,
   in which the first grooves are located in the first body face of the land part,
   in which the first grooves include
      a plurality of main flow grooves extending in the first direction, and
      a plurality of communication grooves communicating with the main flow grooves and extending in a direction different from the first direction,
   in which the land part is provided with a plurality of communication-groove rows sectioned off by the main flow grooves, the communication-groove rows each including the communication grooves arrayed in the first direction,
   in which the communication-groove rows located in the land part include an adjacent communication-groove row, the adjacent communication-groove row including the communication grooves that provide communication between the space part and one of the main flow grooves that is adjacent to the space part,
   in which a unit communication-groove count is defined as a number of the communication grooves per unit length in the first direction,
   in which the adjacent communication-groove row includes
      a low-density region, and
      a high-density region in which the unit communication-groove count is greater than the unit communication-groove count in the low-density region,
   in which the vapor chamber includes a bend region bent along a bend line, the bend line extending in a direction crossing the first direction in plan view, and
   in which the high-density region of the adjacent communication-groove row is located in the bend region, and overlaps the bend line.
[2] According to the present disclosure, there may be provided the vapor chamber according to Item [1];
   in which the low-density region is located to each side of the high-density region in the first direction.
[3] According to the present disclosure, there may be provided the vapor chamber according to Item [1] or [2],
   in which the communication-groove rows include an intermediate communication-groove row, the intermediate communication-groove row including the communication grooves each communicating with two mutually adjacent main flow grooves of the main flow grooves,
   in which the intermediate communication-groove row includes the low-density region, and the high-density region, and
   in which the high-density region of the intermediate communication-groove row is located in the bend region, and overlaps the bend line.
[4] According to the present disclosure, there may be provided the vapor chamber according to item [1] or [2],
   in which the communication-groove rows include an intermediate communication-groove row, the intermediate communication-groove row including the communication grooves each communicating with two mutually adjacent main flow grooves of the main flow grooves,
   in which the intermediate communication-groove row includes the low-density region, and
   in which the low-density region of the intermediate communication-groove row is located in the bend region, and overlaps the bend line.
[5] According to the present disclosure, there may be provided the vapor chamber according to any one of Items [1] to [4],
   in which two mutually adjacent communication-groove rows of the communication-groove rows are defined as a first communication-groove row and a second communication-groove row,
   in which in the high-density region, each of the communication grooves of the first communication-groove row is positioned on an extension of a corresponding one of the communication grooves of the second communication-groove row, and
   in which in the low-density region, each of the communication grooves of the first communication-groove row is positioned offset relative to an extension of each of the communication grooves of the second communication-groove row.
[6] According to the present disclosure, there may be provided the vapor chamber according to any one of Items [1] to [5],
   in which in the low-density region, the communication grooves extend in a direction orthogonal to the first direction, and
   in which in the high-density region, the communication grooves extend in a direction inclined relative to the first direction.
[7] According to the present disclosure, there may be provided the vapor chamber according to any one of Items [1] to [6],
   in which the bend line extends in a direction orthogonal to the first direction.
[8] According to the present disclosure, there may be provided the vapor chamber according to any one of Items [1] to [6],
   in which the bend line extends in a direction inclined relative to the first direction.
[9] According to the present disclosure, there may be provided a vaper chamber in which a working fluid is sealed, the vapor chamber including:
   a body sheet including a first body face and a second body face, the second body face being located opposite from the first body face;
   a first sheet located on the first body face of the body sheet;
   a second sheet located on the second body face of the body sheet;
   a space part disposed in the body sheet, the space part being covered by the first sheet and the second sheet; and
   a plurality of first grooves communicating with the space part,
   in which the body sheet includes a land part, the land part being located within the space part and extending in a first direction,
   in which the first grooves are located in the first body face of the land part,
   in which the first grooves include
      a plurality of main flow grooves extending in the first direction, and
      a plurality of communication grooves communicating with the main flow grooves and extending in a direction different from the first direction,
   in which the land part is provided with a plurality of communication-groove rows sectioned off by the main flow grooves, the communication-groove rows each including the communication grooves arrayed in the first direction,
   in which the communication-groove rows located in the land part include an adjacent communication-groove row, the adjacent communication-groove row including the communication grooves that provide communication between the space part and one of the main flow grooves that is adjacent to the space part,
   in which a unit communication-groove count is defined as a number of the communication grooves per unit length in the first direction,
   in which the adjacent communication-groove row includes
      a low-density region, and
      a high-density region in which the unit communication-groove count is greater than the unit communication-groove count in the low-density region, and
   in which the high-density region of the adjacent communication-groove row is arranged along a direction crossing the first direction.
[10] According to the present disclosure, there may be provided a body sheet for a vapor chamber, the vapor chamber being a vapor chamber in which a working fluid is sealed, the body sheet including:
   a first body face;
   a second body face located opposite from the first body face;
   a space part extending from the first body face to the second body face;
   a land part located within the space part and extending in a first direction; and
   a plurality of first grooves located in the first body face of the land part, the first grooves communicating with the space part,
   in which the first grooves include
      a plurality of main flow grooves extending in the first direction, and
      a communication groove communicating with the main flow grooves and extending in a direction different from the first direction,
   in which the land part is provided with a plurality of communication-groove rows sectioned off by the main flow grooves, the communication-groove rows each including a plurality of the communication grooves arrayed in the first direction,
   in which the communication groove rows located in the land part include an adjacent communication-groove row, the adjacent communication-groove row including the communication grooves that provide communication between the space part and one of the main flow grooves that is adjacent to the space part,
   in which a unit communication-groove count is defined as a number of the communication grooves per unit length in the first direction,
   in which the adjacent communication-groove row includes
      a low-density region, and
      a high-density region in which the unit communication-groove count is greater than the unit communication-groove count in the low-density region, and
   in which the high-density region of the adjacent communication-groove row is arranged along a direction crossing the first direction.
[11] According to the present disclosure, there may be provided a vaper chamber in which a working fluid is sealed, the vapor chamber including:
   a body sheet including
      a first body face,
      a second body face opposite from the first body face, and
      a first-body recess disposed in the first body face;
   a first sheet that is stacked on the first body face; and
   a bend part where the body sheet and the first sheet are bent,
   in which the first-body recess includes
      a first opening part provided at the first body face, and
      an inner part located closer to the second body face than is the first opening part,
   in which the first-body recess is disposed at least in the bend part, and
   in which in cross-sectional view taken at the bend part, the first-body recess increases in width with increasing distance from the first opening part toward the inner part.
[12] According to the present disclosure, there may be provided the vapor chamber according to Item [11],
   in which in cross-sectional view, the first-body recess includes a first boundary edge, the first boundary edge extending from the first opening part to the inner part, and
   in which in the bend part, the first boundary edge is curved toward an outside of the first-body recess.
[13] According to the present disclosure, there may be provided the vapor chamber according to Item [11] or [12], including
   a second sheet that is stacked on the second body face,
   in which the body sheet includes a second body recess disposed in the second body face,
   in which the second-body recess includes a second opening part provided at the second body face, and
   in which the first-body recess and the second-body recess are connected at the inner part and communicate with each other.
[14] According to the present disclosure, there may be provided the vapor chamber according to Item [13],
   in which in cross-sectional view taken at the bend part, the second-body recess increases in width with increasing distance from the second opening part toward the inner part.
[15] According to the present disclosure, there may be provided the vapor chamber according to Item [14],
   in which in cross-sectional view taken at the bend part, the second-body recess includes a second boundary edge, the second boundary edge extending from the second opening part to the inner part, and
   in which in the bend part, the second boundary edge is curved toward an outside of the second-body recess.
[16] According to the present disclosure, there may be provided the vapor chamber according to Item [14] or [15],
   in which the first-body recess is disposed also at a location different from the bend part, and
   in which in cross-sectional view taken at the location different from the bend part, the first-body recess increases in width with increasing distance from the first opening part toward the inner part, and the second-body recess decreases in width with increasing distance from the second opening part toward the inner part.
[17] According to the present disclosure, there may be provided the vapor chamber according to Item [14] or [15],
   in which the first-body recess is disposed also at a location different from the bend part, and
   in which in cross-sectional view taken at the location different from the bend part, the first-body recess decreases in width with increasing distance from the first opening part toward the inner part, and the second-body recess decreases in width with increasing distance from the second opening part toward the inner part.
[18] According to the present disclosure, there may be provided a body sheet for a vapor chamber, the vapor chamber being a vapor chamber in which a working fluid is sealed, the body sheet including:
   a first body face;
   a second body face located opposite from the first body face;
   a first body recess disposed in the first body face; and
   a second body recess disposed in the second body face,
   in which the first-body recess includes
      a first opening part provided at the first body face, and
      an inner part located closer to the second body face than is the first opening part,
   in which the second-body recess includes a second opening part provided at the second body face,
   in which the first-body recess and the second-body recess are connected at the inner part and communicate with each other, and
   in which in cross-sectional view, the first-body recess increases in width with increasing distance from the first opening part toward the inner part, and the second-body recess decreases in width with increasing distance from the second opening part toward the inner part.
[19] According to the present disclosure, there may be provided the body sheet for a vapor chamber according to Item [18],
   in which in cross-sectional view, the first-body recess includes a first boundary edge, the first boundary edge extending from the first opening part to the inner part, and
   in which the first boundary edge is curved toward an outside of the first-body recess.
[20] According to the present disclosure, there may be provided the body sheet for a vapor chamber according to Item [18] or [19],
   in which in cross-sectional view, the second-body recess includes a second boundary edge, the second boundary edge extending from the second opening part to the inner part, and
   in which the second boundary edge is curved toward an outside of the second-body recess.
[21] According to the present disclosure, there may be provided a vapor chamber including:
   the body sheet for a vapor chamber according to any one of Items [18] to [20],
   a first sheet that is stacked on the first body face; and
   a second sheet that is stacked on the second body face.
[22] According to the present disclosure, there may be provided the vapor chamber according to Item [21],
   in which the vapor chamber includes a bend part where the body sheet, the first sheet, and the second sheet are bent,
   in which the first-body recess and the second-body recess are disposed at least in the bend part, and
   in which in cross-sectional view taken at the bend part, the first-body recess increases in width with increasing distance from the first opening part toward the inner part, and the second-body recess decreases in width with increasing distance from the second opening part toward the inner part.
[23] According to the present disclosure, there may be provided the vapor chamber according to Item [22],
   in which the first-body recess and the second-body recess are disposed also at a location different from the bend part, and
   in which in cross-sectional view taken at the location different from the bend part, the first-body recess decreases in width with increasing distance from the first opening part toward the inner part, and the second-body recess decreases in width with increasing distance from the second opening part toward the inner part.
[24] According to the present disclosure, there may be provided a vaper chamber in which a working fluid is sealed, the vapor chamber including:
   a body sheet including a first body face and a second body face, the second body face being located opposite from the first body face;
   a first sheet located on the first body face of the body sheet;
   a second sheet located on the second body face of the body sheet; and
   a space part disposed in the body sheet, the space part being covered by the first sheet and the second sheet,
   in which the body sheet includes a plurality of land parts, the land parts being located within the space part and extending in a first direction,
   in which the space part includes a plurality of working fluid passages, the working fluid passages being each defined between two mutually adjacent land parts of the land parts,
   in which each of the working fluid passages is provided with a reinforcement part, the reinforcement part extending in a thickness direction of the body sheet from the first sheet to the second sheet,
   in which the vapor chamber includes a bend region bent along a bend line, the bend line extending in a direction crossing the first direction in plan view, and
   in which the reinforcement parts are located in the bend region, and arranged along the bend line.
[25] According to the present disclosure, there may be provided the vapor chamber according to Item [24],
   in which the reinforcement part includes a protrusion protruding from one land part of two of the land parts in a width direction of the one land part, the two of the land parts being two land parts that define each of the working fluid passages.
[26] According to the present disclosure, there may be provided the vapor chamber according to Item [24],
   in which the reinforcement part includes a protrusion protruding from each of two of the land parts in a width direction of the land part, the two of the land parts being two land parts that define each of the working fluid passages.
[27] According to the present disclosure, there may be provided the vapor chamber according to Item [25] or [26],
   in which the reinforcement part includes a plurality of the protrusions spaced apart from each other in the first direction.
[28] According to the present disclosure, there may be provided the vapor chamber according to any one of Items [25] to [27], including
   a plurality of first grooves located in the first body face of each of the land parts and communicating with the space part,
   in which the protrusion is defined by the first body face and the second body face, and constitutes the body sheet, and
   in which a plurality of second grooves are located in the first body face of the protrusion, the second grooves communicating with the space part and the first grooves.
[29] According to the present disclosure, there may be provided the vapor chamber according to Item [24],
   in which the reinforcement part includes a reinforcement land part spaced apart from each of the land parts.
[30] According to the present disclosure, there may be provided the vapor chamber according to Item [29],
   in which the reinforcement part includes a plurality of the reinforcement land parts.
[31] According to the present disclosure, there may be provided the vapor chamber according to any one of Items [24] to [30],
   in which the bend line extends in a direction orthogonal to the first direction.
[32] According to the present disclosure, there may be provided the vapor chamber according to any one of Items [24] to [30],
   in which the bend line extends in a direction inclined relative to the first direction.
[33] According to the present disclosure, there may be provided a vaper chamber in which a working fluid is sealed, the vapor chamber including:
   a body sheet including a first body face and a second body face, the second body face being located opposite from the first body face;
   a first sheet located on the first body face of the body sheet;
   a second sheet located on the second body face of the body sheet; and
   a space part disposed in the body sheet, the space part being covered by the first sheet and the second sheet,
   in which the vapor chamber is sectioned into a first region, a second region, and a reinforcement region, the reinforcement region being located between the first region and the second region,
   in which the body sheet includes a plurality of land parts located within the space part, the land parts extending in a first direction from the first region to the second region via the reinforcement region,
   in which the space part includes a plurality of working fluid passages, the working fluid passages being each defined between two mutually adjacent land parts of the land parts,
   in which each of the working fluid passages is provided with a reinforcement part, the reinforcement part extending in a thickness direction of the body sheet from the first sheet to the second sheet, and
   in which the reinforcement parts are located in the reinforcement region, and arranged along a direction crossing the first direction.
[34] According to the present disclosure, there may be provided the vapor chamber according to Item [33],
   in which the vapor chamber is sectioned into a first region, a second region, and a reinforcement region, the reinforcement region being located between the first region and the second region, and
   in which the reinforcement part is located in the reinforcement region.
[35] According to the present disclosure, there may be provided the vapor chamber according to Item [34],
   in which the reinforcement region at least partially overlaps a bend region where the vapor chamber is bent along a bend line, the bend line extending in a direction crossing the first direction in plan view.
[36] According to the present disclosure, there may be provided a body sheet for a vapor chamber, the vapor chamber being a vapor chamber in which a working fluid is sealed, the body sheet including:
   a first body face;
   a second body face located opposite from the first body face;
   a space part extending from the first body face to the second body face; and
   a plurality of land parts located within the space part and extending in a first direction,
   in which the space part includes a plurality of working fluid passages, the working fluid passages being each defined between two mutually adjacent land parts of the land parts,
   in which each of the working fluid passages is provided with a reinforcement part, the reinforcement part extending in a thickness direction of the body sheet from the first body face to the second body face, and
   in which the reinforcement parts are arranged along a direction crossing the first direction.
[37] According to the present disclosure, there may be provided an electronic apparatus including:
   a housing;
   a device contained in the housing; and
   the vapor chamber according to any one of Items [1] to [9], [11] to [17], and [21] to [35], the vapor chamber being in thermal contact with the device.

### Advantageous Effects of Invention

The present disclosure allows the vapor chamber to exhibit improved heat dissipation efficiency even when bent.

### BRIEF DESCRIPTION OF DRAWINGS

FIG. 1 is a schematic perspective view of an electronic apparatus according to a first embodiment of the present disclosure.

FIG. 2 schematically illustrates an example of a vapor chamber according to the first embodiment that is incorporated in the electronic apparatus illustrated in FIG. 1.

FIG. 3 schematically illustrates another example of the vapor chamber according to the first embodiment that is incorporated in the electronic apparatus illustrated in FIG. 1.

FIG. 4 is an outline perspective view of the vapor chamber according to the first embodiment of the present disclosure.

FIG. 5 is a plan view of the vapor chamber illustrated in FIG. 2 in its pre-bending state.

FIG. 6 is a cross-section taken along a line A-A of FIG. 5.

FIG. 7 is a plan view of an inner face of a first sheet illustrated in FIG. 6.

FIG. 8 is a plan view of an inner face of a second sheet illustrated in FIG. 6.

FIG. 9 is a plan view of a first body face of a wick sheet illustrated in FIG. 6.

FIG. 10 is a plan view of a second body face of the wick sheet illustrated in FIG. 6.

FIG. 11 is a partial enlarged cross-section of FIG. 6, which is taken along a line B-B of FIG. 13A (described later).

FIG. 12 is a partial enlarged view of a liquid channel part illustrated in FIG. 9.

FIG. 13A is an enlarged plan view of a reinforcement part of a vapor chamber illustrated in FIG. 9.

FIG. 13B is an enlarged plan view of a modification of the reinforcement part illustrated in FIG. 13A.

FIG. 13C is an enlarged plan view of another modification of the reinforcement part illustrated in FIG. 13A.

FIG. 14 is a cross-section taken along a line C-C of FIG. 13A.

FIG. 15 is a diagrammatic cross-section of a bend region of the vapor chamber illustrated in FIG. 4.

FIG. 16A is an enlarged plan view of another modification of the reinforcement part illustrated in FIG. 13A.

FIG. 16B is an enlarged plan view of another modification of the reinforcement part illustrated in FIG. 13A.

FIG. 16C is an enlarged plan view of another modification of the reinforcement part illustrated in FIG. 13A.

FIG. 16D is an enlarged plan view of another modification of the reinforcement part illustrated in FIG. 13A.

FIG. 17A illustrates, in cross-section, a modification of the configuration illustrated in FIG. 14.

FIG. 17B illustrates, in cross-section, another modification of the configuration illustrated in FIG. 14.

FIG. 17C is an enlarged plan view of a bridge part illustrated in FIG. 17B.

FIG. 18 is an outline perspective view of a vapor chamber according to a second embodiment of the present disclosure.

FIG. 19 is a plan view of the vapor chamber illustrated in FIG. 18 in its pre-bending state.

FIG. 20 is an enlarged plan view of a reinforcement part of the vapor chamber illustrated in FIG. 19.

FIG. 21 is an enlarged plan view of a reinforcement part of a vapor chamber according to a third embodiment of the present disclosure.

FIG. 22 is a cross-section taken along a line D-D of FIG. 21.

FIG. 23 is a cross-section taken along a line E-E of FIG. 21.

FIG. 24A is an enlarged plan view of a modification of the reinforcement part illustrated in FIG. 21.

FIG. 24B is an enlarged plan view of another modification of the reinforcement part illustrated in FIG. 21.

FIG. 25A is an enlarged plan view of another modification of the reinforcement part illustrated in FIG. 21.

FIG. 25B is an enlarged plan view of another modification of the reinforcement part illustrated in FIG. 21.

FIG. 25C is an enlarged plan view of another modification of the reinforcement part illustrated in FIG. 21.

FIG. 26 illustrates, in cross-section, a modification of the configuration illustrated in FIG. 22.

FIG. 27A illustrates, in cross-section, another modification of the configuration illustrated in FIG. 22.

FIG. 27B illustrates, in cross-section, another modification of the configuration illustrated in FIG. 22.

FIG. 28 is an outline perspective view of a vapor chamber according to a fourth embodiment of the present disclosure.

FIG. 29 is a plan view of the vapor chamber illustrated in FIG. 28 in its pre-bending state.

FIG. 30 is a plan view of a first body face of a wick sheet of the vapor chamber illustrated in FIG. 29.

FIG. 31 is a plan view of a second body face of the wick sheet of the vapor chamber illustrated in FIG. 29.

FIG. 32 is a partial enlarged view of a liquid channel part illustrated in FIG. 30.

FIG. 33 is a diagrammatic cross-section of a bend region of the vapor chamber illustrated in FIG. 28.

FIG. 34A is a partial enlarged view of a modification of the liquid channel part illustrated in FIG. 32.

FIG. 34B is a cross-section taken along a line F-F of FIG. 34A.

FIG. 34C is a cross-section taken along a line G-G of FIG. 34A.

FIG. 35 is a partial enlarged view of another modification of the liquid channel part illustrated in FIG. 32.

FIG. 36A is a partial enlarged view of another modification of the liquid channel part illustrated in FIG. 32.

FIG. 36B is a partial enlarged view of another modification of the liquid channel part illustrated in FIG. 32.

FIG. 37A is a partial enlarged view of another modification of the liquid channel part illustrated in FIG. 32.

FIG. 37B is a partial enlarged view of another modification of the liquid channel part illustrated in FIG. 32.

FIG. 38 is an outline perspective view of a vapor chamber according to a fifth embodiment of the present disclosure.

FIG. 39 is a plan view of the vapor chamber illustrated in FIG. 38 in its pre-bending state.

FIG. 40 is a plan view of a first body face of a wick sheet illustrated in FIG. 39.

FIG. 41 is a partial enlarged view of a liquid channel part illustrated in FIG. 40.

FIG. 42 is a partial enlarged view of a modification of the liquid channel part illustrated in FIG. 41.

FIG. 43 is a plan view of a modification of the vapor chamber illustrated in FIG. 39 in its pre-bending state.

FIG. 44 is a top view of a vapor chamber according to a sixth embodiment of the present disclosure.

FIG. 45 is a cross-section taken along a line H-H of FIG. 44.

FIG. 46 is a top view of a lower sheet illustrated in FIG. 45.

FIG. 47 is a bottom view of an upper sheet illustrated in FIG. 45.

FIG. 48 is a top view of a body sheet illustrated in FIG. 45.

FIG. 49 is a partial enlarged cross-section of FIG. 45.

FIG. 50 is a partial enlarged top view of a liquid channel part illustrated in FIG. 49.

FIG. 51 illustrates a material-sheet preparing step of a method for manufacturing the vapor chamber according to the sixth embodiment of the present disclosure.

FIG. 52 illustrates a resist-pattern forming step of the method for manufacturing the vapor chamber according to the sixth embodiment of the present disclosure.

FIG. 53 illustrates an etching step of the method for manufacturing the vapor chamber according to the sixth embodiment of the present disclosure.

FIG. 54 illustrates a resist-pattern removing step of the method for manufacturing the vapor chamber according to the sixth embodiment of the present disclosure.

FIG. 55 illustrates a bonding step of the method for manufacturing the vapor chamber according to the sixth embodiment of the present disclosure.

FIG. 56A is a partial enlarged cross-section of a modification of a vapor channel part illustrated in FIG. 49.

FIG. 56B is a partial enlarged cross-section of another modification of the vapor channel part illustrated in FIG. 49.

FIG. 56C is a partial enlarged cross-section of another modification of the vapor channel part illustrated in FIG. 49.

FIG. 56D is a cross-section of a modification of a vapor channel part illustrated in FIG. 45.

FIG. 56E is a cross-section of another modification of the vapor channel part illustrated in FIG. 45.

FIG. 57 is a cross-section of another modification of the vapor channel part illustrated in FIG. 45.

FIG. 58 is a partial enlarged cross-section of FIG. 57.

FIG. 59 is a top view of a modification of the vapor chamber illustrated in FIG. 44.

FIG. 60 is a perspective view of a vapor chamber bent along a bend line illustrated in FIG. 59.

FIG. 61 illustrates an exemplary cross-section of the vapor chamber illustrated in FIG. 60, taken at a location different from a bend part.

FIG. 62 is a partial enlarged cross-section of FIG. 61.

FIG. 63A is an illustration for explaining an example of a vapor channel recess of the vapor chamber illustrated in FIG. 60.

FIG. 63B is an illustration for explaining another example of the vapor channel recess of the vapor chamber illustrated in FIG. 60.

FIG. 64 is a cross-section of a modification of the vapor channel part illustrated in FIG. 45.

FIG. 65 is a partial enlarged cross-section of FIG. 64.

### DESCRIPTION OF EMBODIMENTS

Embodiments of the present disclosure are described below with reference to the drawings. In the accompanying drawings, for ease of illustration and understanding, the scales, the horizontal-to-vertical dimensional ratios, and other details in the drawings are changed and exaggerated from the actual ones.

As used herein, geometric conditions, physical characteristics, terms specifying the degree or extent of geometric conditions or physical characteristics, numerical values representing geometric conditions or physical characteristics, and other similar references may be interpreted without being bound by their strict meanings. Such geometric conditions, physical characteristics, terms, numerical values, and other similar references may be interpreted to include a range such that similar or equivalent functions may be expected. Examples of terms specifying geometric conditions include “length”, “angle”, “shape”, and “arrangement.” Examples of terms specifying geometric conditions include “parallel”, “orthogonal”, and “same.” Further, for the clarity of the drawings, a plurality of parts or portions that may be expected to have similar functions are depicted as being shaped regularly. However, the shapes of such portions or parts may, without being bound by their strict meanings, differ from each other, insofar as the above-mentioned functions may be expected. In the drawings, each boundary line representing the bonding face between components or other features is indicated by a simple straight line. However, such a boundary line may, without being bound to a strictly straight line, have any shape, insofar as desired bond performance can be expected.

### First Embodiment

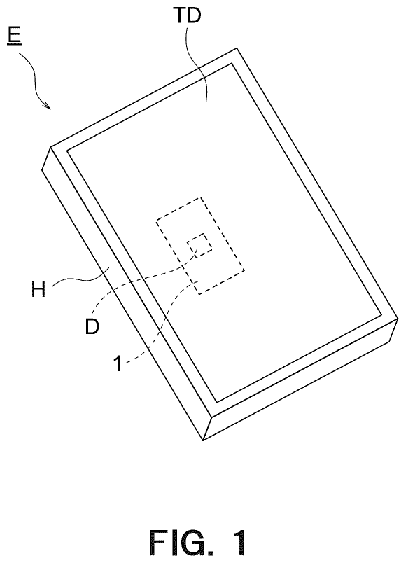

A vapor chamber, an electronic apparatus, and a body sheet for a vapor chamber according to a first embodiment of the present disclosure are described below with reference to FIGS. 1 to 17C. A vapor chamber 1 according to the first embodiment is contained in a housing H of an electronic apparatus E together with an electronic device D that is prone to heat generation. The vapor chamber 1 serves to cool the electronic device D. Examples of the electronic apparatus E include a mobile terminal, such as a portable terminal or a tablet terminal. Examples of the electronic device D include a central processing unit (CPU), a light-emitting diode (LED), and a power semiconductor. The electronic device D will be sometimes also referred to as a device to be cooled.

Reference is first made to a tablet terminal, which is an example of the electronic apparatus E in which the vapor chamber 1 according to the first embodiment is incorporated. As illustrated in FIG. 1, the electronic apparatus E may include the housing H, the electronic device D contained in the housing H, and the vapor chamber 1. The electronic apparatus E illustrated in FIG. 1 includes a touchscreen display TD on the front of the housing H. The vapor chamber 1 is contained in the housing H, and disposed in thermal contact with the electronic device D. The vapor chamber 1 receives heat that the electronic device D generates when the electronic apparatus E is in use. The heat received by the vapor chamber 1 is released out of the vapor chamber 1 via working fluids 2a and 2b (described later). The electronic device D is thus effectively cooled. If the electronic apparatus E is a tablet terminal, the electronic device D corresponds to, for example, a central processing unit.

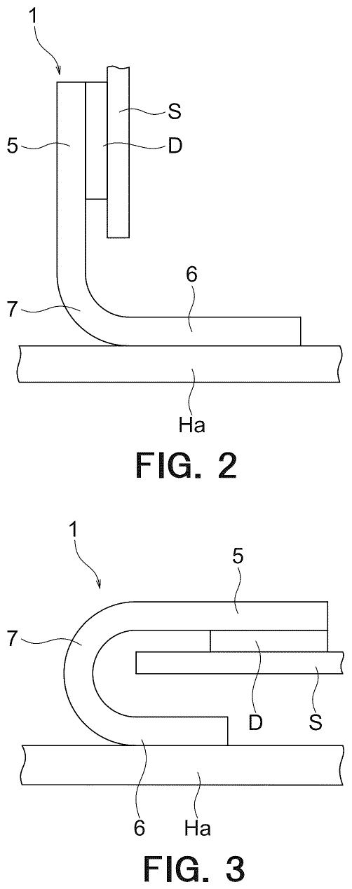

Reference is now made to the vapor chamber 1 according to the first embodiment. The vapor chamber 1 according to the first embodiment is bent as illustrated in FIGS. 2 and 3. The vapor chamber 1 is bent in accordance with the internal structure of the electronic apparatus E. Depending the positional relationship between the electronic apparatus E that is prone to heat generation, and a housing component Ha that releases heat, the vapor chamber 1 may undergo bending in some cases. The housing component Ha is a component constituting the housing H.

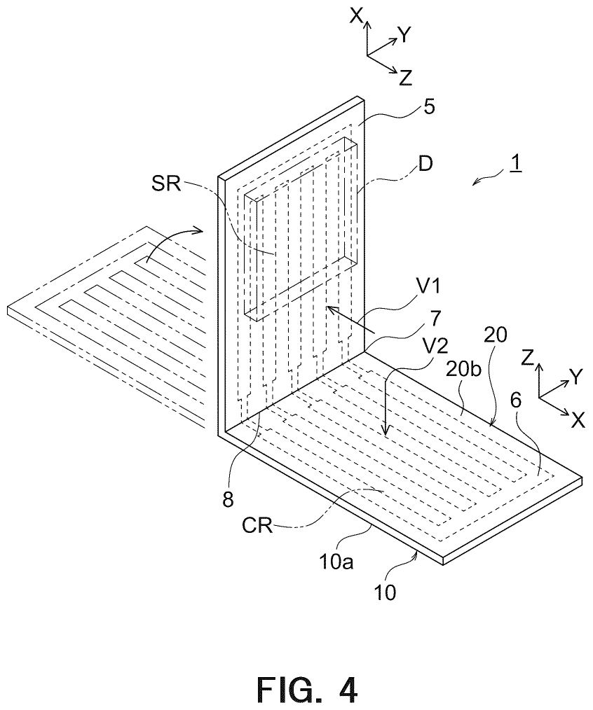

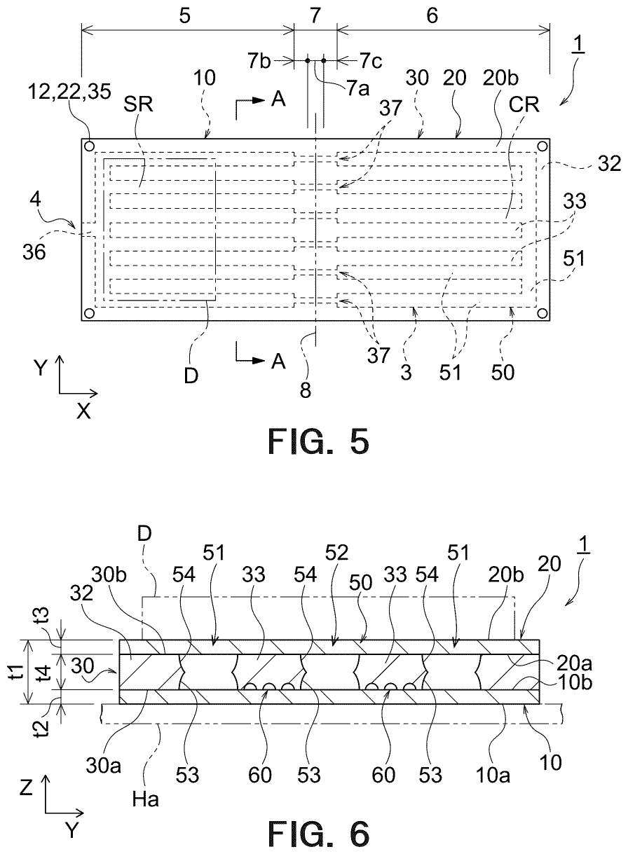

By way of one example, reference is made to a case where the electronic device D and the housing component Ha are disposed as illustrated in FIG. 2. In this case, the vapor chamber 1 is bent at substantially right angles such that the vapor chamber 1 is in contact with the electronic device D and the housing component Ha. More specifically, a bend region 7a (described later) is in the shape of a quarter-circular arc. The electronic device D is mounted to a substrate S. By way of another example, reference is made to a case where the electronic device D and the housing component Ha are disposed as illustrated in FIG. 3. In this case, the vapor chamber 1 is bent at 180 degrees such that the vapor chamber 1 is in contact with the electronic device D and the housing component Ha. More specifically, the bend region 7a is in the shape of a semi-circular arc. Although FIGS. 2 and 3 each depict an example in which the vapor chamber 1 is bent along a single bend line 8 (see FIGS. 4 and 5), this is not intended to be limiting. The vapor chamber 1 may be bent along two or more bend lines 8, that is, at different positions.

The following description of the first embodiment is directed to an example of the vapor chamber 1 that is bent at substantially right angles along a single bend line 8 as illustrated in FIG. 4. The vapor chamber 1 illustrated in FIG. 4 is sectioned into a first region 5, a second region 6, and a reinforcement region 7. The reinforcement region 7 is located between the first region 5 and the second region 6. The reinforcement region 7 according to the first embodiment may include the bend region 7a. In the bend region 7a, the vapor chamber 1 is bent at substantially right angles. The first region 5 and the second region 6 each have a substantially flat shape. The electronic device D may be in contact with the first region 5, and the housing component Ha (see FIG. 2) may be in contact with the second region 6. Detailed description of these individual regions will be given later.

Now, the configuration of the vapor chamber 1 is first described with reference to FIGS. 5 to 11, which illustrate the vapor chamber 1 in its pre-bending state. The vapor chamber 1 in the form of a flat plate illustrated in FIG. 5 is bent to obtain the vapor chamber 1 illustrated in FIG. 4.

As illustrated in FIGS. 5 and 6, the vapor chamber 1 includes a hermetically sealed space 3 with the working fluids 2a and 2b sealed therein. As the working fluids 2a and 2b within the hermetically sealed space 3 undergo repeated phase changes, the electronic device D mentioned above is cooled. Examples of the working fluids 2a and 2b include pure water, ethanol, methanol, acetone, and liquid mixtures thereof.

As illustrated in FIGS. 5 and 6, the vapor chamber 1 includes a first sheet 10, a second sheet 20, a wick sheet 30 for a vapor chamber, a vapor channel part 50, and a first liquid channel part 60. The second sheet 20 is disposed on a side of the wick sheet 30 opposite from the first sheet 10. The wick sheet 30 for a vapor chamber is an example of a body sheet, and interposed between the first sheet 10 and the second sheet 20. The wick sheet 30 for a vapor chamber will be hereinafter referred to simply as wick sheet 30. In the vapor chamber 1 according to the first embodiment, the first sheet 10, the wick sheet 30, and the second sheet 20 are stacked in this order. Although the following description is directed to an example in which the wick sheet 30 is made up of a single sheet, the wick sheet 30 may be made up of two or more sheets. That is, the wick sheet 30 may be made up of any number of sheets.

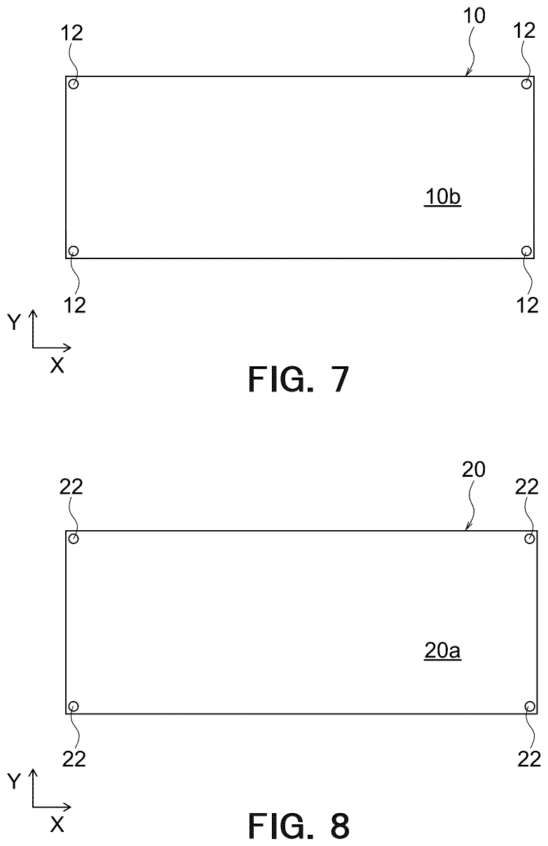

The vapor chamber 1 illustrated in FIG. 5 is generally in the form of a thin flat plate. Although the vapor chamber 1 in its pre-bending state may have any shape in plan view, the vapor chamber 1 in its pre-bending state may have a rectangular shape in plan view as illustrated in FIG. 5. The shape of the vapor chamber 1 in plan view may be, for example, a rectangle that is 1 cm on one side and 3 cm on the other side, or may be a square that is 15 cm on each side. The vapor chamber 1 in its pre-bending state may be of any dimensions in plan view. The following description of the first embodiment is directed to the example in which the vapor chamber 1 in its pre-bending state has a shape in plan view that is a rectangle with its longitudinal direction aligned with an X-direction described later. In this case, as illustrated in FIGS. 7 to 10, the first sheet 10, the second sheet 20, and the wick sheet 30 may each have a shape in plan view similar to that of the vapor chamber 1. The shape, in plan view, of the vapor chamber 1 in its pre-bending state is not necessarily a rectangle but may be any shape, such as a circle, an ellipse, an L-shape, or a T-shape.

As illustrated in FIGS. 4 and 5, the vapor chamber 1 includes an evaporation region SR where the working liquid 2b evaporates, and a condensation region CR where the working vapor 2a condenses. The working vapor 2a is a working fluid in a gaseous state, and the working liquid 2b is a working fluid in a liquid state.

The evaporation region SR is a region that overlaps the electronic device D in plan view, and that is in contact with the electronic device D. Although the evaporation region SR is located within the first region 5 in the present example, the evaporation region SR may be located at any position. According to the first embodiment, the evaporation region SR is located at one side of the vapor chamber 1 in the X-direction. In FIG. 5, the evaporation region SR is located at the left side of the vapor chamber 1. Heat from the electronic device D is transferred to the evaporation region SR, and the transferred heat causes the working liquid 2b to evaporate. The working vapor 2a is thus generated. The heat from the electronic device D may be transferred not only to a region overlapping the electronic device D in plan view, but also to the vicinity of the region that overlaps the electronic device D. Accordingly, the evaporation region SR may, in plan view, include a region overlapping the electronic device D, and the vicinity of the region.

The condensation region CR is a region that does not overlap the electronic device D in plan view, and that serves as a region where mainly the working vapor 2a releases its heat and condenses. The condensation region CR may be located within the second region 6. The condensation region CR may be a region surrounding the evaporation region SR including the second region 6. In the condensation region CR, heat from the working vapor 2a is released. The working vapor 2a is thus cooled to condense, and the working liquid 2b is generated.

As used herein, the term “plan view” refers to viewing in a direction that is orthogonal to a face of the vapor chamber 1 that receives heat from the electronic device D, and that is orthogonal to a face of the vapor chamber 1 that releases the received heat. A face that receives heat corresponds to a second-sheet outer face 20b (described later) of the second sheet 20. A face that releases heat corresponds to a first-sheet outer face 10a (described later) of the first sheet 10. For example, for the first region 5 of the vapor chamber 1 in its bent state, its plan view corresponds to a view seen in a direction represented by an arrow V1 as illustrated in FIG. 4. For the second region 6, its plan view corresponds to a view seen in a direction represented by an arrow V2. As illustrated in FIG. 5, for the vapor chamber 1 in its pre-bending state, its plan view corresponds to a view of the vapor chamber 1 as seen from above or a view of the vapor chamber 1 as seen from below.

As illustrated in FIG. 6, the first sheet 10 has the first-sheet outer face 10a located opposite from the wick sheet 30, and a first-sheet inner face 10b facing the wick sheet 30. In the second region 6 mentioned above, the housing component Ha mentioned above may be in contact with the first-sheet outer face 10a. A first body face 30a (described later) of the wick sheet 30 is in contact with the first-sheet inner face 10b. As illustrated in FIGS. 6 and 7, the first sheet 10 may have a substantially flat shape. The first sheet 10 may have a substantially constant thickness.

As illustrated in FIG. 7, an alignment hole 12 may be disposed at each of the four corners of the first sheet 10. Although the alignment hole 12 is illustrated in FIG. 7 as having a circular shape in plan view, this is not intended to be limiting. The alignment hole 12 may penetrate through the first sheet 10.

As illustrated in FIG. 6, the second sheet 20 includes a second-sheet inner face 20a facing the wick sheet 30, and the second-sheet outer face 20b located opposite from the wick sheet 30. In the first region 5 mentioned above, the electronic device D mentioned above may be in contact with the second-sheet outer face 20b. A second body face 30b (described later) of the wick sheet 30 is in contact with the second-sheet inner face 20a. As illustrated in FIGS. 6 and 8, the second sheet 20 may have a substantially flat shape. The second sheet 20 may have a substantially constant thickness.

As illustrated in FIG. 8, an alignment hole 22 may be disposed at each of the four corners of the second sheet 20. Although the alignment hole 22 is illustrated in FIG. 8 as having a circular shape in plan view, this is not intended to be limiting. The alignment hole 22 may penetrate through the second sheet 20.

As illustrated in FIG. 5, the wick sheet 30 includes the first body face 30a, and the second body face 30b located opposite from the first body face 30a. The first-sheet inner face 10b of the first sheet 10 is in contact with the first body face 30a. The second-sheet inner face 20a of the second sheet 20 is in contact with the second body face 30b.

The first-sheet inner face 10b of the first sheet 10, and the first body face 30a of the wick sheet 30 may be diffusion-bonded to each other. The first-sheet inner face 10b and the first body face 30a may be permanently bonded to each other.

Likewise, the second-sheet inner face 20a of the second sheet 20, and the second body face 30b of the wick sheet 30 may be diffusion-bonded to each other. The second-sheet inner face 20a and the second body face 30b may be permanently bonded to each other.

As described herein, the term “permanently bonded” is not bound by the strict meaning of the term. Rather, the term is used to mean being bonded to an extent that allows the sealing of the hermetically sealed space 3 to be maintained during operation of the vapor chamber 1.

As illustrated in FIGS. 5, 9, and 10, the wick sheet 30 according to the first embodiment includes a frame part 32, and a plurality of land parts 33. The frame part 32 defines the vapor channel part 50. In plan view, the frame part 32 is in the form of a rectangular frame extending in the X-direction and the Y-direction. Each land part 33 is located within the vapor channel part 50. In plan view, the land part 33 is located inside the frame part 32. The frame part 32 and the land part 33 are parts where the material of the wick sheet 30 remains without being etched away in an etching step (described later). A first vapor passage 51 (described later) is provided between the frame part 32, and the land part 33 adjacent to the frame part 32. The working vapor 2a flows through the first vapor passage 51. A second vapor passage 52 (described later) is provided between the land parts 33 that are adjacent to each other. The working vapor 2a flows through the second vapor passage 52.

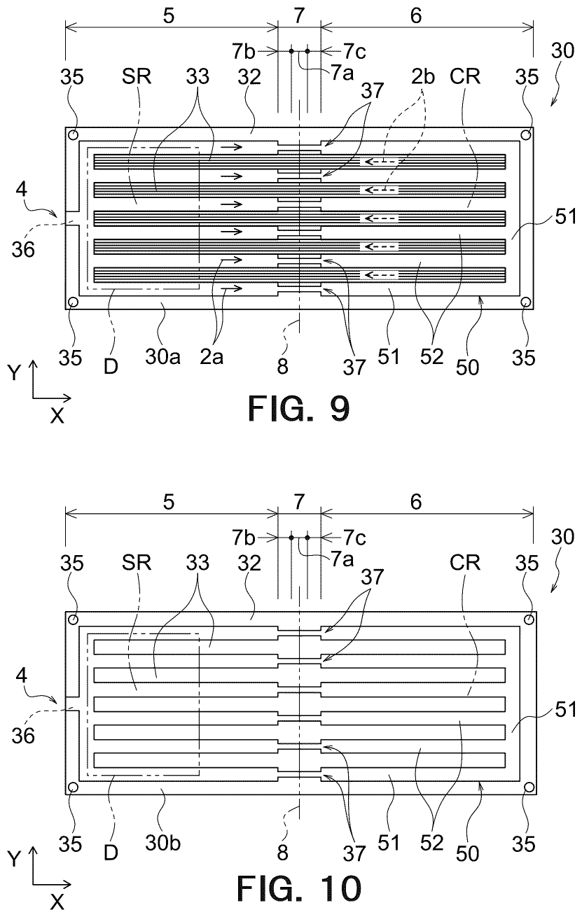

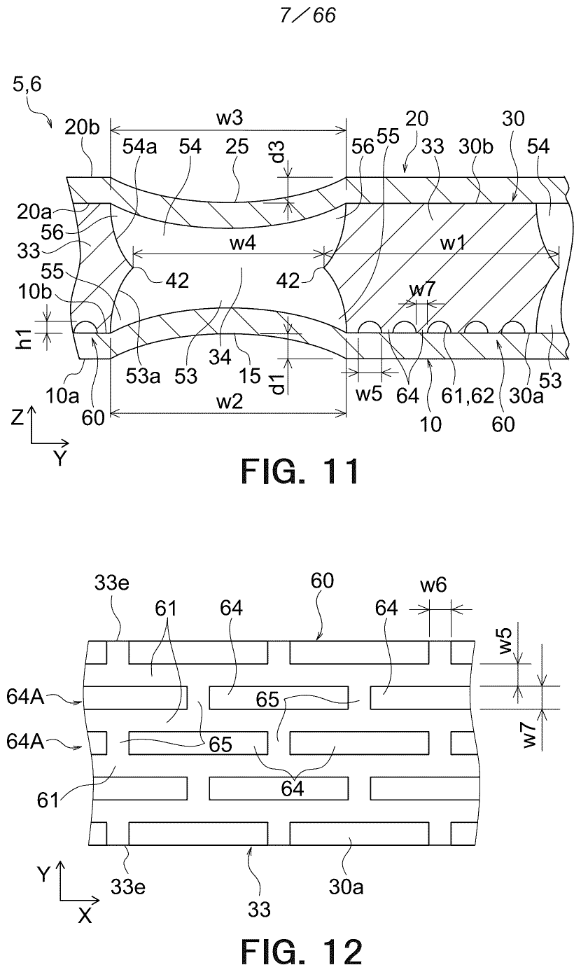

In plan view, the land part 33 may extend in an elongated shape with its longitudinal direction aligned with the X-direction. The land part 33 may have an elongated rectangular shape in plan view. The X-direction is an example of a first direction. The X-direction corresponds to the left-right direction in FIGS. 9 and 10. The land parts 33 may be disposed at equal intervals in the Y-direction. The Y-direction is an example of a second direction. The Y-direction is a direction orthogonal to the X-direction in plan view. The Y-direction is the width direction of the land part 33, and corresponds to the up-down direction in FIGS. 9 and 10. The land parts 33 may be positioned in parallel to each other. A direction orthogonal to the X-direction and to the Y-direction is defined as a Z-direction. The Z-direction corresponds to the up-down direction in FIGS. 6 and 11. The Z-direction corresponds to the thickness direction.

As illustrated in FIG. 11, the land part 33 may have a width w1 of, for example, 100 μm to 1500 μm. The width w1 of the land part 33 in this case is a dimension of the land part 33 in the Y-direction. The width w1 means a dimension of the wick sheet 30 at a position in the Z-direction of the wick sheet 30 where a through-part 34 (described later) exists. The width w1 means a dimension of the land part 33 from an extended portion 42 (described later) on one side to the extended portion 42 on the other side.

In the first region 5 and the second region 6 of the vapor chamber 1 illustrated in FIG. 4, the X-direction corresponds to the direction along the length of the land part 33. The X-direction in the first region 5 corresponds to the up-down direction in FIG. 4. In the first region 5 and the second region 6 of the vapor chamber 1 illustrated in FIG. 4, the Y-direction corresponds to a direction in which the land parts 33 are arranged. In the first region 5 and the second region 6 of the vapor chamber 1 illustrated in FIG. 4, the Z-direction corresponds to a direction orthogonal to the vapor chamber 1. The Z-direction in the second region 6 corresponds to the up-down direction in FIG. 4.

The frame part 32 and each land part 33 are diffusion-bonded to the first sheet 10, and diffusion-bonded to the second sheet 20. This allows for improved mechanical strength of the vapor chamber 1. A wall face 53a of a first vapor channel recess 53 (described later), and a wall face 54a of a second vapor channel recess 54 (described later) constitute a side wall of the land part 33. The first body face 30a and the second body face 30b of the wick sheet 30 may each extend in a flat shape across the frame part 32 and the land parts 33.

As illustrated in FIGS. 9 and 10, an alignment hole 35 may be disposed at each of the four corners of the wick sheet 30. Although the alignment hole 35 is illustrated in FIGS. 9 and 10 as having a circular shape in plan view, this is not intended to be limiting. The alignment hole 35 may penetrate through the wick sheet 30.

As illustrated in FIG. 6, the vapor channel part 50 may be disposed in the first body face 30a of the wick sheet 30. The vapor channel part 50 is an example of a space part. The vapor channel part 50 may be a channel through which mainly the working vapor 2a passes. The working liquid 2b may also pass through the vapor channel part 50. According to the first embodiment, the vapor channel part 50 may extend from the first body face 30a to the second body face 30b, that is, may penetrate through the wick sheet 30. The vapor channel part 50 may be covered at the first body face 30a by the first sheet 10. The vapor channel part 50 may be covered at the second body face 30b by the second sheet 20.

As illustrated in FIGS. 9 and 10, the vapor channel part 50 according to the first embodiment may include the first vapor passage 51, and a plurality of second vapor passages 52. Each of the first vapor passage 51 and the second vapor passage 52 is an example of a working fluid passage. The first vapor passage 51 is provided between the frame part 32 and the land part 33. The first vapor passage 51 is provided contiguously inside the frame part 32 and outside the land part 33. In plan view, the first vapor passage 51 may be in the form of a rectangular frame extending in the X-direction and the Y-direction. The first vapor passage 51 may include a portion extending in the X-direction, and a portion extending in the Y-direction. The second vapor passage 52 is disposed between the land parts 33 that are adjacent to each other. The second vapor passage 52 may have an elongated rectangular shape in plan view. The second vapor passage 52 may extend in the X-direction. The vapor channel part 50 is sectioned by the land parts 33 into the first vapor passage 51 and the second vapor passages 52.

As illustrated in FIG. 6, the first vapor passage 51 and the second vapor passage 52 may extend from the first body face 30a of the wick sheet 30 to the second body face 30b. In this case, the first vapor passage 51 and the second vapor passage 52 penetrate through the wick sheet 30. The first vapor passage 51 and the second vapor passage 52 each include the first vapor channel recess 53, and the second vapor channel recess 54. The first vapor channel recess 53 is disposed in the first body face 30a. The second vapor channel recess 54 is disposed in the second body face 30b. The first vapor channel recess 53 and the second vapor channel recess 54 communicate with each other. The first vapor channel recess 53 and the second vapor channel recess 54 may extend in the X-direction.

The first vapor channel recess 53 may be formed in an etching step (described later) through etching of the first body face 30a of the wick sheet 30. The first vapor channel recess 53 is in the form of a recess provided in the first body face 30a. As illustrated in FIG. 11, the first vapor channel recess 53 may include the wall face 53a having a curved shape. FIG. 11 is a cross-section orthogonal to the X-direction. The wall face 53a defines the first vapor channel recess 53. The wall face 53a may have a curved shape such that the distance between the wall face 53a on one side and the wall face 53a on the other, opposite side decreases with increasing proximity to the second body face 30b. The first vapor channel recess 53 constitutes a portion of the first vapor passage 51 located relatively close to the first sheet 10, and a portion of the second vapor passage 52 located relatively close to the first sheet 10.

In the first region 5 and the second region 6, the first vapor channel recess 53 may have a width w2 of, for example, 100 μm to 5000 μm. The width w2 of the first vapor channel recess 53 is a dimension in the Y-direction. The width w2 is a dimension of the first vapor channel recess 53 at the location of the first body face 30a. The width w2 corresponds to a dimension in the Y-direction of a portion of the first vapor passage 51 that extends in the X-direction, and to a dimension in the Y-direction of the second vapor passage 52. The width w2 also corresponds to a dimension in the X-direction of a portion of the first vapor passage 51 that extends in the Y-direction.

The second vapor channel recess 54 may be formed in an etching step (described later) through etching of the second body face 30b of the wick sheet 30. The second vapor channel recess 54 is in the form of a recess provided in the second body face 30b. As illustrated in FIG. 11, the second vapor channel recess 54 may include the wall face 54a having a curved shape. The wall face 54a defines the second vapor channel recess 54. The wall face 54a may have a curved shape such that the distance between the wall face 54a on one side and the wall face 54a on the other, opposite side decreases with increasing proximity to the first body face 30a. The second vapor channel recess 54 constitutes a portion of the first vapor passage 51 located relatively close to the second sheet 20, and a portion of the second vapor passage 52 located relatively close to the second sheet 20.

As with the width w2 of the first vapor channel recess 53 mentioned above, a width w3 of the second vapor channel recess 54 in the first region 5 and the second region 6 may be, for example, 100 μm to 5000 μm. The width w3 of the second vapor channel recess 54 is a dimension in the Y-direction. The width w3 is a dimension of the second vapor channel recess 54 at the location of the second body face 30b. The width w3 corresponds to a dimension in the Y-direction of a portion of the first vapor passage 51 that extends in the X-direction, and to a dimension in the Y-direction of the second vapor passage 52. The width w3 also corresponds to a dimension in the X-direction of a portion of the first vapor passage 51 that extends in the Y-direction. The width w3 of the second vapor channel recess 54 may be equal to or different from the width w2 of the first vapor channel recess 53.

As illustrated in FIG. 11, the wall face 53a of the first vapor channel recess 53, and the wall face 54a of the second vapor channel recess 54 may be connected to define the through-part 34. According to the first embodiment, the through-part 34 in the first vapor passage 51 may have the shape of a rectangular frame in plan view. The through-part 34 in the second vapor passage 52 may have an elongated rectangular shape in plan view. The through-part 34 may be defined by the extended portion 42. The land part 33 may include the extended portion 42. The extended portion 42 may be defined by a ridge where the wall face 53a of the first vapor channel recess 53, and the wall face 54a of the second vapor channel recess 54 meet. As illustrated in FIG. 11, the extended portion 42 may be extended out toward the inside of the vapor passage 51 or 52. The area of the first vapor passage 51 in plan view may be at its minimum at the through-part 34, and the area of the second vapor passage 52 in plan view may be at its minimum at the through-part 34. The through-part 34 in each of the vapor passages 51 and 52 may have a width w4 of, for example, 400 μm to 5000 μm. The width w4 of the through-part 34 in this case is the width of the through-part 34 in the first region 5 and the second region 6, and corresponds to the gap between the land parts 33 that are adjacent to each other in the Y-direction. As illustrated in FIG. 11, the width w4 may be the gap between two extended portions 42 each corresponding to a portion of the land part 33 where the land part 33 is extended most toward the inside of the vapor passage 51 or 52.

The position of the through-part 34 in the Z-direction may be the midway position between the first body face 30a and the second body face 30b. Alternatively, the position of the through-part 34 may be closer to the first sheet 10 than is the midway position, or may be closer to the second sheet 20 than is the midway position. The through-part 34 may be located at any position in the Z-direction. The position of the through-part 34 in the Z-direction may be the same as the position of the extended portion 42 in the Z-direction.

According to the first embodiment, as mentioned above, the first vapor passage 51 and the second vapor passage 52 are each shaped to have a cross-section that includes the through-part 34 defined by the extended portion 42, which extends out inward. This, however, is not intended to be limiting. For example, the first vapor passage 51 and the second vapor passage 52 may each have a cross-section that is a trapezoid or a parallelogram, or a cross-section that is barrel-shaped.

The vapor channel part 50 including the first vapor passage 51 and the second vapor passage 52 configured as described above constitutes a portion of the hermetically sealed space 3 mentioned above. The vapor passages 51 and 52 each have a relatively large channel cross-sectional area to allow passage of the working vapor 2a therethrough.

It is to be noted that for clarity of illustration, FIG. 11 depicts the first vapor passage 51 and the second vapor passage 52 in enlarged scale. In FIGS. 6 and 11, for clarity of illustration, the number of second vapor passages 52 and the number of land parts 33 are made to differ from those depicted in FIG. 5. Likewise, the number of main flow grooves 61 (described later) in the example illustrated in FIG. 11 is made to differ from that depicted in FIG. 6. For other figures as well, for clarity of illustration, the number of second vapor passages 52, the number of land parts 33, the number of main flow grooves 61, and other details are made to differ between the figures as appropriate.

A plurality of supports (not illustrated) for supporting the land part 33 to the frame part 32 may be disposed in each of the vapor passages 51 and 52. A support for supporting two mutually adjacent land parts 33 may be also provided. These supports may be disposed on both sides of the land part 33 in the X-direction, or may be disposed on both sides of the land part 33 in the Y-direction. Each support may be provided in a manner that does not obstruct the flow of the working vapor 2a that diffuses in the vapor channel part 50. For example, the support may be located near one of the first body face 30a and the second body face 30b of the wick sheet 30, and a space defining the vapor channel part 50 may be provided near the other one of the first body face 30a and the second body face 30b. The support can be thus made thinner than the wick sheet 30. This can prevent the first vapor passage 51 and the second vapor passage 52 from being split into separate parts in the X-direction and the Y-direction.

As illustrated in FIG. 5, the vapor chamber 1 may include an injection part 4 for injecting the working liquid 2b into the hermetically sealed space 3. The injection part 4 includes an injection channel 36 communicating with the first vapor passage 51. The injection part 4 may be located at any position. As illustrated in FIGS. 9 and 10, the injection channel 36 may be in the form of a recess provided in the second body face 30b. Alternatively, the injection channel 36 may be in the form of a recess provided in the first body face 30a. Depending on the configuration of the first liquid channel part 60, the injection channel 36 may communicate with the first liquid channel part 60.

As illustrated in FIGS. 6, 9, and 11, the first liquid channel part 60 may be provided between the first sheet 10 and the wick sheet 30. According to the first embodiment, the first liquid channel part 60 is provided in the first body face 30a of the land part 33. The first liquid channel part 60 may be a channel through which mainly the working liquid 2b passes. The working vapor 2a mentioned above may pass through the first liquid channel part 60. The first liquid channel part 60 constitutes a portion of the hermetically sealed space 3 mentioned above. The first liquid channel part 60 communicates with the vapor channel part 50. The first liquid channel part 60 is implemented as a capillary structure for transporting the working liquid 2b to the evaporation region SR. The first liquid channel part 60 is referred to also as wick in some cases. The first liquid channel part 60 may be provided across the entire first body face 30a of each land part 33. Although not illustrated in FIG. 9 or other figures, the first liquid channel part 60 may be provided inside an area defined by the first body face 30a of the frame part 32. According to the first embodiment, the first liquid channel part 60 is provided neither in the second body face 30b of the land part 33 nor in the second body face 30b of the frame part 32.

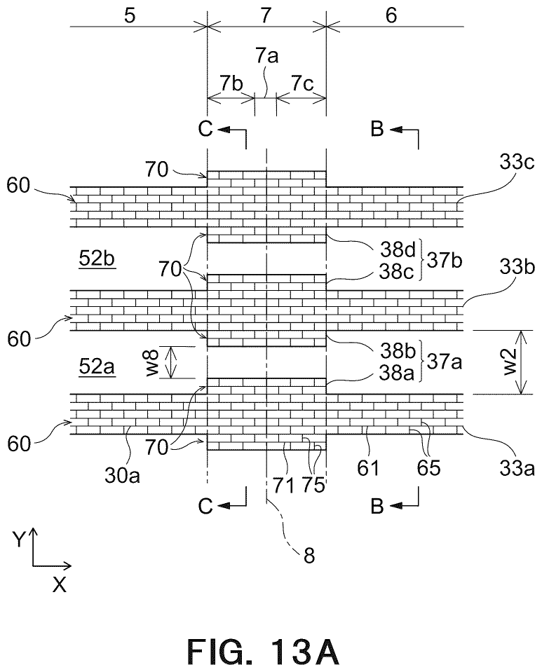

As illustrated in FIG. 12, the first liquid channel part 60 is an example of a first collection of grooves including a plurality of grooves. More specifically, the first liquid channel part 60 includes a plurality of main flow grooves 61, and a plurality of communication grooves 65. The main flow groove 61 and the communication groove 65 of the first liquid channel part 60 each represent an example of a first groove. The main flow groove 61 and the communication groove 65 are grooves through which the working liquid 2b passes. The communication groove 65 communicates with the main flow groove 61.

As illustrated in FIG. 12, each main flow groove 61 extends in the X-direction. The main flow groove 61 has a small channel cross-sectional area that allows mainly the working liquid 2b to flow therethrough under capillary action. The main flow groove 61 is smaller in channel cross-sectional area than the vapor passages 51 and 52. The main flow groove 61 is configured to transport the working liquid 2b condensed from the working vapor 2a to the evaporation region SR. The main flow grooves 61 may be spaced apart from each other at equal intervals in the Y-direction orthogonal to the X-direction. The main flow grooves 61 may be positioned in parallel to each other.

The main flow groove 61 is formed in an etching step (described later) through etching of the first body face 30a of the wick sheet 30. The main flow groove 61 may thus include a curved wall face 62 as illustrated in FIG. 11. The wall face 62 defines the main flow groove 61. The wall face 62 may have such a curved shape that bulges toward the second body face 30b.

As illustrated in FIGS. 11 and 12, the main flow groove 61 may have a width w5 less than the width w2 of the first vapor channel recess 53. The width w5 of the main flow groove 61 may be less than the width w1 of the land part 33. The width w5 of the main flow groove 61 may be, for example, 5 μm to 400 μm. The width w5 means a dimension of the main flow groove 61 at the location of the first body face 30a. In FIGS. 11 and 12, the width w5 corresponds to a dimension of the main flow groove 61 in the Y-direction. The main flow groove 61 may have a depth h1 of, for example, 3 μm to 300 μm. The depth h1 corresponds to a dimension of the main flow groove 61 in the Z-direction.

As illustrated in FIG. 12, each communication groove 65 extends in a direction different from the X-direction. According to the first embodiment, each communication groove 65 extends in the Y-direction, and is perpendicular to the main flow groove 61. Some communication grooves 65 provide communication between two mutually adjacent main flow grooves 61. Other communication grooves 65 provide communication between the first vapor passage 51 or the second vapor passage 52, and the main flow groove 61. Each of the other communication grooves 65 may extend from a side edge 33e of the land part 33 in the Y-direction to the main flow groove 61 adjacent to the side edge 33e. In this way, the first vapor passage 51 communicates with the main flow groove 61, and the second vapor passage 52 communicates with the main flow groove 61.

The communication groove 65 has a small channel cross-sectional area that allows mainly the working liquid 2b to flow therethrough under capillary action. The communication groove 65 has a channel cross-sectional area less than the channel cross-sectional area of each of the vapor passages 51 and 52. The communication grooves 65 may be spaced apart from each other in the X-direction at predetermined intervals or at equal intervals. The communication grooves 65 may be positioned in parallel to each other.

As with the main flow groove 61, the communication groove 65 is also formed through etching (described later). The communication groove 65 may thus include a curved wall face (not illustrated) similar to that of the main flow groove 61. The communication groove 65 may have a width w6 less than the width w2 of the first vapor channel recess 53. The width w6 of the communication groove 65 may be less than the width w1 of the land part 33. As illustrated in FIG. 12, the width w6 of the communication groove 65 may be equal to the width w5 of the main flow groove 61. Alternatively, however, the width w6 may be greater than the width w5, or may be less than the width w5. The width w6 means a dimension of the communication groove 65 at the location of the first body face 30a. In FIG. 12, the width w6 corresponds to a dimension of the communication groove 65 in the X-direction. The communication groove 65 may have a depth equal to the depth h1 of the main flow groove 61. Alternatively, however, the depth of the communication groove 65 may be greater than the depth h1, or may be less than the depth h1.

As illustrated in FIG. 12, the first liquid channel part 60 includes a projection row 64A. The projection row 64A is disposed on the first body face 30a of the wick sheet 30. The projection row 64A is disposed between the main flow grooves 61 that are adjacent to each other. Each projection row 64A includes a plurality of projections 64 arrayed in the X-direction. The projections 64 abut on the first sheet 10. As illustrated in FIG. 12, each projection 64 has a rectangular shape in plan view with its longitudinal direction aligned with the X-direction. The main flow groove 61 is interposed between the projections 64 that are adjacent to each other in the Y-direction. The communication groove 65 is interposed between the projections 64 that are adjacent to each other in the X-direction.

The projection 64 is a part where the material of the wick sheet 30 remains without being etched away in an etching step (described later). According to the first embodiment, the projection 64 has a rectangular shape in plan view as illustrated in FIG. 12. More specifically, the shape in plan view of the projection 64 corresponds to the shape in plan view of the projection 64 at the location of the first body face 30a.

According to the first embodiment, the projections 64 are positioned in a staggered arrangement. More specifically, the projections 64 of the projection rows 64A that are adjacent to each other in the Y-direction are positioned offset relative to each other in the X-direction. The amount of offset may be half the array pitch of the projections 64 in the X-direction. The projection 64 may have a width w7 of, for example, 5 μm to 500 μm. The width w7 means a dimension of the projection 64 at the location of the first body face 30a. In FIG. 12, the width w7 corresponds to a dimension of the projection 64 in the Y-direction. The projections 64 are not necessarily positioned in a staggered arrangement. Alternatively, the projections 64 may be arrayed in parallel with each other. In this case, the projections 64 of the projection rows 64A that are adjacent to each other in the Y-direction are located at the same position in the X-direction.

The first sheet 10, the second sheet 20, and the wick sheet 30 may be made of any material without particular limitation, as long as the material has favorable thermal conductivity sufficient to ensure adequate heat dissipation efficiency of the vapor chamber 1. For example, each of the sheets 10, 20, and 30 may be made of a metallic material. For example, each of the sheets 10, 20, and 30 may contain copper or a copper alloy. Copper and a copper alloy have favorable thermal conductivity, and exhibit corrosion resistance for cases where pure water is to be used as the working fluid. Examples of copper include pure copper and oxygen-free copper (C1020). Examples of copper alloys include: copper alloys containing tin; copper alloys containing titanium (e.g., C1990); and Corson copper alloys (e.g., C7025), which are copper alloys containing nickel, silicon, and magnesium. An example of copper alloys containing tin is phosphor bronze (e.g., C5210).

The vapor chamber 1 illustrated in FIG. 6 may have a thickness t1 of, for example, 100 μm to 500 μm. Making the thickness t1 of the vapor chamber 1 greater than or equal to 100 μm can ensure adequate space for the vapor channel part 50. This allows for proper functioning of the vapor chamber 1. By contrast, making the thickness t1 less than or equal to 500 μm can mitigate an increase in the thickness t1 of the vapor chamber 1. This allows for reduced thickness of the vapor chamber 1.

The thickness of the wick sheet 30 may be greater than the thickness of the first sheet 10. Likewise, the thickness of the wick sheet 30 may be greater than the thickness of the second sheet 20. The first embodiment is directed to an exemplary case where the thickness of the first sheet 10 and the thickness of the second sheet 20 are equal. However, the present disclosure is not limited to such a configuration. Alternatively, the thickness of the first sheet 10 and the thickness of the second sheet 20 may be different.

The first sheet 10 may have a thickness t2 of, for example, 6 μm to 100 μm. Making the thickness t2 of the first sheet 10 greater than or equal to 6 μm can ensure mechanical strength and long-term reliability of the first sheet 10. By contrast, making the thickness t2 of the first sheet 10 less than or equal to 100 μm can mitigate an increase in the thickness t1 of the vapor chamber 1. A thickness t3 of the second sheet 20 may be set similarly to the thickness t2 of the first sheet 10.

The wick sheet 30 may have a thickness t4 of, for example, 50 μm to 400 μm. Making the thickness t4 of the wick sheet 30 greater than or equal to 50 μm can ensure adequate space for the vapor channel part 50. This allows for proper functioning of the vapor chamber 1. By contrast, making the thickness t4 less than or equal to 400 μm can mitigate an increase in the thickness t1 of the vapor chamber 1. This allows for reduced thickness of the vapor chamber 1. The thickness t4 of the wick sheet 30 may be the distance between the first body face 30a and the second body face 30b.

As illustrated in FIG. 5, the vapor chamber 1 according to the first embodiment is sectioned into the first region 5, the second region 6, and the reinforcement region 7. Likewise, the wick sheet 30 is sectioned into the first region 5, the second region 6, and the reinforcement region 7. As illustrated in FIGS. 5, 9, and 10, each of the land parts 33 of the wick sheet 30 mentioned above extends in the X-direction from the first region 5 to the second region 6 via the reinforcement region 7. Each of the land parts 33 is provided over an area extending from the first region 5 to the second region 6, and passes through the reinforcement region 7.

As illustrated in FIGS. 9 and 10, each of the second vapor passages 52 is provided with a reinforcement part 37. The reinforcement part 37 is located in the reinforcement region 7 including the bend region 7a. No reinforcement part 37 may be located in the first region 5. No reinforcement part 37 may be located in the second region 6. Each of the second vapor passages 52 may be provided with a single reinforcement part 37. Although the following description is directed for convenience to the reinforcement part 37 provided in the second vapor passage 52, the reinforcement part 37 may be likewise provided in the first vapor passage 51. For example, two portions of the first vapor passage 51 that are located in the reinforcement region 7 may be each provided with a single reinforcement part 37. Each portion of the first vapor passage 51 that is located in the reinforcement region 7 corresponds to a portion of the first vapor passage 51 that extends in the X-direction.

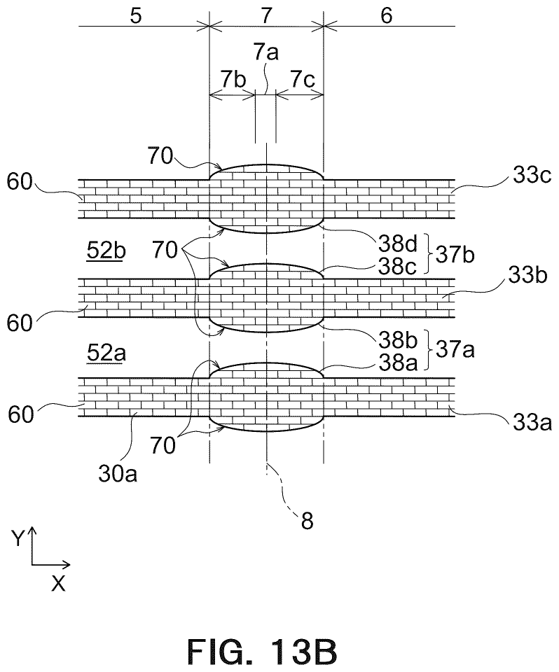

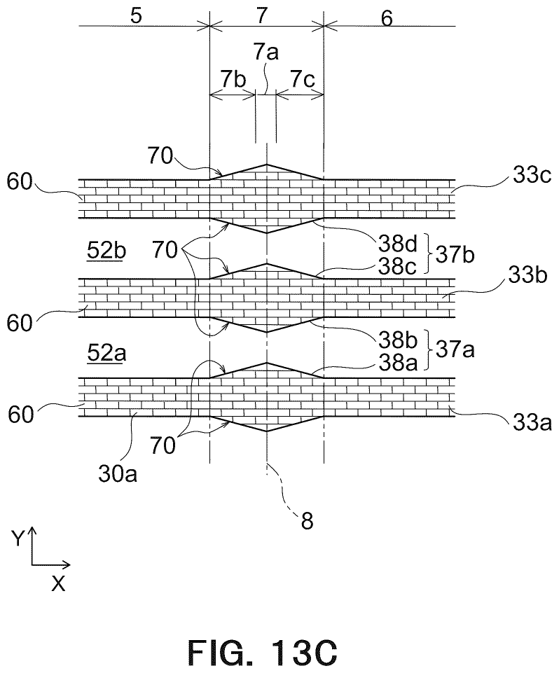

The reinforcement region 7 may be a region having an area in the X-direction where the reinforcement part 37 exists. For example, as illustrated in FIG. 13A, the reinforcement region 7 may be a region having an area in the X-direction where a protrusion 38 (described later) exists. The reinforcement region 7 may be a region extending in the Y-direction. With respect to the X-direction, the first region 5 refers to a region located on one side of the reinforcement region 7, and the second region 6 refers to a region located on the other side of the reinforcement region 7. In FIG. 13A, the first region 5 is located on the left side of the reinforcement region 7, and the second region 6 is located on the right side of the reinforcement region 7. The first region 5, the second region 6, and the reinforcement region 7 may be sectioned off from each other by boundary lines extending along the bend line 8. In the example illustrated in FIG. 13A, the bend line 8 extends linearly in the Y-direction. However, the present disclosure is not limited to such a configuration. The reinforcement region 7 does not necessarily have to extend in the Y-direction as long as the reinforcement part 37 exists in the reinforcement region 7. Each of the boundary lines delimiting the regions 5, 6, and 7 may be a non-straight line in any shape.

As illustrated in FIG. 13A, the reinforcement part 37 according to the first embodiment includes two protrusions 38. The protrusion 38 protrudes from each of two land parts 33 defining the second vapor passage 52. The protrusion 38 may protrude in the Y-direction from the land part 33. The protrusion 38 is located in the reinforcement region 7. The protrusion 38 may constitute the wick sheet 30. The protrusion 38 may be formed by etching. More specifically, the protrusion 38 may be a part where the material of the wick sheet 30 remains without being etched away in an etching step (described later). The protrusion 38 may be provided contiguously and integrally with the corresponding land part 33. In the first vapor passage 51, one of the protrusions 38 may be provided integrally with the land part 33, and the other protrusion 38 may be provided integrally with the frame part 32. The side wall of the protrusion 38 may be defined by a wall face that is similar to the wall face 53a of the first vapor channel recess 53 and to the wall face 54a of the second vapor channel recess 54. In FIG. 13A, reference signs 52a and 52b are used to designate individual second vapor passages. In the following description of the first embodiment, the subscripts “a” and “b” are added to the reference signs designating second vapor passages only when distinction is made between individual second vapor passages. Otherwise, these subscripts are omitted. The same applies to the subscripts “a” to “c” added to the reference signs designating individual land parts. The same applies to the subscripts “a” and “b” added to the reference signs designating individual reinforcement parts. The same applies to the subscripts “a” to “d” added to the reference signs designating individual protrusions.

The reinforcement parts 37 located in the corresponding second vapor passages 52 may be arranged along a predetermined direction crossing the X-direction. According to the first embodiment, such reinforcement parts 37 are arranged along the Y-direction. The Y-direction is a direction orthogonal to the X-direction in plan view. Each reinforcement part 37 is located at the same position in the X-direction. The reinforcement parts 37 may be arranged along the bend line 8.

A space through which the working vapor 2a passes is defined in the reinforcement part 37. More specifically, two protrusions 38 located in a single second vapor passage 52 define therebetween a space secured for the second vapor passage 52. Two protrusions 38 located in a single second vapor passage 52 may be spaced apart from each other in the Y-direction, and may face each other in the Y-direction. Such two protrusions 38 may be located at the same position in the X-direction. Such two protrusions 38 may have the same dimension in the X-direction.

FIG. 13A depicts two second vapor passages 52 that are adjacent to each other in the Y-direction. The two second vapor passages 52 are the second vapor passage 52a, and the second vapor passage 52b. The second vapor passage 52a is provided between a land part 33a and a land part 33b. The second vapor passage 52b is provided between the land part 33b and a land part 33c. A reinforcement part 37a is located in the second vapor passage 52a. A reinforcement part 37b is located in the second vapor passage 52b.

The reinforcement part 37a includes a first protrusion 38a, and a second protrusion 38b. The first protrusion 38a protrudes from the land part 33a. The second protrusion 38b protrudes from the land part 33b. The protrusion 38a and the protrusion 38b are in spaced, facing relation to each other. The reinforcement part 37b includes a third protrusion 38c, and a fourth protrusion 38d. The third protrusion 38c protrudes from the land part 33b. The fourth protrusion 38d protrudes from the land part 33c. The protrusion 38c and the protrusion 38d are in spaced, facing relation to each other. The third protrusion 38c protrudes from the land part 33b in a direction opposite to the direction in which the second protrusion 38b protrudes. Each of the protrusions 38a to 38d may have the same dimension in the X-direction.

Each of the protrusions 38a to 38d is located at the same position in the X-direction. The first protrusion 38a and the second protrusion 38b that constitute a single reinforcement part 37a are located at the same position in the X-direction. The second protrusion 38b and the third protrusion 38c that protrude from a single land part 33b are located at the same position in the X-direction. The third protrusion 38c and the fourth protrusion 38d that constitute a single reinforcement part 37b are located at the same position in the X-direction.

As illustrated in FIG. 13A, in plan view, the protrusion 38 may have a side aligned with the X-direction, and a side aligned with the Y-direction. The protrusion 38 may be provided over the entire reinforcement region 7 in the X-direction.

The shape of the protrusion 38 in plan view does not necessarily have to be a rectangle. The protrusion 38 may have any shape in plan view, such as a semi-circle, a semi-ellipse, a triangle, or a trapezoid. For example, the shape of the protrusion 38 in plan view may be a semi-ellipse as illustrated in FIG. 13B. This configuration can reduce the channel resistance of the second vapor passages 52a and 52b, and consequently can reduce impediment to the flow of the working vapor 2a. Alternatively, for example, the shape of the protrusion 38 in plan view may be a triangle as illustrated in FIG. 13C. This configuration as well can reduce the channel resistance of the second vapor passages 52a and 52b.

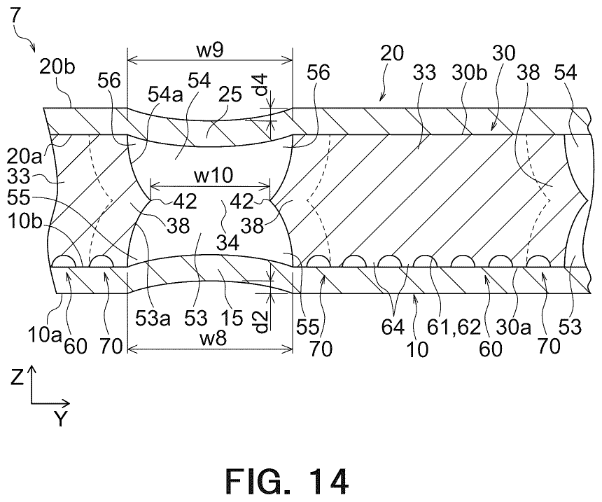

As illustrated in FIG. 14, the reinforcement part 37 extends from the first sheet 10 to the second sheet 20 in the thickness direction of the wick sheet 30. According to the first embodiment, the reinforcement part 37 constitutes the wick sheet 30, and extends from the first body face 30a to the second body face 30b. The protrusion 38 is defined in the Z-direction by the first body face 30a and the second body face 30b of the wick sheet 30. The protrusion 38 is diffusion-bonded to the first-sheet inner face 10b of the first sheet 10, and diffusion-bonded to the second-sheet inner face 20a of the second sheet 20.

As illustrated in FIGS. 13A and 14, due to the presence of the protrusion 38, the second vapor passage 52 has a reduced width in the reinforcement region 7. Due to the presence of the protrusion 38, the first vapor channel recess 53, the second vapor channel recess 54, and the through-part 34 are reduced in size in the Y-direction. This results in improved mechanical strength of the second vapor passage 52.

As illustrated in FIG. 14, the first vapor channel recess 53 in the reinforcement region 7 has a width w8. The width w8 is a dimension in the Y-direction. The width w8 is a dimension of the first vapor channel recess 53 at the first body face 30a. The width w8 corresponds to the width dimension of the second vapor passage 52 in the reinforcement region 7. The width w8 is less than the above-mentioned width w2 of the first vapor channel recess 53 in each of the first region 5 and the second region 6. The width w8 of the first vapor channel recess 53 in the reinforcement region 7 may be, for example, 500 μm to 1500 μm. Making the width w8 greater than or equal to 500 μm can reduce impediment to the flow of the working vapor 2a. Making the width w8 less than or equal to 1500 μm can effectively reduce a deformation of the first sheet 10 that causes the first sheet 10 to extend into the second vapor passage 52.

Likewise, the second vapor channel recess 54 in the reinforcement region 7 has a width w9. The width w9 is a dimension in the Y-direction. The width w9 is a dimension of the second vapor channel recess 54 at the second body face 30b. The width w9 corresponds to the width dimension of the second vapor passage 52 in the reinforcement region 7. The width w9 is less than the above-mentioned width w3 of the second vapor channel recess 54 in each of the first region 5 and the second region 6. The width w9 of the second vapor channel recess 54 in the reinforcement region 7 may be, for example, 500 μm to 1500 μm. Making the width w9 greater than or equal to 500 μm can reduce impediment to the flow of the working vapor 2a. Making the width w9 less than or equal to 1500 μm can effectively reduce a deformation of the second sheet 20 that causes the second sheet 20 to extend into the second vapor passage 52.

The through-part 34 in the reinforcement region 7 may have a width w10 less than the above-mentioned width w4 of the through-part 34 in each of the first region 5 and the second region 6. The width w10 of the through-part 34 in the reinforcement region 7 may be, for example, 300 μm to 1300 μm.

As illustrated in FIGS. 13A and 14, the first body face 30a of the protrusion 38 may be provided with a second liquid channel part 70. The second liquid channel part 70 is an example of a second collection of grooves. The second liquid channel part 70 may communicate with the vapor channel part 50 and the first liquid channel part 60. The second liquid channel part 70 may be configured similarly to the first liquid channel part 60. The second liquid channel part 70 may include a main flow groove 71, and a communication groove 75. The main flow groove 71 and the communication groove 75 of the second liquid channel part 70 each represent an example of a second groove. The main flow groove 71 may be configured similarly to the main flow groove 61. The communication groove 75 may be configured similarly to the communication groove 65. This configuration allows the working liquid 2b within the second vapor passage 52 to enter the second liquid channel part 70. The working liquid 2b within the second liquid channel part 70 can be transported to the evaporation region SR due to the capillary action exerted by the second liquid channel part 70 and the first liquid channel part 60.

As illustrated in FIGS. 11 and 14, a portion of the first sheet 10 may be allowed to extend into the vapor channel part 50. More specifically, a region of the first-sheet outer face 10a that overlaps the vapor channel part 50 may have a recessed shape that is recessed inward toward the vapor channel part 50. The first sheet 10 may include a first-sheet recess 15 overlapping the vapor passage 51 or 52 in plan view. The first-sheet recess 15 extends into the first vapor channel recess 53. The first-sheet recess 15 is provided in each of the first region 5, the second region 6, and the reinforcement region 7. The first-sheet recess 15 may extend from the first region 5 to the second region 6 via the reinforcement region 7.

As will be described later, the first sheet 10 may be thinner than the wick sheet 30. In this case, applying stress on a portion of the first sheet 10 that overlaps the vapor channel part 50 allows distortion to remain in the portion. Due to the presence of such residual distortion, the first-sheet recess 15 can be formed into a recessed shape in each of the first region 5, the second region 6, and the reinforcement region 7. For example, the first sheet 10 is more likely to exhibit residual distortion when subjected to stress applied while being softened by heating, or more likely to exhibit residual distortion when subjected to stress applied after being softened by heating. The first-sheet recess 15 can be thus formed into a recessed shape. Alternatively, however, in at least one of the first region 5, the second region 6, and the reinforcement region 7, the first sheet 10 may be formed in a flat shape such that the first sheet 10 does not include the first-sheet recess 15.

As illustrated in FIGS. 11 and 14, the first-sheet inner face 10b at the location of the first-sheet recess 15, and the wall face 53a of the first vapor channel recess 53 define a channel corner 55, which constitutes a portion of the vapor channel cross-section. The channel corner 55 may be wedge-shaped. The channel corner 55 may have capillary action.

As illustrated in FIGS. 11 and 14, a recess dimension d2 of the first-sheet outer face 10a in the reinforcement region 7 is less than a recess dimension d1 of the first-sheet outer face 10a in each of the first region 5 and the second region 6. This is because the width w8 of the first vapor channel recess 53 in the reinforcement region 7 is less than the width w2 of the first vapor channel recess 53 in each of the first region 5 and the second region 6.

As illustrated in FIGS. 11 and 14, a portion of the second sheet 20 may be allowed to extend into the vapor channel part 50. More specifically, a region of the second-sheet outer face 20b that overlaps the vapor channel part 50 may have a recessed shape that is recessed inward toward the vapor channel part 50. The second sheet 20 may include a second-sheet recess 25 overlapping the vapor passage 51 or 52 in plan view. The second-sheet recess 25 extends into the second vapor channel recess 54. The second-sheet recess 25 is provided in each of the first region 5, the second region 6, and the reinforcement region 7. The second-sheet recess 25 may extend from the first region 5 to the second region 6 via the reinforcement region 7.

As will be described later, the second sheet 20 may be thinner than the wick sheet 30. In this case, applying stress on a portion of the second sheet 20 that overlaps the vapor channel part 50 allows distortion to remain in the portion. Due to the presence of such residual distortion, the second-sheet recess 25 can be formed into a recessed shape in each of the first region 5, the second region 6, and the reinforcement region 7. For example, the second sheet 20 is more likely to exhibit residual distortion when subjected to stress applied while being softened by heating, or more likely to exhibit residual distortion when subjected to stress applied after being softened by heating. The second-sheet recess 25 can be thus formed into a recessed shape. Alternatively, however, in at least one of the first region 5, the second region 6, and the reinforcement region 7, the second sheet 20 may be formed in a flat shape such that the second sheet 20 does not include the second-sheet recess 25.

As illustrated in FIGS. 11 and 14, the second-sheet inner face 20a at the location of the second-sheet recess 25, and the wall face 54a of the second vapor channel recess 54 define a channel corner 56, which constitutes a portion of the vapor channel cross-section. The channel corner 56 may be wedge-shaped. The channel corner 56 may have capillary action.

As illustrated in FIGS. 11 and 14, a recess dimension d4 of the second-sheet outer face 20b in the reinforcement region 7 is less than a recess dimension d3 of the second-sheet outer face 20b in each of the first region 5 and the second region 6. This is because the width w9 of the second vapor channel recess 54 in the reinforcement region 7 is less than the width w3 of the second vapor channel recess 54 in each of the first region 5 and the second region 6.

The reinforcement region 7 may at least partially overlap the bend region 7a. According to the first embodiment, the entirety of the bend region 7a may overlap the reinforcement region 7. As illustrated in FIG. 5 or other figures, according to the first embodiment, the bend region 7a may have a dimension in the X-direction that is less than the dimension of the reinforcement region 7 in the X-direction. The reinforcement region 7 may have a dimension in the X-direction such that the reinforcement region 7 extends out on both sides of the bend region 7a in the X-direction.

The reinforcement region 7 according to the first embodiment includes the bend region 7a. In the bend region 7a, the vapor chamber 1 is bent along the bend line 8 extending in a direction crossing the X-direction in plan view. As illustrated in FIGS. 4 and 5, the bend line 8 according to the first embodiment extends in the Y-direction in plan view. The Y-direction is a direction orthogonal to the X-direction in plan view. The bend line 8 traverses the frame part 32, the land part 33, the first vapor passage 51, and the second vapor passage 52. This configuration can reduce a deformation of the first sheet 10 that causes the first sheet 10 to extend into the vapor passages 51 and 52, and can also reduce a deformation of the second sheet 20 that causes the second sheet 20 to extend into the vapor passages 51 and 52. This can ensure that the first vapor passage 51 and the second vapor passage 52 have adequate channel cross-sectional area.

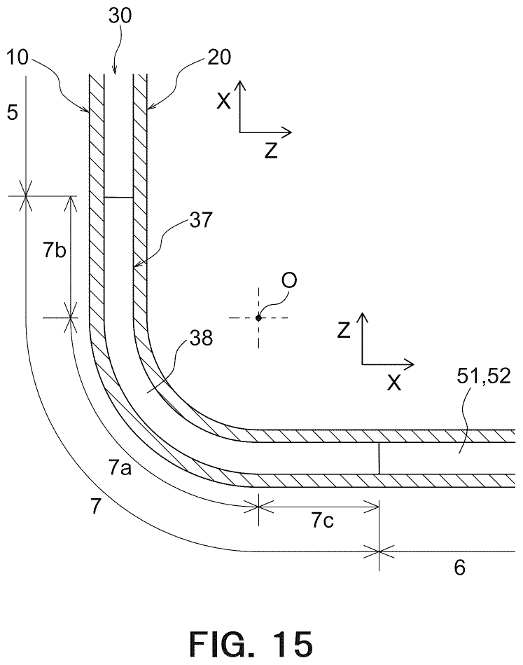

The vapor chamber 1 is bent as illustrated in FIG. 15. FIG. 15 illustrates an example in which the bend region 7a has the shape of a quarter-circular arc as in the case of the vapor chamber 1 illustrated in FIG. 2. Alternatively, however, the bend region 7a may have the shape of a semi-circular arc as in the case of the vapor chamber 1 illustrated in FIG. 3. That is, the bend region 7a may be bent in any shape. As illustrated in FIG. 15, the vapor chamber 1 may be bent in such a way that the second sheet 20 is located inward relative to the wick sheet 30. In the bend region 7a, the first sheet 10 is located outward relative to the wick sheet 30 with respect to a center O of the bend. The second sheet 20 is located inward relative to the wick sheet 30 with respect to the center O of the bend.

The reinforcement region 7 may include a first adjacent region 7b, and a second adjacent region 7c. The first adjacent region 7b is located between the first region 5 and the bend region 7a. The second adjacent region 7c is located between the second region 6 and the bend region 7a. The first adjacent region 7b and the second adjacent region 7c are portions of the reinforcement region 7 other than the bend region 7a, and may have a substantially flat shape. The bend region 7a may be located in the central portion of the reinforcement region 7 in the X-direction. The reinforcement part 37 may extend from the first adjacent region 7b to the second adjacent region 7c via the bend region 7a. The bend line 8 overlaps the reinforcement part 37. The vapor chamber 1 is bent at a position where the reinforcement part 37 exists. The bend region 7a, the first adjacent region 7b, and the second adjacent region 7c may be sectioned off from each other by boundary lines extending along the bend line 8. In the example illustrated in FIG. 13A, the bend region 7a may be sectioned off by boundary lines extending in the Y-direction in plan view.

Reference is now made to a method for manufacturing the vapor chamber 1 according to the first embodiment configured as described above.

First, as a preparing step, the first sheet 10, the second sheet 20, and the wick sheet 30 are prepared. The preparing step may include an etching step of forming the wick sheet 30 through etching. In the etching step, the wick sheet 30 may be formed through etching by use of a patterned resist film (not illustrated) based on the photolithography technique.

As a temporal fastening step, the first sheet 10, the wick sheet 30, and the second sheet 20 are temporarily fastened together. For example, the sheets 10, 20, and 30 may be temporarily fastened together by spot welding or laser welding. At this time, the sheets 10, 20, and 30 may be aligned with each other by use of the alignment holes 12, 22, and 35.

Subsequently, as a bonding step, the first sheet 10, the wick sheet 30, and the second sheet 20 are permanently bonded to each other. The sheets 10, 20, and 30 may be bonded to each other by diffusion bonding.

The bonding step is followed by an injection step. In the injection step, the hermetically sealed space 3 is evacuated to a vacuum, and the working liquid 2b is injected into the hermetically sealed space 3 from the injection part 4 (see FIG. 5).

The injection step is followed by a sealing step, in which the injection channel 36 mentioned above is sealed off. This cuts off communication between the hermetically sealed space 3 and the external environment, resulting in hermetic sealing of the hermetically sealed space 3. As a result, the hermetically sealed space 3 with the working liquid 2b sealed therein is obtained. This prevents external leakage of the working liquid 2b sealed in the hermetically sealed space 3.

The sealing step may be followed by a bending step, in which the first sheet 10, the second sheet 20, and the wick sheet 30 are bent. For example, the sheets 10, 20, and 30 are bent along the bend line 8 extending in the Y-direction as illustrated in FIG. 5. At this time, a jig (not illustrated) abuts on the second-sheet outer face 20b of the second sheet 20, which is located at the inner side of the bend. With the sheets 10, 20, and 30 held at their opposite ends in the X-direction, the sheets 10, 20, and 30 are each bent at a desired angle. Consequently, the vapor chamber 1 in its bent state illustrated in FIG. 4 is obtained, and the bend region 7a is formed in the reinforcement region 7 of the vapor chamber 1. The bending step may be performed between the bonding step and the injection step.

During bending, the first sheet 10 and the second sheet 20 in the bend region 7a are subjected to an applied force that tends to cause the vapor channel part 50 to collapse. To address this, according to the first embodiment, as described above, each of the vapor passages 51 and 52 in the reinforcement region 7 including the bend region 7a is provided with the protrusion 38, which serves as the reinforcement part 37. The protrusion 38 extends from the first sheet 10 to the second sheet 20. This reduces the risk that each of the first sheet 10 and the second sheet 20 may extend into the vapor passages 51 and 52.

The vapor chamber 1 according to the first embodiment is obtained through the above-mentioned process.

Reference is now made to how the vapor chamber 1 operates, that is, how the electronic device D is cooled.

The vapor chamber 1 obtained as described above is installed inside the housing H of, for example, a mobile terminal. In the second region 6, the first-sheet outer face 10a of the first sheet 10 is in contact with the housing component Ha. In the first region 5, the second-sheet outer face 20b of the second sheet 20 is in contact with the electronic device D. The working liquid 2b within the hermetically sealed space 3 adheres, due to its surface tension, to the wall face of the hermetically sealed space 3. More specifically, the working liquid 2b adheres to the following wall faces: the wall face 53a of the first vapor channel recess 53; the wall face 54a of the second vapor channel recess 54; the wall face 62 of the main flow groove 61 of the first liquid channel part 60; and the wall face of the communication groove 65 of the first liquid channel part 60. The working liquid 2b may also adhere to portions of the first-sheet inner face 10b of the first sheet 10 that are exposed to the following areas: the first vapor channel recess 53, the main flow groove 61, and the communication groove 65. Further, the working liquid 2b may also adhere to a portion of the second-sheet inner face 20a of the second sheet 20 that is exposed to the second vapor channel recess 54.

When the electronic device D generates heat in this state, the working liquid 2b in the evaporation region SR receives heat from the electronic device D. As the received heat is absorbed as latent heat, the working liquid 2b evaporates, and the working vapor 2a is generated. As indicated by solid arrows in FIG. 9, the generated working vapor 2a diffuses within the first vapor passage 51 and the second vapor passage 52, which constitute the hermetically sealed space 3. More specifically, the working vapor 2a diffuses mainly in the X-direction in the following locations: a portion of the first vapor passage 51 of the vapor channel part 50 that extends in the X-direction; and the second vapor passage 52. In this case, a portion of the working vapor 2a diffuses smoothly from the first region 5 to the second region 6 by passing through the reinforcement region 7 including the bend region 7a. In the reinforcement region 7, the working vapor 2a passes through the space between two protrusions 38 that constitute the reinforcement part 37. As previously mentioned, in the bend region 7a, the risk of the first sheet 10 and the second sheet 20 extending into the vapor passages 51 and 52 is reduced. As a result, in the bend region 7a as well, adequate channel cross-sectional area for the working vapor 2a is provided, which reduces impediment to the flow of the working vapor 2a. If the bend region 7a has the shape of a circular arc as illustrated in FIG. 15, this can reduce impediment to the flow of the working vapor 2a in the bend region 7a. The working vapor 2a is thus allowed to smoothly diffuse through the vapor passages 51 and 52 toward the second region 6. Meanwhile, in a portion of the first vapor passage 51 that extends in the Y-direction, the working vapor 2a diffuses mainly in the Y-direction.

The working vapor 2a within each of the vapor passages 51 and 52 is then transported away from the evaporation region SR to the condensation region CR, which is at a relatively low temperature. In the condensation region CR, the working vapor 2a is cooled by rejecting heat mainly to the first sheet 10. The heat received by the first sheet 10 from the working vapor 2a is transferred to the outside air via the housing component Ha (see FIG. 6).

As the working vapor 2a rejects heat to the first sheet 10 in the condensation region CR, the working vapor 2a gives off the latent heat absorbed in the evaporation region SR. The working vapor 2a thus condenses, and the working liquid 2b is generated. The generated working liquid 2b adheres to the respective wall faces 53a and 54a of the vapor channel recesses 53 and 54, the first-sheet inner face 10b of the first sheet 10, and the second-sheet inner face 20a of the second sheet 20. At this time, the working liquid 2b keeps evaporating in the evaporation region SR. As indicated by dashed arrows in FIG. 9, the working liquid 2b in the condensation region CR of the first liquid channel part 60 is thus transported by the capillary action of each main flow groove 61 toward the evaporation region SR. Consequently, the working liquid 2b adhering on the wall faces 53a and 54a, the first-sheet inner face 10b, and the second-sheet inner face 20a moves to the first liquid channel part 60, where the working liquid 2b passes through the communication groove 65 into the main flow groove 61. The working liquid 2b condensed within each of the vapor passages 51 and 52 in the reinforcement region 7 moves to the first liquid channel part 60 by passing through the main flow groove 71 and the communication groove 75 of the second liquid channel part 70. In this way, each main flow groove 61 and each communication groove 65 are filled with the working liquid 2b. The working liquid 2b now filling these grooves gains, due to the capillary action of each main flow groove 61, a propulsion force that causes the working liquid 2b to move toward the evaporation region SR. The working liquid 2b is thus smoothly transported toward the evaporation region SR. The working liquid 2b is transported under capillary action even when, as illustrated in FIG. 4, the evaporation region SR is located in an upper part of the vapor chamber 1.

In the first liquid channel part 60, each main flow groove 61 communicates with another adjacent main flow groove 61 via the corresponding communication groove 65. The working liquid 2b thus moves back and forth between two main flow grooves 61 that are adjacent to each other. This reduces the risk of dry-out in the main flow grooves 61. As a result, capillary action is imparted to the working liquid 2b within each main flow groove 61, and the working liquid 2b is thus smoothly transported toward the evaporation region SR.

Upon reaching the evaporation region SR, the working liquid 2b evaporates by receiving heat from the electronic device D again. The working vapor 2a evaporated from the working liquid 2b passes through the communication groove 65 within the evaporation region SR to the first vapor channel recess 53 and the second vapor channel recess 54, each of which has a large channel cross-sectional area. Then, the working vapor 2a diffuses within each of the vapor channel recesses 53 and 54, and a portion of the working vapor 2a is allowed to diffuse smoothly from the first region 5 to the second region 6 by passing through the reinforcement region 7 including the bend region 7a. In this way, the working fluids 2a and 2b undergo refluxing within the hermetically sealed space 3 while repeating phase changes, that is, evaporation and condensation. Heat from the electronic device D is thus diffused and released. As a result, the electronic device D is cooled.

As described above, according to the first embodiment, the land parts 33 extend in the X-direction from the first region 5 to the second region 6 via the reinforcement region 7. Each second vapor passage 52 defined between mutually adjacent land parts 33 is provided with the reinforcement part 37 extending from the first sheet 10 to the second sheet 20. Such reinforcement parts 37 are located in the bend region 7a where the vapor chamber 1 is bent, and arranged along the bend line 8. The above-mentioned configuration can reduce, in the bend region 7a, a deformation of the first sheet 10 and the second sheet 20 that causes these sheets to extend into the second vapor passage 52, and can reinforce the second vapor passage 52 in the bend region 7a. The above-mentioned configuration can therefore reduce collapse of the second vapor passage 52, and consequently can reduce the channel resistance of the second vapor passage 52. This can reduce impediment to the flow of the working vapor 2a even when the vapor chamber 1 is bent, and consequently can improve the heat dissipation efficiency of the vapor chamber 1. The presence of the reinforcement part 37 in the second vapor passage 52 allows for increased capillary action to facilitate flow from the second vapor passage 52 to the first liquid channel part 60. This can reduce stagnation of the working liquid 2b in the second vapor passage 52 in the bend region 7a, and consequently reduce impediment to the flow of the working vapor 2a. As a result, the heat dissipation efficiency of the vapor chamber 1 can be improved. Further, in the bending step, the reinforcement part 37 can be used as a visual indication in determining where the bend line 8 is positioned. This allows for improved efficiency of bending operation.

According to the first embodiment, the reinforcement part 37 includes two protrusions 38, each of which protrudes in the Y-direction from the corresponding one of two land parts 33 defining the second vapor passage 52. Consequently, in the reinforcement region 7, the second vapor passage 52 can be reduced in width, and the second vapor passage 52 can be reinforced. This can reduce collapse of the second vapor passage 52 in the reinforcement region 7 even when the vapor chamber 1 is bent, and consequently can reduce the channel resistance of the second vapor passage 52.

According to the first embodiment, the first body face 30a of the land part 33 is provided with the first liquid channel part 60 including the main flow groove 61 and the communication groove 65. The protrusion 38 is defined by the first body face 30a and the second body face 30b, and constitutes the wick sheet 30. The second liquid channel part 70 including the main flow groove 71 and the communication groove 75 is located at the first body face 30a of the protrusion 38. The second liquid channel part 70 communicates with the vapor channel part 50 and the first liquid channel part 60. Consequently, the working liquid 2b condensed within the second vapor passage 52 in the reinforcement region 7 is allowed to move to the second liquid channel part 70. The working liquid 2b can be thus transported smoothly toward the evaporation region SR. This can reduce stagnation of the working liquid 2b in the second vapor passage 52 in the bend region 7a, and consequently can reduce impediment to the flow of the working vapor 2a.

According to the first embodiment, the bend line 8 is aligned with the Y-direction orthogonal to the X-direction. With this configuration, even when the vapor chamber 1 is bent along the bend line 8 extending in the Y-direction, the vapor passages 51 and 52 can be reinforced by the reinforcement part 37. This can as well reduce collapse of the vapor passages 51 and 52.

According to the first embodiment, the land parts 33 extend in the X-direction from the first region 5 to the second region 6 via the reinforcement region 7. Each second vapor passage 52 defined between mutually adjacent land parts 33 is provided with the reinforcement part 37 extending from the first sheet 10 to the second sheet 20. Such reinforcement parts 37 are located in the reinforcement region 7, and arranged along a direction crossing the X-direction. The above-mentioned configuration can reduce, in the reinforcement region 7, a deformation of the first sheet 10 and the second sheet 20 that causes these sheets to extend into the second vapor passage 52, and can reinforce the second vapor passage 52 in the reinforcement region 7. This makes it possible to, even when the vapor chamber 1 is bent in the reinforcement region 7 along the bend line 8 extending in a direction crossing the X-direction, reduce collapse of the second vapor passage 52, and consequently reduce the channel resistance of the second vapor passage 52. This in turn makes it possible to, even when the vapor chamber 1 is bent, reduce impediment to the flow of the working vapor 2a, and consequently improve the heat dissipation efficiency of the vapor chamber 1.

The foregoing description of the first embodiment is directed to the example in which the reinforcement part 37 includes two protrusions 38 each protruding from the corresponding one of two land parts 33 defining the second vapor passage 52. However, the present disclosure is not limited to such a configuration. For example, the reinforcement part 37 may include the protrusion 38 protruding from one of two land parts 33 that define the second vapor passage 52. In this case, the reinforcement part 37 may include no protrusion 38 protruding from the other land part 33. In this case as well, the second vapor passage 52 in the reinforcement region 7 can be reinforced. This makes it possible to, even when the vapor chamber 1 is bent in the reinforcement region 7, reduce collapse of the second vapor passage 52, and consequently reduce the channel resistance of the second vapor passage 52.

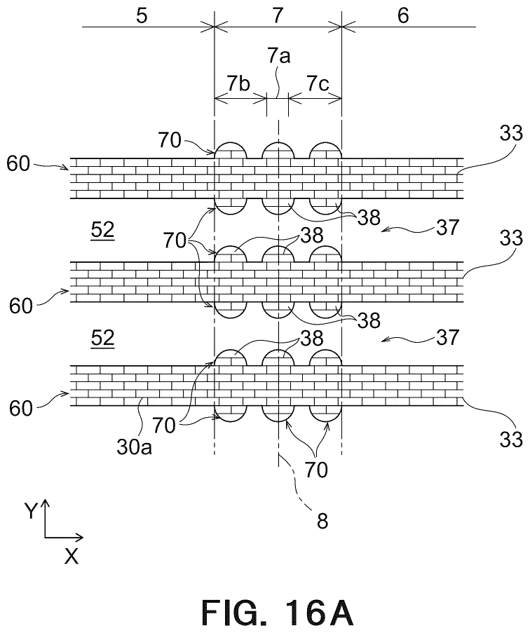

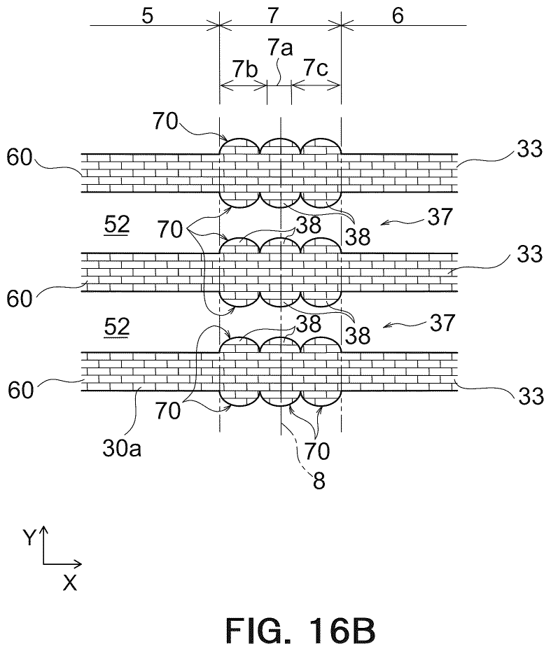

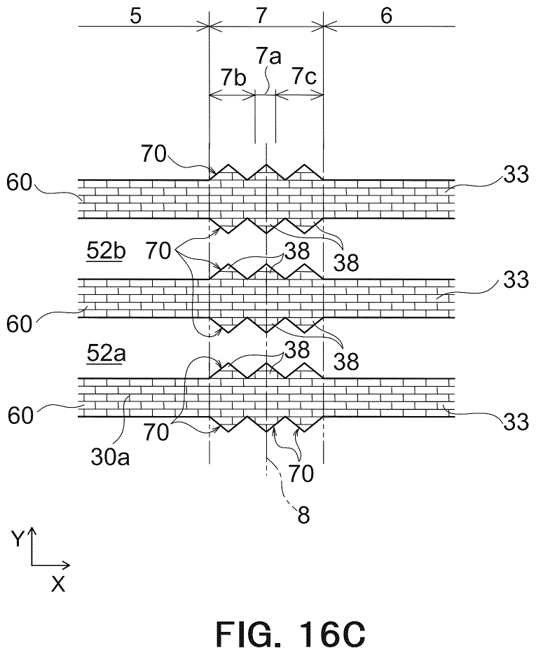

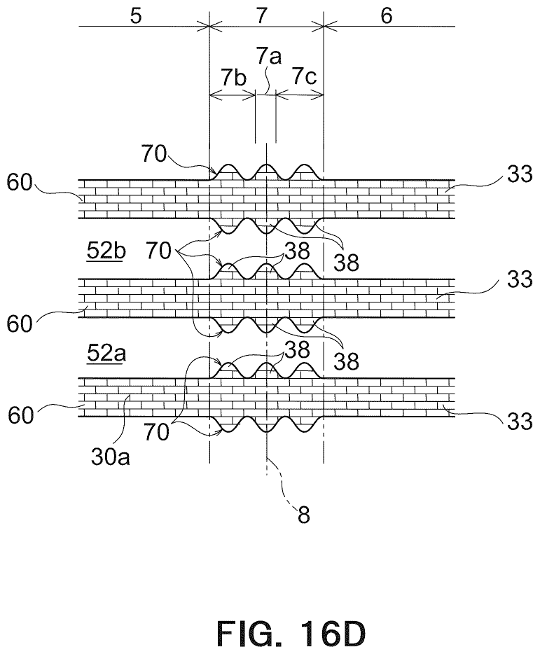

The foregoing description of the first embodiment is directed to the example in which the protrusion 38 is provided over the entire reinforcement region 7 in the X-direction. However, the present disclosure is not limited to such a configuration. For example, as illustrated in FIG. 16A, the reinforcement region 7 may be provided with a plurality of protrusions 38 spaced apart from each other in the X-direction. This configuration can reduce collapse of the second vapor passage 52 even when the vapor chamber 1 is bent in the reinforcement region 7. Although the protrusion 38 is depicted in FIG. 16A as being located in the bend region 7a, the protrusion 38 does not have to be located in the bend region 7a. In such a case as well, the presence of the protrusion 38 near the bend region 7a enables reinforcement of the second vapor passage 52. The spaced arrangement of the protrusions 38 in the X-direction can facilitate bending of the vapor chamber 1. Although each protrusion 38 is depicted in FIG. 16A as having a semi-circular shape in plan view, the protrusion 38 may have any shape in plan view without being limited to the semi-circular shape.

The protrusions 38 may be configured such that, unlike in the case of the example depicted in FIG. 16A, the protrusions 38 are not spaced apart in the X-direction. For example, as illustrated in FIG. 16B, two protrusions 38 that are adjacent to each other in the X-direction may be connected to each other with no spacing therebetween. This configuration makes it possible to further reinforce the reinforcement region 7, and consequently reduce collapse of the second vapor passage 52. In the example depicted in FIG. 16B, each protrusion 38 may have a semi-circular shape in plan view. If the protrusion 38 has a semi-circular shape in plan view, the channel resistance of the second vapor passage 52 can be reduced. Each protrusion 38 may have any shape in plan view. For example, the shape of each protrusion 38 in plan view may be a triangle as illustrated in FIG. 16C. In this case as well, the channel resistance of the second vapor passage 52 can be reduced. Alternatively, as illustrated in FIG. 16D, each of the protrusions 38 may have a curved shape in plan view such that the protrusions 38 are in a corrugated configuration in plan view. In this case as well, the channel resistance of the second vapor passage 52 can be reduced.

The foregoing description of the first embodiment is directed to the example in which the second body face 30b of the land part 33, and the second body face 30b of the frame part 32 are provided with no liquid channel part. However, the present disclosure is not limited to such a configuration. For example, the second body face 30b of the land part 33 may be provided with a liquid channel part (not illustrated). As with the first liquid channel part 60 described above, the liquid channel part may include the main flow grooves 61, and the communication grooves 65. Each groove of the liquid channel part provided in the second body face 30b may have a channel cross-sectional area equal to the channel cross-sectional area of each groove of the first liquid channel part 60, or may have a channel cross-sectional area greater than the channel cross-sectional area of each groove of the first liquid channel part 60. If the second body face 30b is provided with a liquid channel part, the first body face 30a may be provided with no first liquid channel part 60.

The foregoing description of the first embodiment is directed to the example in which in the vapor chamber 1, the second sheet 20 is located inward relative to the wick sheet 30. However, the present disclosure is not limited to such a configuration. For example, the vapor chamber 1 may be bent in such a way that the first sheet 10 is located inward relative to the wick sheet 30. In this case as well, a liquid channel part similar to the first liquid channel part 60 mentioned above may be provided in the first body face 30a or the second body face 30b of the wick sheet 30, or may be provided in both the first body face 30a and the second body face 30b.

The foregoing description of the first embodiment is directed to the example in which the electronic device D is in contact with the second-sheet outer face 20b, and the housing component Ha is in contact with the first-sheet outer face 10a. This, however, is not intended to be limiting. Alternatively, the electronic device D may be in contact with the first-sheet outer face 10a, and the housing component Ha may be in contact with the second-sheet outer face 20b. In this case as well, a liquid channel part similar to the first liquid channel part 60 mentioned above may be provided in the first body face 30a or the second body face 30b of the wick sheet 30, or may be provided in both the first body face 30a and the second body face 30b. The vapor chamber 1 may be bent in such a way that the second sheet 20 is located inward relative to the wick sheet 30, or may be bent in such a way that the first sheet 10 is located inward relative to the wick sheet 30.

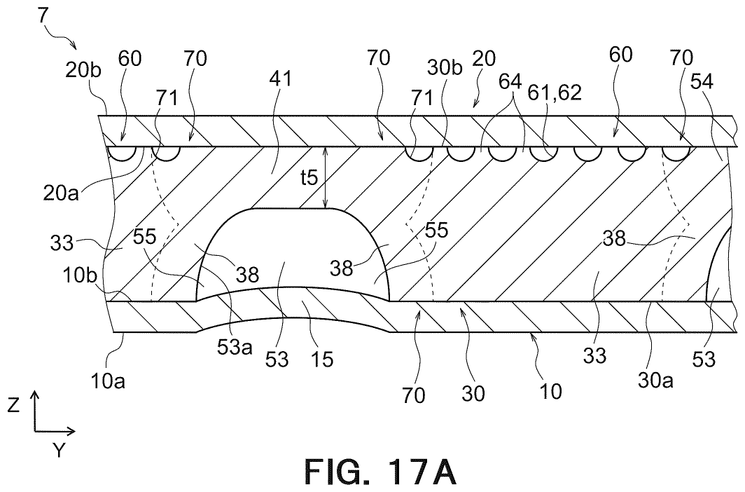

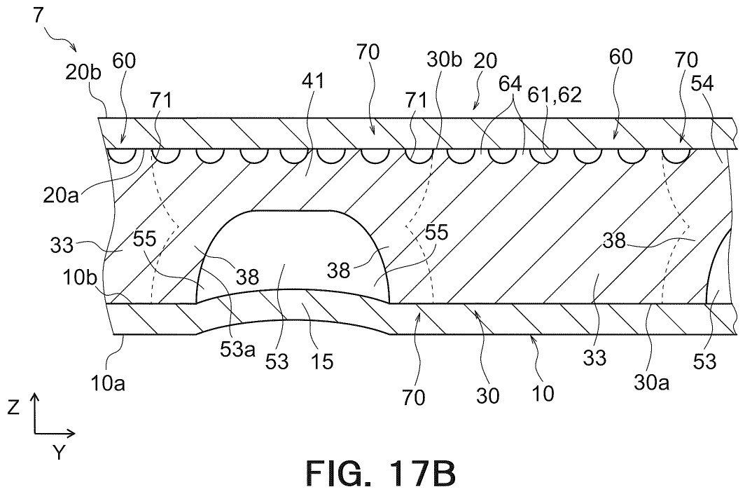

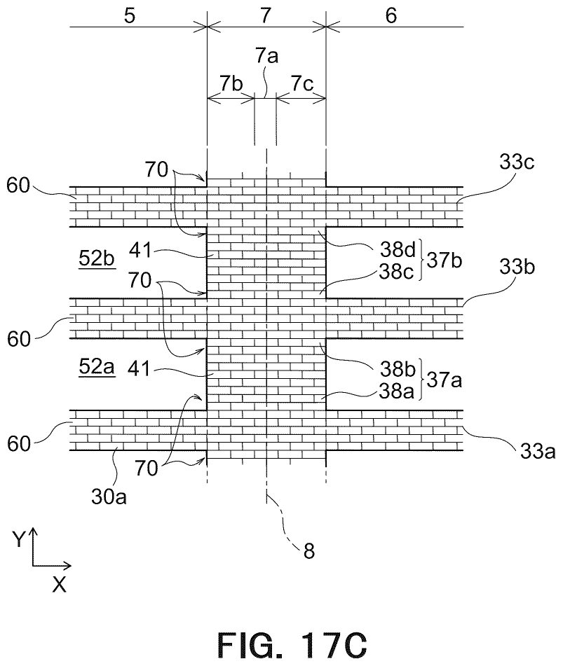

The foregoing description of the first embodiment is directed to the example in which two protrusions 38 located in a single second vapor passage 52 are spaced apart from each other in the Y-direction. However, the present disclosure is not limited to such a configuration. For example, as illustrated in FIG. 17A, such two protrusions 38 may be connected by a bridge part 41. In this case, the second vapor passage 52 in the bend region 7a can be further reinforced. This can further reduce collapse of the second vapor passage 52 even when the vapor chamber 1 is bent, and consequently can further reduce the channel resistance of the second vapor passage 52.

The bridge part 41 may be provided in a manner that does not obstruct the flow of the working vapor 2a that diffuses in the second vapor passage 52. FIG. 17A depicts an example in which the first liquid channel part 60 and the second liquid channel part 70 are provided not in the first body face 30a of the wick sheet 30 but in the second body face 30b. In this case, the bridge part 41 may be provided at the second body face 30b, and no second vapor channel recess 54 may be provided. The first body face 30a is provided with the first vapor channel recess 53. The bridge part 41 can be thus made to have a thickness 15 less than the thickness t4 (see FIG. 6) of the wick sheet 30. This makes it possible to prevent the second vapor passage 52 from being split into separate parts. One exemplary way to form the bridge part 41 illustrated in FIG. 17A may be to, in etching the second body face 30b of the wick sheet 30, leave the second body face 30b unetched at a location where the bridge part 41 is to be provided.

Unlike in the case of the example illustrated in FIG. 17A, the first liquid channel part 60 and the second liquid channel part 70 may be provided not in the second body face 30b of the wick sheet 30 but in the first body face 30a. In this case, the bridge part 41 may be provided at the first body face 30a, and no first vapor channel recess 53 may be provided. The second body face 30b may be provided with the second vapor channel recess 54.

If the first liquid channel part 60 and the second liquid channel part 70 are provided in both the first body face 30a and the second body face 30b, the bridge part 41 may be provided at one of the first body face 30a and the second body face 30b.

In the example depicted in FIG. 17A, the second body face 30b of the bridge part 41 is not provided with grooves constituting a channel for the working liquid 2b. Alternatively, as illustrated in FIG. 17B, the second body face 30b of the bridge part 41 may be provided with such grooves. FIG. 17B depicts an example in which the second body face 30b of the bridge part 41 is provided with the main flow grooves 71 constituting the second liquid channel part 70. The main flow grooves 71 may extend in the X-direction. Mutually adjacent main flow grooves 71 may be communicated with each other by the communication groove 75 (see FIG. 13). According to the example illustrated in FIG. 17B, the first liquid channel parts 60 each provided in the corresponding one of two mutually adjacent land parts 33 are allowed to communicate with each other by means of the second liquid channel part 70 provided in the bridge part 41. The working liquid 2b is thus allowed to move back and forth between two first liquid channel parts 60 that are adjacent to each other. This can improve the capacity with which the working liquid 2b is transported to the evaporation region SR.

As illustrated in FIG. 17C, the bridge part 41 may have a dimension in the X-direction equal to the dimension of the protrusion 38 in the X-direction. The bridge part 41 may be provided in such a way that in plan view, the bridge part 41 extends contiguously from the protrusion 38. However, the dimension of the bridge part 41 in the X-direction is not limited to the dimension mentioned above. For example, the bridge part 41 may have a dimension in the X-direction less than the dimension of the protrusion 38 in the X-direction, or may have a dimension in the X-direction greater than the dimension of the protrusion 38 in the X-direction.

The foregoing description of the first embodiment is directed to the example in which the entire bend region 7a overlaps the reinforcement region 7, and the reinforcement region 7 extends out on both sides of the bend region 7a in the X-direction. However, the present disclosure is not limited to such a configuration. For example, only a portion of the bend region 7a may overlap the reinforcement region 7, and the bend region 7a may include a portion that does not overlap the reinforcement region 7. The bend region 7a may have a dimension in the X-direction greater than the dimension of the reinforcement region 7 in the X-direction. In this case as well, due to the presence of the reinforcement region 7 in a portion of the bend region 7a, the second vapor passage 52 in the bend region 7a can be reinforced. The bend region 7a may have a dimension in the X-direction such that the bend region 7a extends out on both sides of the reinforcement region 7 in the X-direction. Alternatively, the bend region 7a may have a dimension in the X-direction equal to the dimension of the reinforcement region 7 in the X-direction. In this case, the entire bend region 7a in the X-direction may overlap the entire reinforcement region 7.

### Second Embodiment

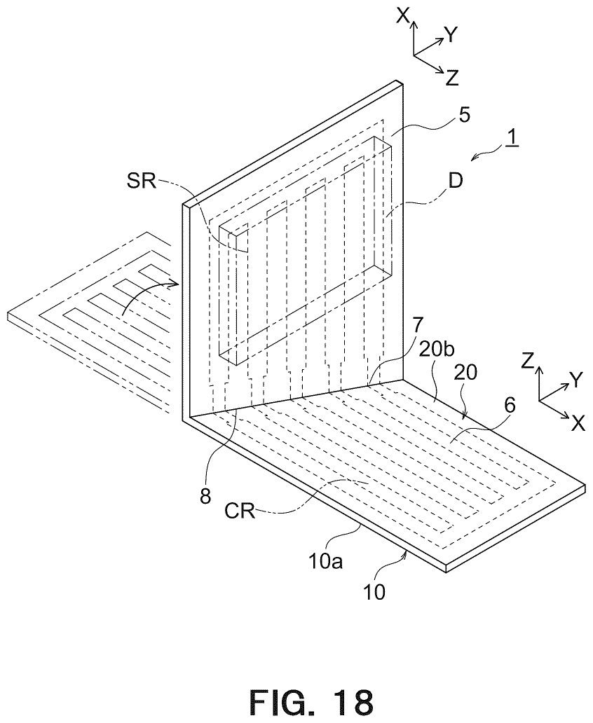

Now, reference is made to FIGS. 18 to 20 to describe a vapor chamber, an electronic apparatus, and a body sheet for a vapor chamber according to a second embodiment of the present disclosure.

The second embodiment illustrated in FIGS. 18 to 20 differs mainly in that reinforcement parts are arranged along a direction inclined relative to the first direction. The second embodiment is otherwise substantially identical in configuration to the first embodiment illustrated in FIGS. 1 to 17C. Features in FIGS. 18 to 20 that are identical to those according to the first embodiment illustrated in FIGS. 1 to 17C are designated by the same reference signs and not described in further detail.

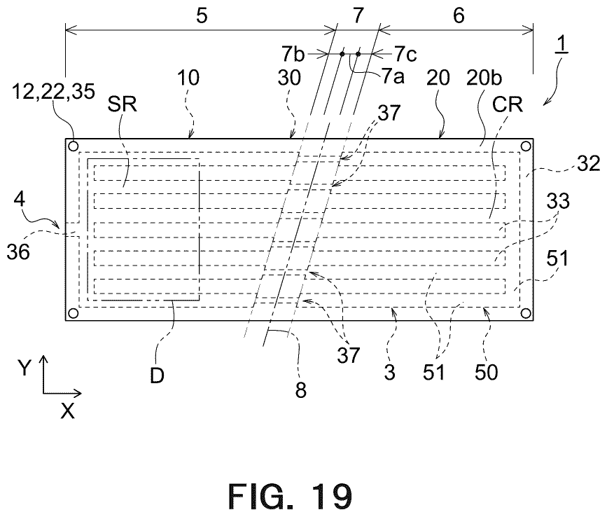

According to the second embodiment, as illustrated in FIGS. 18 and 19, the reinforcement parts 37 located in the vapor passages 51 and 52 are arranged along a direction inclined relative to the X-direction. The reinforcement parts 37 are arranged along the bend line 8 described later. The reinforcement parts 37 may be positioned offset relative to each other in the X-direction. Of two reinforcement parts 37 adjacent to each other in the Y-direction in FIG. 19, the reinforcement part 37 located higher in FIG. 19 is offset to the right relative to the reinforcement part 37 located lower in FIG. 19.

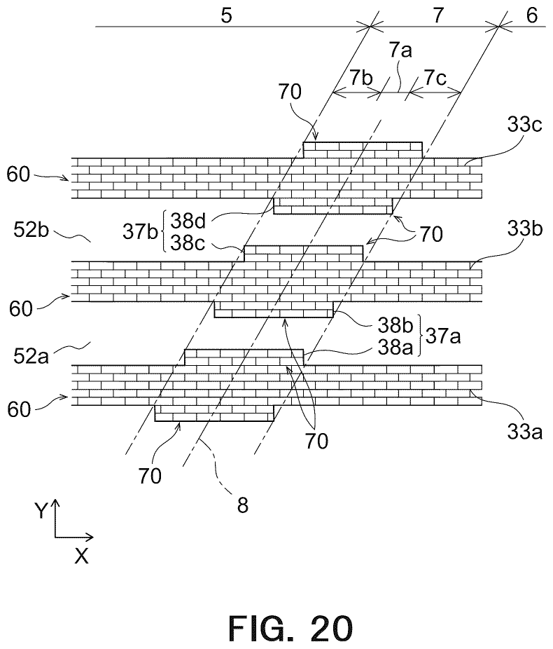

As illustrated in FIG. 20, the reinforcement part 37 includes two protrusions 38, each of which protrudes from the corresponding one of two land parts 33 defining the second vapor passage 52. Two protrusions 38 located in a single second vapor passage 52 may be positioned offset relative to each other in the X-direction. Each of the protrusions 38 may have the same dimension in the X-direction.

As illustrated in FIG. 20, the protrusions 38a to 38d are positioned offset relative to each other in the X-direction. The first protrusion 38a and the second protrusion 38b that constitute a single reinforcement part 37a are positioned offset relative to each other in the X-direction. The second protrusion 38b and the third protrusion 38c that protrude from a single land part 33b are positioned offset relative to each other in the X-direction. The third protrusion 38c and the fourth protrusion 38d that constitute a single reinforcement part 37b are positioned offset relative to each other in the X-direction.

As described above, the protrusions 38 are gradually offset relative to each other in the X-direction. The reinforcement parts 37 are thus arranged along a direction inclined relative to the X-direction.

As illustrated in FIG. 18, the vapor chamber 1 according to the second embodiment is bent along the bend line 8 that is inclined relative to the X-direction in plan view. The bend line 8 illustrated in FIG. 18 is inclined relative to the X-direction, and also inclined relative to the Y-direction. The bend line 8 illustrated in FIG. 18 as well extends in a direction crossing the X-direction in plan view. The reinforcement parts 37 are arranged along the bend line 8. The reinforcement region 7 illustrated in FIG. 20 may be defined as an area in the X-direction where the protrusion 38 is present. As illustrated in FIG. 20, the reinforcement region 7 may be defined as a region extending in a direction inclined relative to the X-direction. In this case, the bend region 7a may be a region that extends along the bend line 8 in a direction inclined relative to the X-direction. In the example illustrated in FIG. 20, the bend region 7a may be sectioned off by boundary lines extending in a direction inclined relative to the X-direction in plan view.

As described above, according to the second embodiment, the bend line 8 extends in a direction inclined relative to the X-direction. The reinforcement parts 37 are arranged along the bend line 8. With this configuration, even when the vapor chamber 1 is bent along the bend line 8 extending in a direction inclined relative to the X-direction, the vapor passages 51 and 52 can be reinforced by the reinforcement part 37. This can as well reduce collapse of the vapor passages 51 and 52.

### Third Embodiment

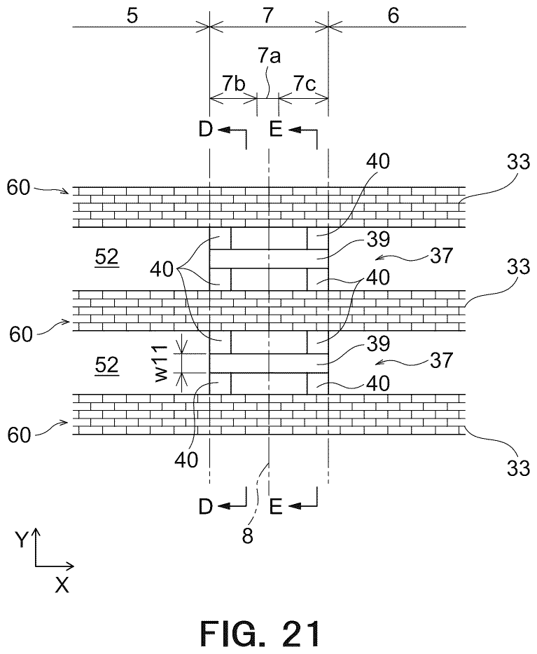

Now, reference is made to FIGS. 21 to 27B to describe a vapor chamber, an electronic apparatus, and a body sheet for a vapor chamber according to a third embodiment of the present disclosure.

The third embodiment illustrated in FIGS. 21 to 27B differs mainly in that the reinforcement part includes a reinforcement land part spaced apart from the land part. The third embodiment is otherwise substantially identical in configuration to the first embodiment illustrated in FIGS. 1 to 17C. Features in FIGS. 21 to 27B that are identical to those according to the first embodiment illustrated in FIGS. 1 to 17C are designated by the same reference signs and not described in further detail.

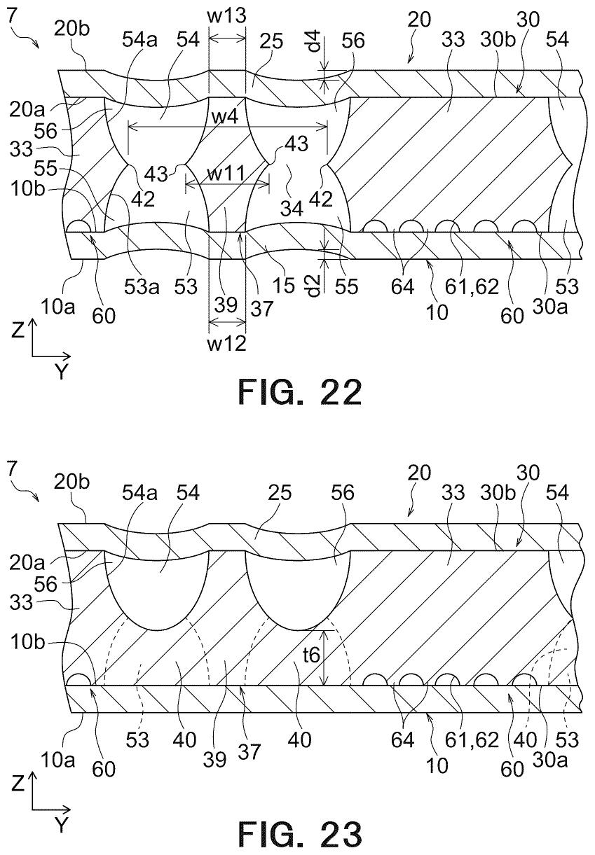

According to the third embodiment, as illustrated in FIGS. 21 and 22, the reinforcement part 37 includes a reinforcement land part 39 spaced apart from the land part 33. The reinforcement land part 39 is located in the reinforcement region 7, and may be columnar in form. A single reinforcement land part 39 is located in each of the vapor passages 51 and 52. The reinforcement land part 39 may constitute the wick sheet 30. The reinforcement land part 39 may be formed through etching as a structural part of the wick sheet 30. More specifically, the reinforcement land part 39 may be a part where the material of the wick sheet 30 remains without being etched away in an etching step (described later). The side wall of the reinforcement land part 39 may be defined by a wall face that is similar to the wall face 53a of the first vapor channel recess 53 and to the wall face 54a of the second vapor channel recess 54.

The reinforcement parts 37 located in the corresponding vapor passages 51 and 52 may be arranged along a predetermined direction crossing the X-direction. According to the third embodiment, the reinforcement parts 37 are arranged along the Y-direction. The Y-direction is a direction orthogonal to the X-direction in plan view. Each reinforcement land part 39 is located at the same position in the X-direction. Each reinforcement land part 39 may have the same dimension in the X-direction.

As illustrated in FIG. 21, in plan view, the reinforcement land part 39 may have a side aligned with the X-direction, and a side aligned with the Y-direction. The reinforcement land part 39 may be provided over the entire reinforcement region 7 in the X-direction. In other words, the reinforcement region 7 may be defined as an area in the X-direction where the reinforcement land part 39 is present. As illustrated in FIG. 21, the reinforcement region 7 may be defined as a region extending in the Y-direction.

The reinforcement land part 39 is defined in the Z-direction by the first body face 30a and the second body face 30b of the wick sheet 30. The reinforcement land part 39 extends in the Z-direction from the first body face 30a to the second body face 30b. The reinforcement land part 39 is diffusion-bonded to the first-sheet inner face 10b of the first sheet 10, and diffusion-bonded to the second-sheet inner face 20a of the second sheet 20.

As illustrated in FIG. 22, due to the presence of the reinforcement land part 39, the second vapor passage 52 in the reinforcement region 7 has an improved mechanical strength. The first body face 30a of the reinforcement land part 39 may be provided with no second liquid channel part 70. In the reinforcement land part 39, the first body face 30a and the second body face 30b may have a flat shape.

As illustrated in FIG. 22, the reinforcement land part 39 may include an extended portion 43. More specifically, as with the land part 33, the reinforcement land part 39 includes the wall face 53a that defines the first vapor channel recess 53. As with the land part 33, the reinforcement land part 39 includes the wall face 54a that defines the second vapor channel recess 54. The reinforcement land part 39 includes the extended portion 43 defined by a ridge where the wall face 53a and the wall face 54a meet. As illustrated in FIG. 22, the extended portion 43 may extend out toward the extended portion 42 that faces the extended portion 43. The position of the extended portion 43 in the Z-direction may be the same as the position of the extended portion 42 of the land part 33 in the Z-direction. As illustrated in FIG. 22, the position of the extended portion 43 in the Z-direction may be the midway position between the first body face 30a and the second body face 30b.

As illustrated in FIGS. 21 and 22, the reinforcement land part 39 in the reinforcement region 7 has a width w11. The w11 is a dimension of the reinforcement land part 39 in the Y-direction. The width w11 means a dimension of the wick sheet 30 at a position in the Z-direction of the wick sheet 30 where the through-part 34 mentioned above exists. The width w11 means a dimension from the extended portion 43 on one side to the extended portion 43 on the other side. The width w11 is less than the above-mentioned width w4 of the through-part 34 in each of the first region 5 and the second region 6. The width w11 may be, for example, 30 μm to 500 μm.

As illustrated in FIG. 21, a width w12 at the first body face 30a of the reinforcement land part 39 may be equal to a width w13 at the second body face 30b of the reinforcement land part 39. The width w12 is a dimension at the first body face 30a of the reinforcement land part 39 in the Y-direction. The width w13 is a dimension at the second body face 30b of the reinforcement land part 39 in the Y-direction.

As illustrated in FIGS. 21 and 23, the reinforcement land part 39 may be supported to the land part 33 by a reinforcement support 40. Although FIG. 21 depicts an example in which each single reinforcement land part 39 is supported by four reinforcement supports 40, any number of reinforcement supports 40 may be present. The reinforcement support 40 may be provided in a manner that does not obstruct the flow of the working vapor 2a that diffuses in the second vapor passage 52. For example, the reinforcement support 40 may be located near one of the first body face 30a and the second body face 30b of the wick sheet 30, and a space defining the second vapor passage 52 may be provided near the other one of the first body face 30a and the second body face 30b. FIG. 23 depicts an example in which the reinforcement support 40 is provided at the first body face 30a, with no first vapor channel recess 53 provided. The second body face 30b is provided with the second vapor channel recess 54. The reinforcement support 40 can be thus made to have a thickness t6 less than the thickness t4 (see FIG. 6) of the wick sheet 30. This makes it possible to prevent the second vapor passage 52 from being split into separate parts. One exemplary way to form the reinforcement support 40 illustrated in FIG. 23 may be to, in etching the first body face 30a of the wick sheet 30, leave the first body face 30a unetched at a location where the reinforcement support 40 is to be provided.

As illustrated in FIG. 22, the first sheet 10 may include the first-sheet recess 15 overlapping the vapor passage 51 or 52 in plan view. A portion of the first-sheet recess 15 that is bonded to the reinforcement land part 39 does not have to extend into the first vapor channel recess 53. In the reinforcement region 7, the first-sheet recess 15 is provided around the reinforcement land part 39 in plan view. In the reinforcement region 7, the recess dimension d2 of the first-sheet outer face 10a may be less than the recess dimension d2 illustrated in FIG. 14. Likewise, the second sheet 20 may include the second-sheet recess 25 overlapping the vapor passage 51 or 52 in plan view. A portion of the second-sheet recess 25 that is bonded to the reinforcement land part 39 does not have to extend into the second vapor channel recess 54. In the reinforcement region 7, the second-sheet recess 25 is provided around the reinforcement land part 39 in plan view. In the reinforcement region 7, the recess dimension d4 of the second-sheet outer face 20b may be less than the recess dimension d4 illustrated in FIG. 14.

As described above, according to the third embodiment, the reinforcement part 37 includes the reinforcement land part 39 spaced apart from the land part 33. The second vapor passage 52 can be thus reinforced in the reinforcement region 7. This makes it possible to, in the reinforcement region 7, reduce collapse of the second vapor passage 52 even when the vapor chamber 1 is bent, and consequently reduce the channel resistance of the second vapor passage 52. The presence of the reinforcement part 37 in the second vapor passage 52 allows for increased capillary action to facilitate flow from the second vapor passage 52 to the first liquid channel part 60. This can reduce stagnation of the working liquid 2b in the second vapor passage 52 in the bend region 7a, and consequently can reduce impediment to the flow of the working vapor 2a. As a result, the heat dissipation efficiency of the vapor chamber 1 can be improved. Further, in the bending step, the reinforcement part 37 can be used as a visual indication in determining where the bend line 8 is positioned. This allows for improved efficiency of bending operation.

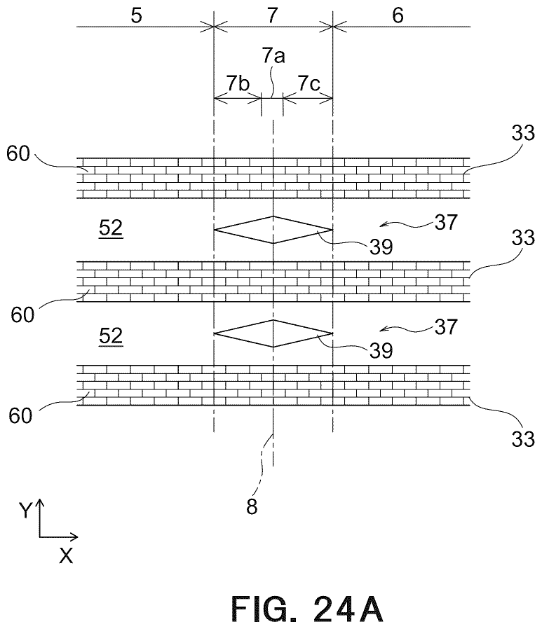

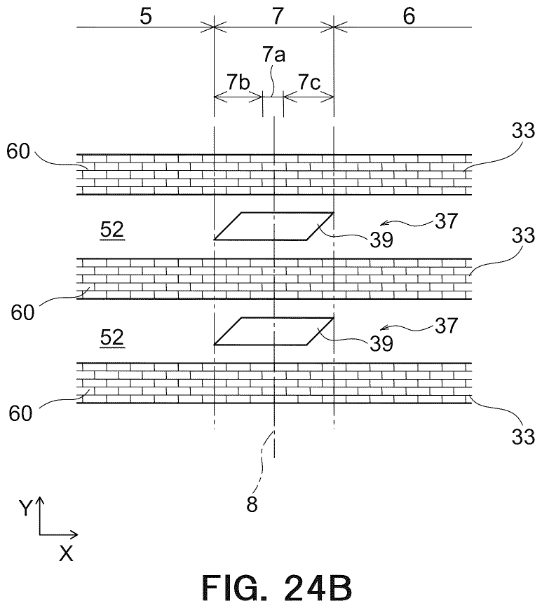

The foregoing description of the third embodiment is directed to the example in which, in plan view, the reinforcement land part 39 has a side aligned with the X-direction, and a side aligned with the Y-direction. However, the present disclosure is not limited to such a configuration. For example, as illustrated in FIG. 24A, the reinforcement land part 39 may have, in plan view, a rhombic shape extending in the X-direction and the Y-direction. This configuration can reduce channel resistance, and consequently can reduce impediment to the flow of the working vapor 2a. The reinforcement land part 39 may have any shape in plan view, such as a circle, an ellipse, or a combination of these shapes. Alternatively, in plan view, the reinforcement land part 39 may have the shape of a parallelogram extending in the X-direction in plan view as illustrated in FIG. 24B. Two opposite sides of the parallelogram may be aligned with the X-direction. The exemplary configuration illustrated in FIG. 24B can reduce channel resistance, and consequently can reduce impediment to the flow of the working vapor 2a.

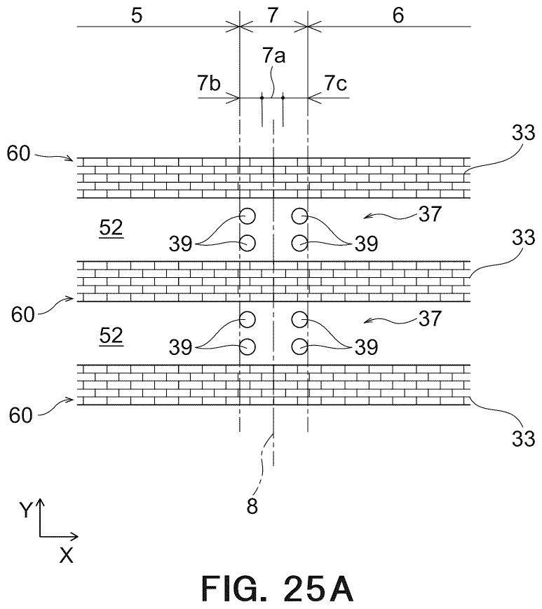

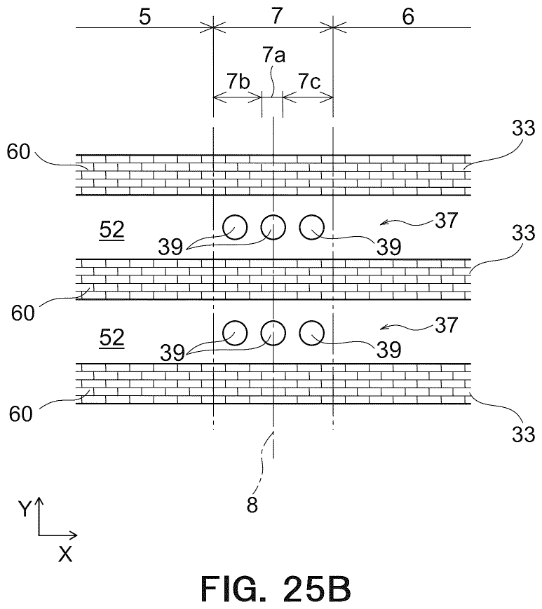

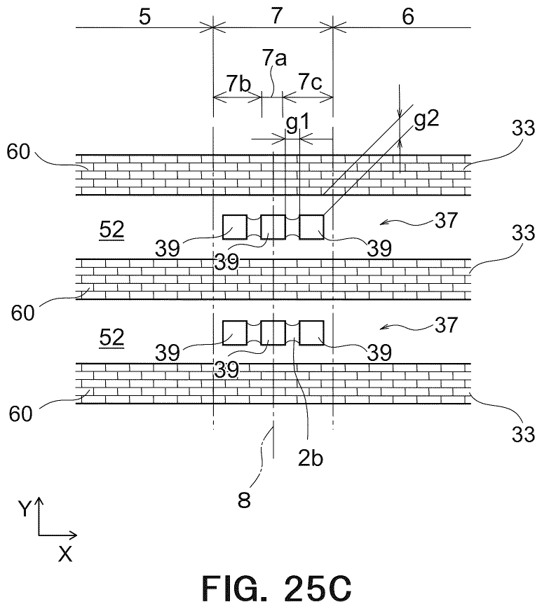

The foregoing description of the third embodiment is directed to the example in which a single reinforcement land part 39 is located in each of the vapor passages 51 and 52. However, the present disclosure is not limited to such a configuration. For example, as illustrated in FIG. 25A, a plurality of reinforcement land parts 39 may be located in each of the vapor passages 51 and 52. In this case, each reinforcement part 37 includes the reinforcement land parts 39. The reinforcement land parts 39 are spaced apart from each other. In this case as well, the second vapor passage 52 can be reinforced in the reinforcement region 7. In the example depicted in FIG. 25A, no reinforcement land part 39 is located in the bend region 7a. However, the presence of the reinforcement land part 39 located near the bend region 7a makes it possible to reinforce the second vapor passage 52. The reinforcement land part 39 may be located in the bend region 7a. The reinforcement region 7 illustrated in FIG. 25A may be defined as an area in the X-direction where the reinforcement land part 39 is present.

The foregoing description of the third embodiment is directed to the example in which the reinforcement land parts 39 are arranged along the Y-direction. However, the present disclosure is not limited to such a configuration. For example, the reinforcement land parts 39 may be arranged along a direction inclined relative to the X-direction as illustrated in FIG. 20 or other figures. Alternatively, as illustrated in FIG. 25B, the reinforcement land parts 39 may be arranged along the X-direction. This configuration allows the reinforcement land part 39 to be positioned in the bend region 7a. As a result, the second vapor passage 52 can be further reinforced. The shape of the reinforcement land part 39 in plan view may be a circle as illustrated in FIG. 25B, or may be a rectangle as illustrated in FIG. 25C. If the shape of the reinforcement land part 39 in plan view is a rectangle, the working liquid 2b can be drawn through capillary action into the space between two reinforcement land parts 39 that are adjacent to each other in the X-direction. This can reduce stagnation of the working liquid 2b in the space between the reinforcement land part 39 and the land part 33. In this case, an adequate cross-sectional area for the working vapor 2a can be secured, which can reduce impediment to the flow of the working vapor 2a. As illustrated in FIG. 25C, a gap g1 may be less than a gap g2. The gap g1 is a dimension in the X-direction of two reinforcement land parts 39 that are adjacent to each other in the X-direction. The gap 92 is a dimension in the Y-direction between the reinforcement land part 39 and the land part 33. The configuration described above allows for increased capillary action in the space between two mutually adjacent reinforcement land parts 39.

The foregoing description of the third embodiment is directed to the example in which the reinforcement land part 39 constitutes the wick sheet 30, and is formed through etching. However, the present disclosure is not limited to such a configuration. The reinforcement part 37 may be provided in the first sheet 10 or the second sheet 20. For example, the reinforcement part 37 may be formed at the first-sheet inner face 10b of the first sheet 10 by plating in such a way that the reinforcement part 37 protrudes from the first-sheet inner face 10b. In this case, a face of the reinforcement part 37 that faces the second sheet 20 may be diffusion-bonded to the second sheet 20. Alternatively, the reinforcement part 37 may be formed at the second-sheet inner face 20a of the second sheet 20 by plating in such a way that the reinforcement part 37 protrudes from the second-sheet inner face 20a. Alternatively, the reinforcement part 37 may include a first reinforcement section (not illustrated) provided at the first sheet 10, and a second reinforcement section (not illustrated) provided at the second sheet 20. In this case, the first reinforcement section may be formed by plating in such a way that the first reinforcement section protrudes from the first-sheet inner face 10b of the first sheet 10. The second reinforcement section may be formed by plating in such a way that the second reinforcement section protrudes from the second-sheet inner face 20a of the second sheet 20. The first reinforcement section and the second reinforcement section may be diffusion-bonded together to form the reinforcement part 37.

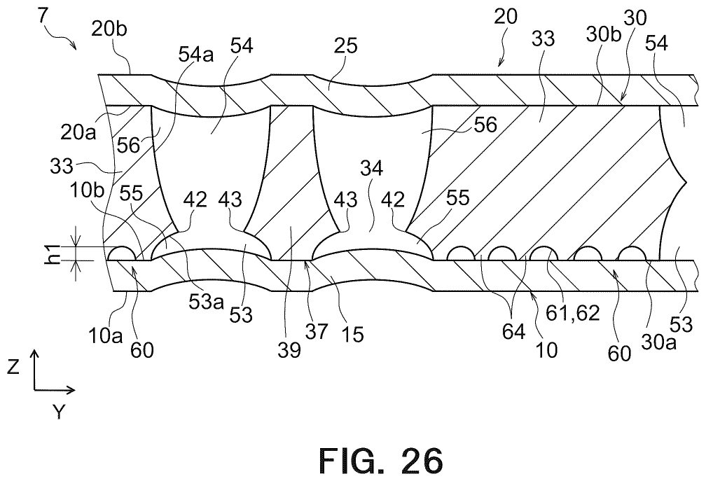

The foregoing description of the third embodiment is directed to the example in which in the Z-direction, each of the extended portion 42 and the extended portion 43 is located at the midway position between the first body face 30a and the second body face 30b. However, the present disclosure is not limited to such a configuration. For example, as illustrated in FIG. 26, each of the extended portion 42 and the extended portion 43 may be located at a position in the Z-direction that is closer to the first sheet 10 than is the midway position. This configuration makes it possible to increase the capillary action of the first vapor channel recess 53 located between the first sheet 10 and each of the extended portions 42 and 43. The working liquid 2b condensed within the second vapor passage 52 in the bend region 7a is thus allowed to move from the second vapor passage 52 to the first liquid channel part 60. This can improve the capacity with which the working liquid 2b is transported to the evaporation region SR. Further, if each of the extended portions 42 and 43 is located at a position closer to the first sheet 10 than is the midway position as described above, this makes it possible to increase the channel cross-sectional area of the second vapor channel recess 54, and consequently reduce the channel resistance for the working vapor 2a in the second vapor channel recess 54.

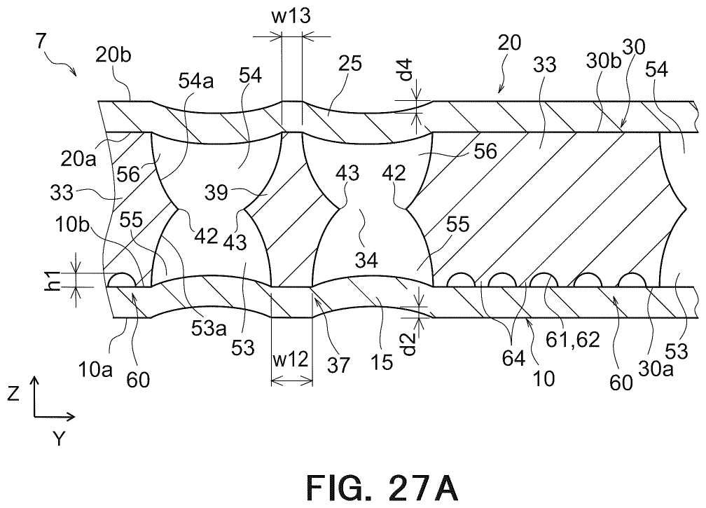

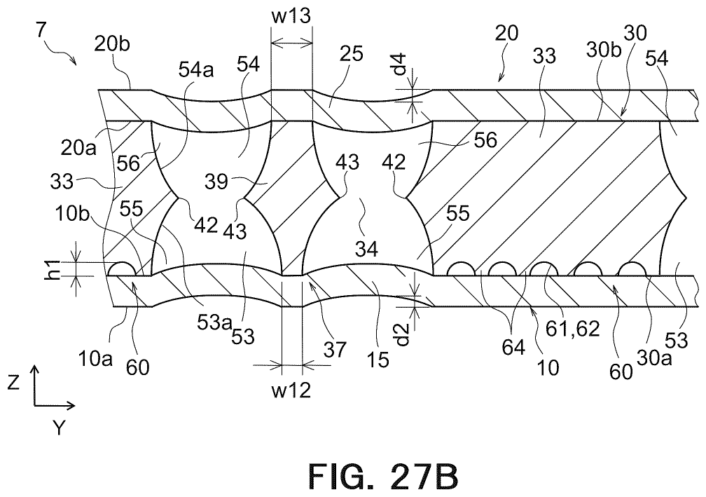

The foregoing description of the third embodiment is directed to the example in which the width w12 at the first body face 30a of the reinforcement land part 39 is equal to the width w13 at the second body face 30b of the reinforcement land part 39. However, the present disclosure is not limited to such a configuration. For example, as illustrated in FIG. 27A, the width w13 may be less than the width w12. This configuration allows the reinforcement land part 39 to occupy a relatively small area of the second vapor channel recess 54. The second-sheet recess 25 can be thus formed easily. Consequently, the recess dimension d4 of the second-sheet outer face 20b can be increased. This makes it possible to, if the second sheet 20 is located at the inner side of the bend, increase the capillary action of the channel corner 56 of the second vapor channel recess 54. The resulting ability to reduce stagnation of the working liquid 2b in the second vapor passage 52 in the bend region 7a can reduce impediment to the flow of the working vapor 2a. This means that if the first liquid channel part 60 is provided at the second body face 30b of the wick sheet 30, the working liquid 2b is allowed to quickly move to the first liquid channel part 60.

As illustrated in FIG. 27A, if the width w13 is less than the width w12, this means that the width w12 can be made greater than the width w13. This configuration allows the reinforcement land part 39 to occupy a relatively large area of the first vapor channel recess 53. The second vapor passage 52 can be thus further reinforced. This makes it possible to, even when the vapor chamber 1 is bent, reduce collapse of the first vapor channel recess 53 in the reinforcement region 7, and consequently reduce the channel resistance for the working vapor 2a in the first vapor channel recess 53. This means that if the first liquid channel part 60 is provided at the first body face 30a of the wick sheet 30, the working vapor 2a evaporated in the first liquid channel part 60 can be smoothly diffused in the first vapor channel recess 53.

Unlike with the example illustrated in FIG. 27A, the width w13 may be greater than the width w12 as illustrated in FIG. 27B. This configuration allows the reinforcement land part 39 to occupy a relatively large area of the second vapor channel recess 54. The second vapor passage 52 can be thus further reinforced. This makes it possible to, in the reinforcement region 7, reduce collapse of the second vapor channel recess 54 even when the vapor chamber 1 is bent, and consequently reduce the channel resistance for the working vapor 2a in the second vapor channel recess 54. This means that if the first liquid channel part 60 is provided at the second body face 30b of the wick sheet 30, the working vapor 2a evaporated in the first liquid channel part 60 can be smoothly diffused in the second vapor channel recess 54.

As illustrated in FIG. 27B, if the width w13 is greater than the width w12, this means that the width w12 can be made less than the width w13. This configuration allows the reinforcement land part 39 to occupy a relatively small area of the first vapor channel recess 53. The first-sheet recess 15 can be thus formed easily. Consequently, the recess dimension d2 of the first-sheet outer face 10a can be increased. This makes it possible to, if the first sheet 10 is located at the outer side of the bend, increase the capillary action of the channel corner 55 of the first vapor channel recess 53. The resulting ability to reduce stagnation of the working liquid 2b in the second vapor passage 52 in the bend region 7a can reduce impediment to the flow of the working vapor 2a. This means that if the first liquid channel part 60 is provided at the first body face 30a of the wick sheet 30, the working liquid 2b is allowed to quickly move to the first liquid channel part 60.

### Fourth Embodiment

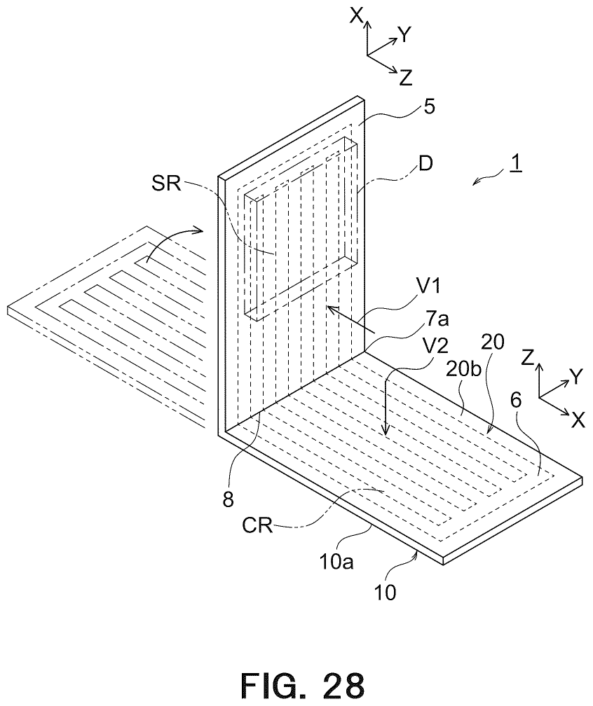

Now, reference is made to FIGS. 28 to 37B to describe a vapor chamber, an electronic apparatus, and a body sheet for a vapor chamber according to a fourth embodiment of the present disclosure.

The fourth embodiment illustrated in FIGS. 28 to 37B differs mainly in the following respects: the first liquid channel part includes a low-density region with a comparatively small number of communication grooves, and a high-density region with a comparatively large number of communication grooves; and the high-density region is located in the bend region and overlaps the bend line. The fourth embodiment is otherwise substantially identical in configuration to the first embodiment illustrated in FIGS. 1 to 17C. Features in FIGS. 28 to 37B that are identical to those according to the first embodiment illustrated in FIGS. 1 to 17C are designated by the same reference signs and not described in further detail.

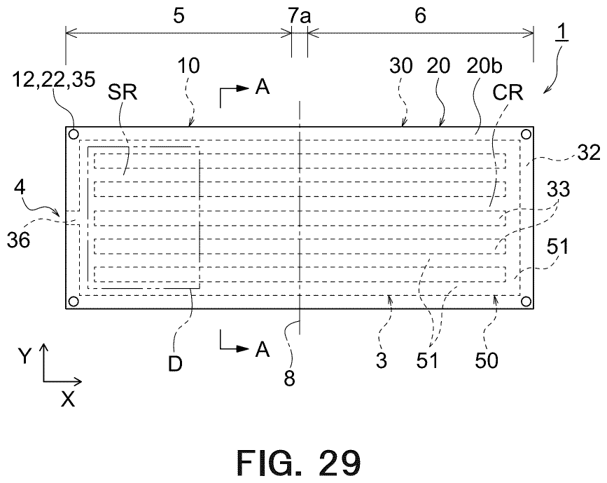

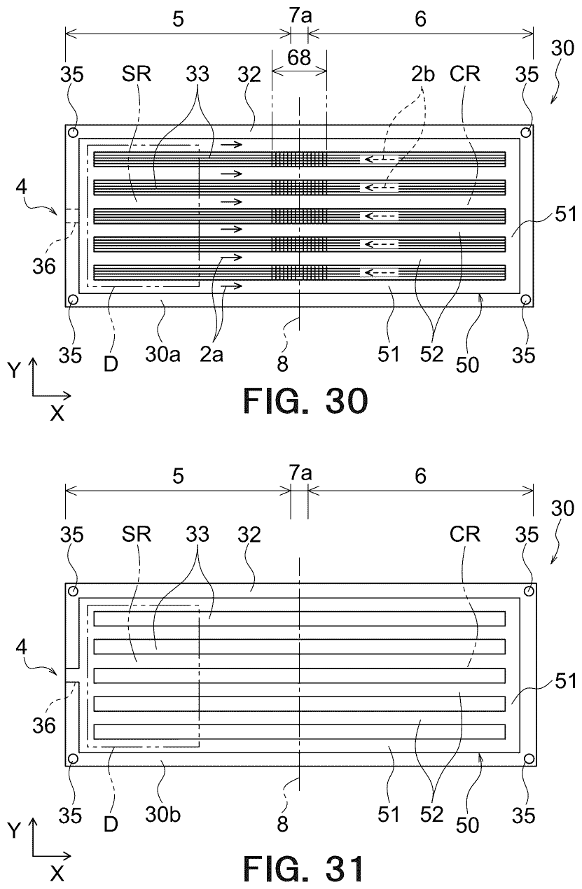

According to the fourth embodiment, the vapor chamber 1 illustrated in FIGS. 28 and 29 is sectioned into the first region 5, the second region 6, and the bend region 7a, which is located between the first region 5 and the second region 6. According to the fourth embodiment, the reinforcement region 7 (see, for example, FIG. 5) is not provided between the first region 5 and the second region 6. In the bend region 7a, the vapor chamber 1 is bent at substantially right angles. As illustrated in FIGS. 28 and 29, according to the fourth embodiment, each first vapor passage 51 and each second vapor passage 52 are not provided with the reinforcement part 37 (see, for example, FIG. 5). The second vapor passage 52 and the land part 33 according to the fourth embodiment are thus depicted in FIGS. 28 to 31 as extending in the form of a straight line. As illustrated in FIG. 30, each land part 33 is provided with a high-density region 68 (described later).

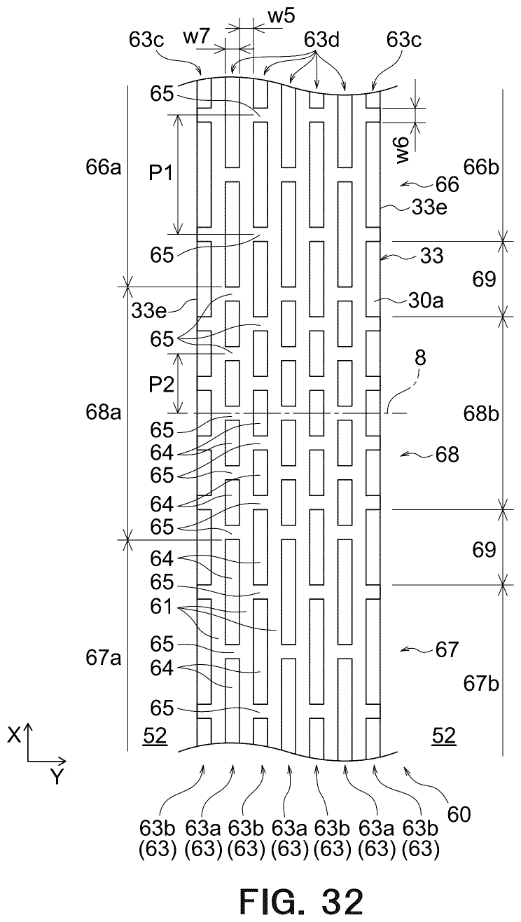

As illustrated in FIG. 32, in low-density regions 66 and 67 and the high-density region 68 (described later), each communication groove 65 according to the fourth embodiment extends in the Y-direction, and is perpendicular to the main flow groove 61. According to the fourth embodiment, the communication groove 65 located in each of the low-density regions 66 and 67 and the high-density region 68 (described later) extends in the Y-direction.

As illustrated in FIG. 32, each of the land parts 33 is provided with a plurality of communication-groove rows 63. In other words, the first liquid channel part 60 includes the communication-groove rows 63. Each communication-groove row 63 includes a plurality of communication grooves 65 arrayed in the X-direction. The communication-groove rows 63 are provided in the first body face 30a of each land part 33. Each of the communication-groove rows 63 is sectioned off by the main flow groove 61.

The first liquid channel part 60 includes a plurality of projections 64 disposed on the first body face 30a of the wick sheet 30. The projections 64 are each provided between the communication grooves 65 that are adjacent to each other in the X-direction. The projections 64 are arrayed in the X-direction in correspondence with each communication-groove row 63. According to the fourth embodiment, as illustrated in FIG. 12, the projection 64 may have a rectangular shape in plan view with its longitudinal direction aligned with the X-direction.

According to the fourth embodiment, the projections 64 are positioned in a staggered arrangement. More specifically, the projections 64 corresponding to a first communication-groove row 63a (described later), which is one of two mutually adjacent communication-groove rows 63 in the Y-direction, are positioned offset in the X-direction relative to the projections 64 corresponding to a second communication-groove row 63b.

As illustrated in FIG. 32, each of the land parts 33 is provided with the communication-groove rows 63. The respective communication grooves 65 of two mutually adjacent communication-groove rows 63 in the Y-direction are positioned offset relative to each other in the X-direction. Of the communication-groove rows 63, such two mutually adjacent communication-groove rows 63 in the Y-direction are defined herein as the first communication-groove row 63a and the second communication-groove row 63b. Each communication groove 65 of the first communication-groove row 63a is positioned offset relative to an extension of communication groove 65 of the second communication-groove row 63b. An extension of the communication groove 65 refers to an imaginary line formed by extending the communication groove 65 in the Y-direction. Accordingly, each communication groove 65 of the first communication-groove row 63a, and the communication groove 65 of the second communication-groove row 63b are not positioned in a straight line. According to the fourth embodiment, each communication groove 65 of the first communication-groove row 63a located in each of the first low-density region 66, the second low-density region 67, and the high-density region 68 (described later) is positioned offset relative to an extension of the communication groove 65 of the second communication-groove row 63b. The first communication-groove row 63a and the second communication-groove row 63b may be provided alternately. In the following description of the fourth embodiment, the subscripts “a” and “b” are added to the reference signs designating communication-groove rows only when distinction is made between individual communication-groove rows. Otherwise, these subscripts are omitted.

As illustrated in FIG. 32, each of the communication-groove rows 63 according to the fourth embodiment includes the low-density regions 66 and 67, and the high-density region 68. The high-density region 68 is a region where a unit communication-groove count representing a unit number of communication grooves 65 is greater than the unit communication-groove count in each of the low-density regions 66 and 67. The low-density regions 66 and 67 are located to opposite sides of the high-density region 68 in the X-direction. In the example illustrated in FIG. 32, the first low-density region 66 is located above the high-density region 68 in FIG. 32, and the second low-density region 67 is located below the high-density region 68 in FIG. 32.

According to the fourth embodiment, each main flow groove 61 provided in the land part 33 may have a constant width. In each of the low-density regions 66 and 67 and the high-density region 68, each main flow groove 61 may have a constant width. Each projection 64 provided on the land part 33 may have a constant width. In each of the low-density regions 66 and 67 and the high-density region 68, each projection 64 may have a constant width.

A unit communication-groove count means the number of communication grooves 65 per unit length in the X-direction. The unit communication-groove count in the high-density region 68 is greater than the unit communication-groove count in each of the low-density regions 66 and 67. For example, as illustrated in FIG. 32, the unit communication-groove count in the high-density region 68 may be determined by dividing the number of communication grooves 65 located in the high-density region 68 by the dimension of the high-density region 68 in the X-direction. For example, the total number of communication grooves 65 located in the high-density region 68 may be divided by the dimension of the high-density region 68 in the X-direction. In this case, the dimension of the high-density region 68 in the X-direction is a dimension represented by a double-headed arrow denoted by a reference sign 68a or 68b illustrated in FIG. 32. Likewise, the unit communication-groove count in the low-density region 66 or 67 may be determined by dividing the number of communication grooves 65 located in the low-density region 66 or 67 by the dimension of the low-density region 66 or 67 in the X-direction. In this case, the dimension of the low-density region 66 or 67 in the X-direction is a dimension represented by a double-headed arrow denoted by a reference sign 66a, 66b, 67a, or 67b illustrated in FIG. 32.

The high-density region 68 may be a region where the communication grooves 65 are arrayed with a small array pitch in the X-direction. The low-density regions 66 and 67 may be regions where the communication grooves 65 are arrayed with a large array pitch in the X-direction. In FIG. 32, the communication grooves 65 located in the high-density region 68 are arrayed with a constant array pitch p2 in the X-direction, and the communication grooves 65 located in each of the low-density regions 66 and 67 are arrayed with a constant array pitch p1 in the X-direction. The array pitch p2 may be less than the array pitch p1. As illustrated in FIG. 32, the high-density region 68 may be defined as a region occupied by the communication grooves 65 that are arrayed with the array pitch p2 in the X-direction. The low-density regions 66 and 67 may be defined as regions occupied by the communication grooves 65 that are arrayed with the array pitch p1 in the X-direction.

An intermediate region 69 may be located between the high-density region 68 and the low-density regions 66 and 67. A subset of the communication-groove rows 63 may include the intermediate region 69, and the other communication-groove rows 63 may include no intermediate region 69. In the example illustrated in FIG. 32, the first communication-groove row 63a does not include the intermediate region 69, but the second communication-groove row 63b includes the intermediate region 69. The intermediate region 69 does not include the communication groove 65. The intermediate region 69 may include the communication groove 65. In this case, the unit communication-groove count in the intermediate region 69 may be less than the unit communication-groove count in the high-density region 68, and greater than the unit communication-groove count in each of the low-density regions 66 and 67. The pitch in the X-direction of the communication grooves 65 in the intermediate region 69 may be greater than the pitch in the X-direction of the communication grooves 65 in the high-density region 68, and less than the pitch in the X-direction of the communication grooves 65 in each of the low-density regions 66 and 67. In this case, the array pitch p2 of the communication grooves 65 located in the high-density region 68 may be the smallest of the pitches of the communication grooves 65 in a single communication-groove row 63. The array pitch p1 of the communication grooves 65 located in each of the low-density regions 66 and 67 may be the largest of the pitches of the communication grooves 65 in a single communication-groove row 63.

As illustrated in FIG. 32, the first communication-groove row 63a includes a first low-density region 66a, a second low-density region 67a, and a high-density region 68a. The second communication-groove row 63b includes a first low-density region 66b, a second low-density region 67b, and a high-density region 68b. The high-density region 68a of the first communication-groove row 63a, and the high-density region 68b of the second communication-groove row 63b may be arranged in a direction crossing the X-direction. In the example illustrated in FIG. 32, the high-density region 68a and the high-density region 68b are arranged in the Y-direction. The dimension of the high-density region 68a in the X-direction may be equal to the dimension of the high-density region 68b in the X-direction or, as illustrated in FIG. 32, may be different from the dimension of the high-density region 68b in the X-direction. In the following description of the fourth embodiment, the subscripts “a” and “b” are added to the reference signs designating low-density regions and high-density regions only when distinctions are made between individual low-density regions and between individual high-density regions. Otherwise, these subscripts are omitted.

As illustrated in FIG. 30, the high-density regions 68 located in the corresponding land parts 33 may be arranged in a direction crossing the X-direction. In the example illustrated in FIG. 30, the respective high-density regions 68a of the land parts 33 are arranged in the Y-direction. As illustrated in FIGS. 30 and 31, according to the fourth embodiment, the second vapor passage 52 is not provided with the reinforcement part 37 illustrated in FIGS. 9 and 10.

As illustrated in FIG. 32, the communication-groove rows 63 located in each of the land parts 33 may include an adjacent communication-groove row 63c, and an intermediate communication-groove row 63d. A single land part 33 may be provided with two adjacent communication-groove rows 63c. If the wick sheet 30 includes a plurality of land parts 33, each of the land parts 33 may be provided with two adjacent communication-groove rows 63c.

The adjacent communication-groove row 63c includes the communication grooves 65 that provide communication between the vapor channel part 50 and the main flow groove 61 adjacent to the vapor channel part 50. The adjacent communication-groove row 63c is adjacent to the side edge 33e located at either side in the Y-direction of the land part 33. The adjacent communication-groove row 63c is adjacent to the first vapor passage 51 or the second vapor passage 52 of the vapor channel part 50. In the example illustrated in FIG. 32, two adjacent communication-groove rows 63c are each adjacent to the corresponding second vapor passage 52.

The intermediate communication-groove row 63d includes the communication grooves 65 each communicating with two mutually adjacent main flow grooves 61. The communication-groove rows 63 located in each of the land parts 33 may include a plurality of intermediate communication-groove rows 63d. The intermediate communication-groove row 63d is located at an intermediate location in the Y-direction of the land part 33. The intermediate communication-groove row 63d is located between two adjacent communication-groove rows 63c. The intermediate communication-groove row 63d is adjacent to neither the first vapor passage 51 nor the second vapor passage 52.

Each of the adjacent communication-groove row 63c and the intermediate communication-groove row 63d may be the first communication-groove row 63a mentioned above, or may be the second communication-groove row 63b. In the example illustrated in FIG. 32, each of the two adjacent communication-groove rows 63c is the second communication-groove row 63b. The intermediate communication-groove rows 63d include the first communication-groove row 63a and the second communication-groove row 63b that are arranged alternately in the Y-direction. One of the adjacent communication-groove row 63c and the intermediate communication-groove row 63d that are adjacent to each other may be implemented by the first communication-groove row 63a, and the other may be implemented by the second communication-groove row 63b. In the example illustrated in FIG. 32, the adjacent communication-groove row 63c is implemented by the second communication-groove row 63b, and the intermediate communication-groove row 63d adjacent to the adjacent communication-groove row 63c is implemented by the first communication-groove row 63a.

According to the fourth embodiment, each adjacent communication-groove row 63c includes the low-density regions 66 and 67, and the high-density region 68. Each intermediate communication-groove row 63d includes the low-density regions 66 and 67, and the high-density region 68. In each land part 33 according to the fourth embodiment, the high-density region 68 of the adjacent communication-groove row 63c, and the high-density region 68 of the intermediate communication-groove row 63d are arranged in the Y-direction.

As illustrated in FIG. 29, the vapor chamber 1 according to the fourth embodiment includes the bend region 7a. In the bend region 7a, the vapor chamber 1 is bent along the bend line 8 extending in a direction crossing the X-direction in plan view. As illustrated in FIGS. 28 and 29, the bend line 8 according to the fourth embodiment extends in the Y-direction in plan view. The Y-direction is a direction orthogonal to the X-direction in plan view. The bend line 8 traverses the frame part 32, the land part 33, the first vapor passage 51, and the second vapor passage 52. This configuration can reduce a deformation of the first sheet 10 that causes the first sheet 10 to extend into the vapor passages 51 and 52, and can also reduce a deformation of the second sheet 20 that causes the second sheet 20 to extend into the vapor passages 51 and 52. This can ensure that the first vapor passage 51 and the second vapor passage 52 have adequate channel cross-sectional area. The first region 5, the second region 6, and the bend region 7a may be sectioned off from each other by boundary lines extending along the bend line 8. In the example illustrated in FIGS. 28 and 29, the regions 5, 6, and 7 may be sectioned off from each other by boundary lines extending in the Y-direction in plan view.

As illustrated in FIG. 30, the high-density region 68 mentioned above is located in the bend region 7a. More specifically, the high-density region 68 located in each of the land parts 33 is located in the bend region 7a. The high-density region 68 may extend beyond the bend region 7a in the X-direction. With the bend region 7a viewed from inside or outside the bend, the high-density region 68 located in each of the land parts 33 overlaps the bend line 8. Such high-density regions 68 may be arranged along the Y-direction. Although each high-density region 68 is schematically depicted in FIG. 30 as being sectioned off by linear boundary lines extending in the Y-direction in plan view, the present disclosure is not limited to such a configuration. As long as each high-density region 68 is sectioned off for each individual communication-groove row 63 as illustrated in FIG. 32, the high-density region 68 does not have to be sectioned off by the linear boundary lines as illustrated in FIG. 30.

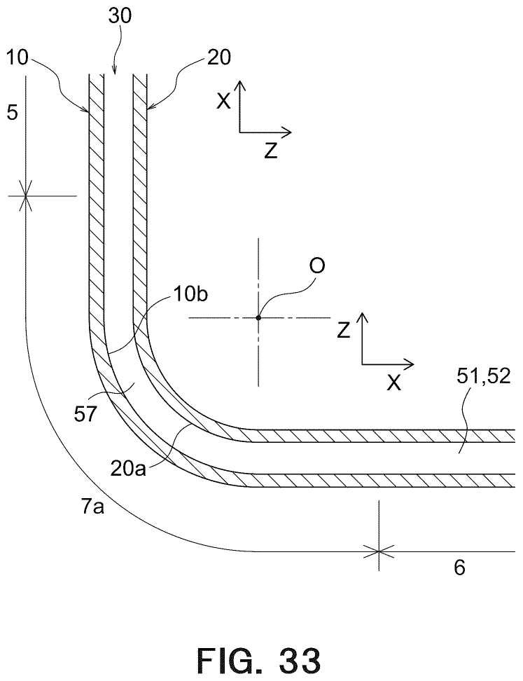

The vapor chamber 1 is bent as illustrated in FIG. 33. In the bend region 7a, the first sheet 10 is located outward relative to the wick sheet 30 with respect to the center O of the bend. The second sheet 20 is located inward relative to the wick sheet 30 with respect to the center O of the bend.

As illustrated in FIG. 33, the vapor passages 51 and 52 may each include a passage bend part 57 located in the bend region 7a. FIG. 33 illustrates an example of the passage bend part 57. Although the passage bend part 57 is illustrated in FIG. 33 as having the shape of a quarter-circular arc when viewed in the Y-direction, this is not intended to be limiting. The passage bend part 57 may include the first vapor channel recess 53 and the second vapor channel recess 54 mentioned above.

When the vapor chamber 1 is in operation, a portion of the working vapor 2a passing through the first vapor passage 51 and the second vapor passage 52 passes through the passage bend part 57 (see FIG. 33) located in the bend region 7a. The working vapor 2a tends to condense when passing through the passage bend part 57.

At the outer side of the passage bend part 57, the working vapor 2a is susceptible to collision with the first-sheet inner face 10b. Upon such collision, the working vapor 2a condenses into the working liquid 2b, which adheres to the first-sheet inner face 10b. In the bend region 7a, the first body face 30a of the land part 33 is provided with the high-density region 68 of the adjacent communication-groove row 63c, and the high-density region 68 of the intermediate communication-groove row 63d. In the high-density region 68, the increased unit communication-groove count allows for increased capillary action to draw in the working liquid 2b in the Y-direction. The working liquid 2b condensed in the passage bend part 57 is drawn from the passage bend part 57 into the high-density region 68 of the adjacent communication-groove row 63c. The working liquid 2b is thus drawn into the main flow groove 61 adjacent to the passage bend part 57, and then into the high-density region 68 of the intermediate communication-groove row 63d. In this way, the working liquid 2b is smoothly drawn into each main flow groove 61 of the first liquid channel part 60. Once drawn into each main flow groove 61, the working liquid 2b is transported toward the evaporation region SR through the capillary action of the main flow groove 61. This helps to reduce stagnation of the working liquid 2b that has adhered to the first-sheet inner face 10b in the bend region 7a.

At the inner side of the passage bend part 57, the flow of the working vapor 2a may be allowed to separate from the second-sheet inner face 20a. This is explained below in more detail. In an area near the exit of the passage bend part 57, eddies are formed, and the working vapor 2a condenses and adheres onto the second-sheet inner face 20a. The area near the exit of the passage bend part 57 corresponds to a portion of the passage bend part 57 that is located relatively close to the second region 6. In the bend region 7a, the first body face 30a of the land part 33 is provided with the high-density region 68 having an increased unit communication-groove count. This results in increased capillary action to draw in the working liquid 2b in the Y-direction. The working liquid 2b is thus smoothly drawn into each main flow groove 61. Once drawn into each main flow groove 61, the working liquid 2b is transported toward the evaporation region SR through the capillary action of the main flow groove 61. This helps to reduce stagnation of the working liquid 2b that has adhered to the second-sheet inner face 20a in the bend region 7a.

As described above, according to the fourth embodiment, the communication grooves 65 of the first liquid channel part 60 constitute the communication-groove rows 63. The communication-groove rows 63 include the adjacent communication-groove row 63c. The adjacent communication-groove row 63c includes the communication grooves 65 that provide communication between the vapor channel part 50, and the main flow groove 61 adjacent to the vapor channel part 50. The adjacent communication-groove row 63c includes the low-density regions 66 and 67, and the high-density region 68 where the unit communication-groove count is greater than the unit communication-groove count in each of the low-density regions 66 and 67. The vapor chamber 1 is bent in the bend region 7a along the bend line 8 extending in the Y-direction in plan view. The high-density region 68 of the adjacent communication-groove row 63c is located in the bend region 7a, and overlaps the bend line 8. This configuration can ensure that in the bend region 7a, the density of the communication grooves 65 that provide communication between the vapor channel part 50 and the main flow groove 61 can be increased, which allows for increased capillary action to draw the working liquid 2b from the vapor channel part 50 into the first liquid channel part 60. Consequently, the working liquid 2b condensed in the bend region 7a can be smoothly drawn into the first liquid channel part 60. This makes it possible to reduce stagnation of the working liquid 2b in each of the vapor passages 51 and 52 in the bend region 7a. As a result, the vapor chamber 1 can exhibit improved heat dissipation efficiency even in its bent state.

According to the fourth embodiment, the low-density regions 66 and 67 are located to opposite sides of the high-density region 68 in the X-direction. The low-density regions 66 and 67, which are regions with decreased density of communication grooves 65, can be thus provided to opposite sides of the bend region 7a. As a result, the capillary action that the main flow groove 61 exerts in the X-direction can be increased in areas located to opposite sides of the bend region 7a. The working liquid 2b can be thus transported toward the evaporation region SR.

According to the fourth embodiment, the communication-groove rows 63 include the intermediate communication-groove row 63d, which includes the communication grooves 65 each communicating with two mutually adjacent main flow grooves 61. The intermediate communication-groove row 63d includes the low-density regions 66 and 67, and the high-density region 68. The high-density region 68 of the intermediate communication-groove row 63d is located in the bend region 7a, and overlaps the bend line 8. The above-mentioned configuration can ensure that in the bend region 7a, the density of the communication grooves 65 communicating the main flow grooves 61 with each other can be increased. The working liquid 2b drawn into the high-density region 68 of the adjacent communication-groove row 63c can be thus smoothly drawn into the high-density region 68 of the intermediate communication-groove row 63d, and consequently, the working liquid 2b can be further smoothly drawn into the first liquid channel part 60. This can further reduce stagnation of the working liquid 2b in each of the vapor passages 51 and 52 in the bend region 7a. This in tum allows the vapor chamber 1 to exhibit further improved heat dissipation efficiency even in its bent state.

According to the fourth embodiment, in the low-density regions 66 and 67 and the high-density region 68, each communication groove 65 of the first communication-groove row 63a is positioned offset relative to an extension of the communication groove 65 of the second communication-groove row 63b. This can ensure that each communication groove 65 of the first communication-groove row 63a, and the corresponding communication groove 65 of the second communication-groove row 63b are not positioned in a straight line. This in turn can ensure that two communication grooves 65 do not intersect the main flow groove 61 in the form of a cross, and consequently can ensure adequate capillary action of the main flow groove 61.

According to the fourth embodiment, in the low-density regions 66 and 67 and the high-density region 68, the communication groove 65 extends in the Y-direction orthogonal to the X-direction. This can ensure that the communication groove 65 has a short length. The working liquid 2b can be thus smoothly drawn from the vapor channel part 50 into the main flow groove 61. This can further reduce stagnation of the working liquid 2b in each of the vapor passages 51 and 52 in the bend region 7a. The working liquid 2b is thus allowed to smoothly move back and forth between the main flow grooves 61 that are adjacent to each other. Consequently, the risk of dry-out in the main flow grooves 61 can be reduced. This makes it possible to impart capillary action to the working liquid 2b within each main flow groove 61. The working liquid 2b can be thus smoothly transported toward the evaporation region SR.

According to the fourth embodiment, the bend line 8 extends in the Y-direction orthogonal to the X-direction. The vapor chamber 1 can be thus bent in a direction orthogonal to the X-direction in which the land part 33 extends. This makes it possible to, in the bend region 7a, reduce a deformation of the first sheet 10 that causes the first sheet 10 to extend into the vapor passages 51 and 52, and also reduce a deformation of the second sheet 20 that causes the second sheet 20 to extend into the vapor passages 51 and 52. This in turn can ensure that the first vapor passage 51 and the second vapor passage 52 each have adequate cross-sectional area, and consequently can reduce impediment to the flow of the working vapor 2a in the bend region 7a.

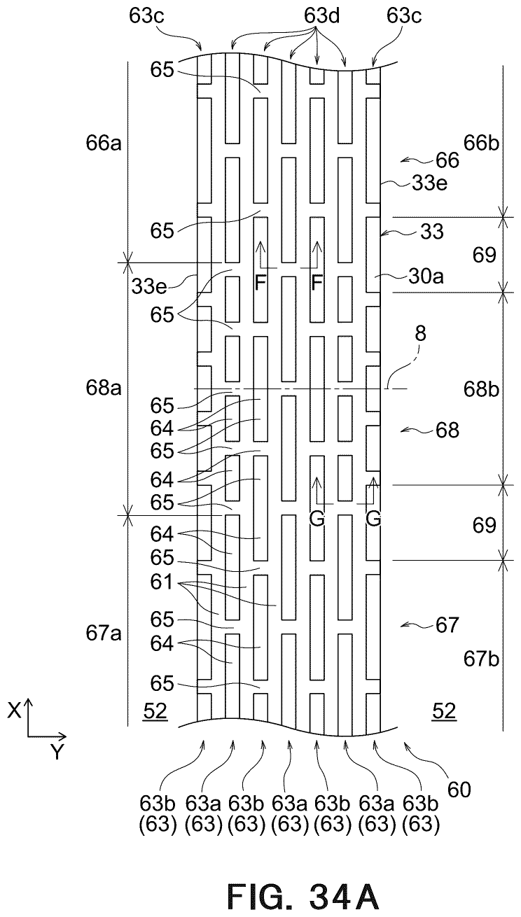

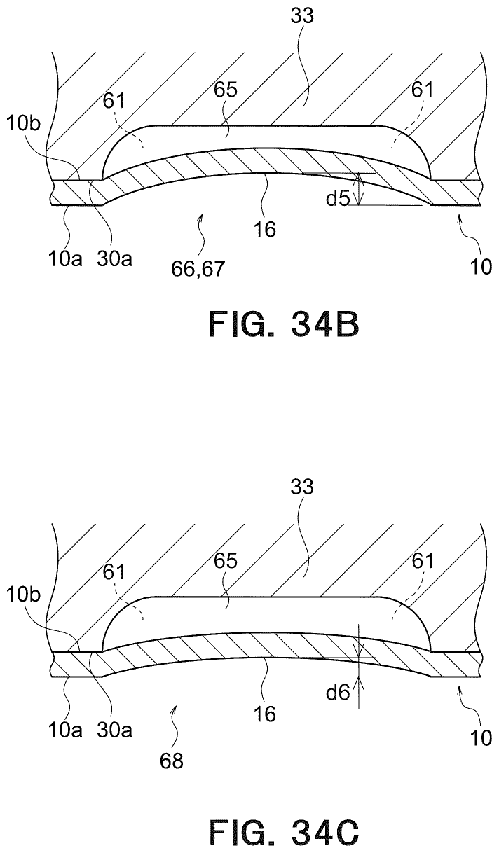

The foregoing description of the fourth embodiment is directed to the example in which each of the intermediate communication-groove rows 63d includes the low-density regions 66 and 67, and the high-density region 68. However, the present disclosure is not limited to such a configuration. For example, as illustrated in FIG. 34A, at least one of the intermediate communication-groove rows 63d may include no high-density region 68.

In the example illustrated in FIG. 34A, some of the intermediate communication-groove rows 63d include no high-density region 68. Such an intermediate communication-groove row 63d including no high-density region 68 may be made up generally of the low-density regions 66 and 67. The intermediate communication-groove row 63d adjacent to the adjacent communication-groove row 63c includes the high-density region 68. The above-mentioned configuration as well can ensure that in the bend region 7a, the density of the communication grooves 65 that provide communication between the vapor channel part 50 and the main flow groove 61 can be increased, which allows for increased capillary action to draw the working liquid 2b from the vapor channel part 50 into the first liquid channel part 60. Consequently, the working liquid 2b condensed in the bend region 7a can be smoothly drawn into the first liquid channel part 60. This makes it possible to reduce stagnation of the working liquid 2b in each of the vapor passages 51 and 52 in the bend region 7a. In the intermediate communication-groove row 63d including no high-density region 68, the capillary action exerted in the X-direction due to the main flow groove 61 can be increased. As a result, the working liquid 2b drawn into the high-density region 68 of the adjacent communication-groove row 63c can be smoothly drawn into the main flow groove 61. This makes it possible to reduce stagnation of the working liquid 2b in the high-density region 68 of the adjacent communication-groove row 63c.

Unlike with the example illustrated in FIG. 34A, none of the intermediate communication-groove rows 63d may include the high-density region 68. Even in this case, the presence of the high-density region 68 in the adjacent communication-groove row 63c allows the working liquid 2b condensed in the bend region 7a to be smoothly drawn into the first liquid channel part 60.

As illustrated in FIGS. 34B and 34C, a portion of the first sheet 10 may be allowed to extend into the communication groove 65. More specifically, a region of the first-sheet outer face 10a that overlaps the communication groove 65 may have a recessed shape that is recessed inward toward the communication groove 65. The first sheet 10 may include a first-sheet communication-groove recess 16 overlapping the communication groove 65 in plan view. The first-sheet communication-groove recess 16 extends into the communication groove 65. The first-sheet communication-groove recess 16 may be provided in each of the first region 5, the second region 6, and the bend region 7a. The first sheet 10 may include a first-sheet main-flow-groove recess (not illustrated) overlapping the main flow groove 61 in plan view. The first-sheet main-flow-groove recess may extend into the main flow groove 61. The first-sheet main-flow-groove recess may be provided in each of the first region 5, the second region 6, and the bend region 7a, or may be provided so as to extend contiguously from the first region 5 to the second region 6. The first-sheet communication-groove recess 16 may be provided contiguously with the first-sheet main-flow-groove recess.

The first-sheet inner face 10b at the first-sheet communication-groove recess 16, and the wall face of the communication groove 65 define a channel corner (not illustrated) constituting a portion of a liquid channel cross-section. The channel corner may be shaped like a wedge extending in the Y-direction. The presence of the channel corner allows for increased capillary action.

FIG. 34B illustrates the first-sheet communication-groove recess 16 in each of the low-density regions 66 and 67. In each of the low-density regions 66 and 67, the unit communication-groove count is low, which means that the spacing between the communication grooves 65 is relatively large. Consequently, the stress exerted on the first sheet 10 during bending is not readily dispersed, and tends to concentrate in a portion of the first sheet 10 that overlaps the communication groove 65. This results in increased recession of the first-sheet communication-groove recess 16 in each of the low-density regions 66 and 67. In FIG. 34B, reference sign d5 denotes a recess dimension representing how much a portion of the first-sheet outer face 10a where the first-sheet communication-groove recess 16 exists is recessed in each of the low-density regions 66 and 67.

FIG. 34C illustrates the first-sheet communication-groove recess 16 in the high-density region 68. In the high-density region 68, the unit communication-groove count is high, which means that the spacing between the communication grooves 65 is relatively small. Consequently, the stress exerted on the first sheet 10 during bending is readily dispersed, which makes it possible to reduce concentration of the stress in a portion of the first sheet 10 that overlaps the communication groove 65. This results in decreased recession of the first-sheet communication-groove recess 16 in the high-density region 68. In FIG. 34C, reference sign d6 denotes a recess dimension representing how much a portion of the first-sheet outer face 10a where the first-sheet communication-groove recess 16 exists is recessed in the high-density region 68.

The recess dimension d5 illustrated in FIG. 34B is greater than the recess dimension d6 illustrated in FIG. 34C. This makes it possible to increase the capillary action that the communication groove 65 located in each of the low-density regions 66 and 67 exerts in the Y-direction. This can ensure that in the bend region 7a, the communication groove 65 of the intermediate communication-groove row 63d that includes no high-density region 68 can exert increased capillary action in the Y-direction. In this case, the working liquid 2b drawn into the high-density region 68 of the adjacent communication-groove row 63c is allowed to smoothly move into the main flow groove 61 corresponding to the intermediate communication-groove row 63d that includes no high-density region 68. This can reduce stagnation of the working liquid 2b in the high-density region 68 of the adjacent communication-groove row 63c.

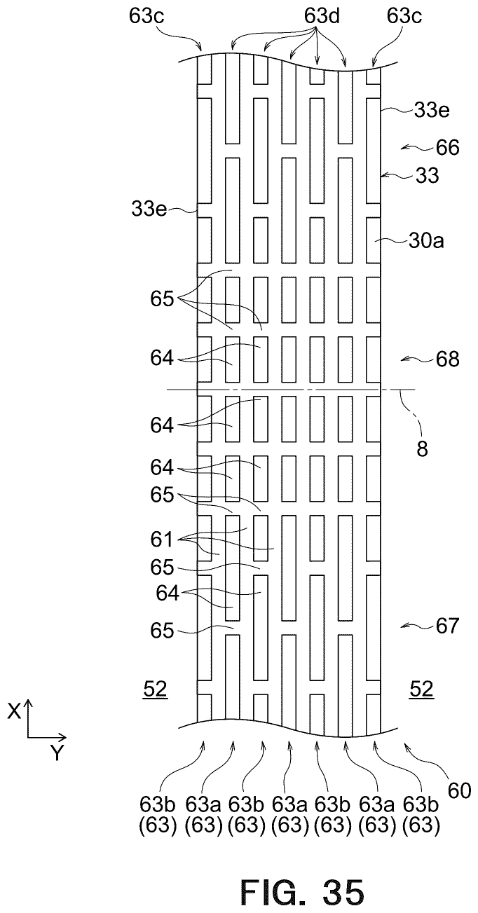

The foregoing description of the fourth embodiment is directed to the example in which each communication groove 65 of the first communication-groove row 63a located in the high-density region 68 is positioned offset relative to an extension of the communication groove 65 of the second communication-groove row 63b. In other words, the foregoing description is directed to the example in which the projections 64 are disposed in a staggered arrangement. However, the present disclosure is not limited to such a configuration. For example, in the high-density region 68, each communication groove 65 of the first communication-groove row 63a may be positioned on an extension of the corresponding communication groove 65 of the second communication-groove row 63b as illustrated in FIG. 35. In this case, the projections 64 are arrayed in parallel with each other, and the main flow grooves 61 and the communication grooves 65 are arranged in a lattice pattern. In the example illustrated in FIG. 35, the communication grooves 65 are aligned with each other in the Y-direction. Consequently, in the bend region 7a, the first liquid channel part 60 can exhibit increased capillary action in the Y-direction, and the condensed working liquid 2b can be thus smoothly drawn into the first liquid channel part 60. Further, the alignment of the communication grooves 65 in the Y-direction allows the vapor chamber 1 to be easily bent along the bend line 8 extending in the Y-direction. In the example illustrated in FIG. 35, the high-density region 68 located in each of the land parts 33 overlaps the bend line 8. Such high-density regions 68 are arranged along the Y-direction. Each of the high-density regions 68 has the same dimension in the X-direction.

The foregoing description of the fourth embodiment is directed to the example in which the main flow grooves 61 located in the high-density region 68 have the same width. However, the present disclosure is not limited to such a configuration. For example, the main flow grooves 61 located in the high-density region 68 may have different widths.

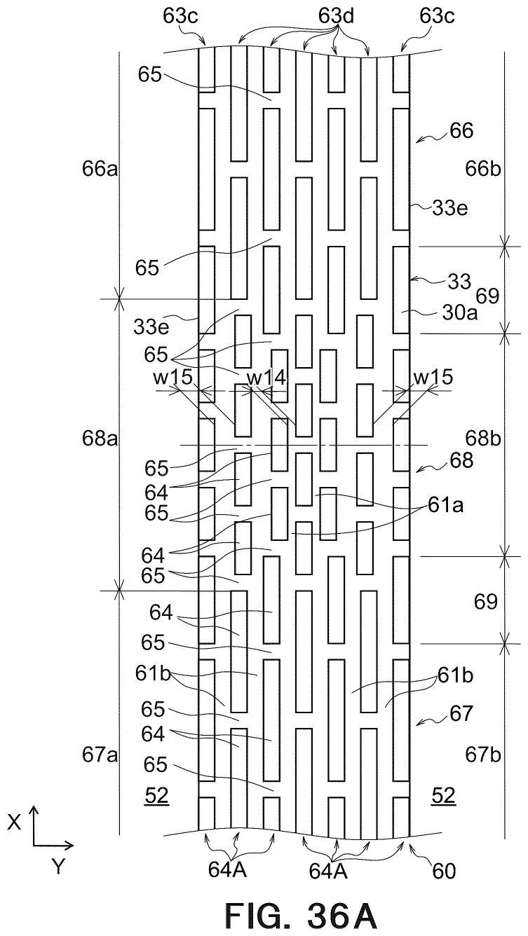

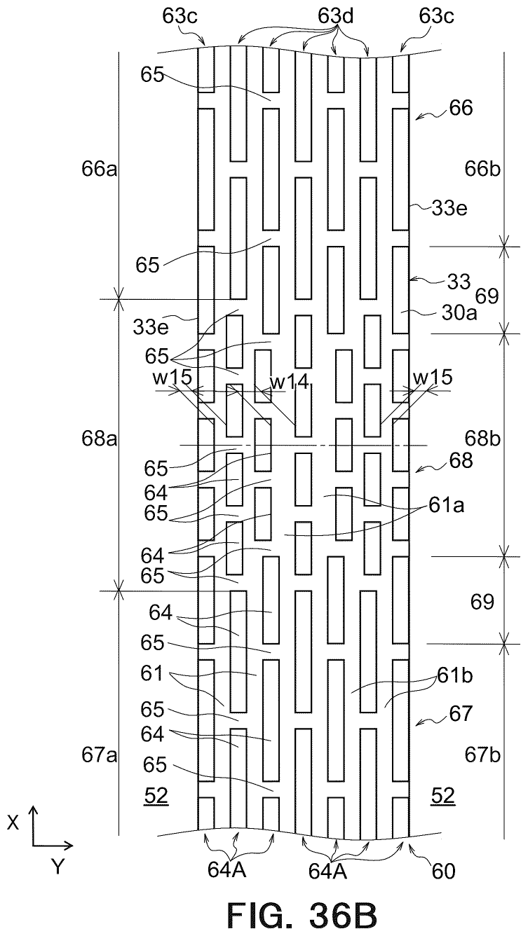

For example, as illustrated in FIG. 36A, the main flow grooves 61 provided in the land part 33 may include a plurality of first main flow grooves 61a, and a plurality of second main flow grooves 61b.

The first main flow groove 61a may be located in the central area of the land part 33 in the width direction. The second main flow groove 61b may be located to each side of the first main flow groove 61a in the width direction. The second main flow groove 61b is located at a position that is near the above-mentioned side edge 33e of the land part 33, and that is near the second vapor passage 52. One or more second main flow grooves 61b may be located to each side in the width direction of the first main flow groove 61a. Although FIG. 36A depicts an example in which two first main flow grooves 61a are present, any number of first main flow grooves 61a may be present. Although FIG. 36A depicts an example in which two second main flow grooves 61b are located to each side of the first main flow groove 61a in the width direction, any number of such second main flow grooves 61b may be present.

In each of the low-density regions 66 and 67, the first main flow groove 61a and the second main flow groove 61b may have the same width, which may be the width w5 (see FIG. 32). In the high-density region 68, the first main flow groove 61a and the second main flow groove 61b may have different widths. As illustrated in FIG. 36A, in the high-density region 68, the first main flow groove 61a has a width w14, and the second main flow groove 61b has a width w15. The width w15 of the second main flow groove 61b may be greater than the width w14 of the first main flow groove 61a. The width w14 may be less than the width w5. The width w15 may be greater than the width w5. To make the width w15 greater than the width w14, each projection 64 located in the high-density region 68 may be offset in the width direction relative to the corresponding projection 64 located in each of the low-density regions 66 and 67. More specifically, in the projection row 64A located between two mutually adjacent second main flow grooves 61b, each projection 64 located in the high-density region 68 may be offset toward the central area in the width direction, relative to the corresponding projection 64 located in each of the low-density regions 66 and 67. In the projection row 64A located between the first main flow groove 61a and the second main flow groove 61b that are adjacent to each other, each projection 64 located in the high-density region 68 may be offset toward the central area in the width direction, relative to the corresponding projection 64 located in each of the low-density regions 66 and 67.

According to the example illustrated in FIG. 36A, the width w15 of the second main flow groove 61b can be increased, which allows for reduced channel resistance for the working liquid 2b in the second main flow groove 61b located near the second vapor passage 52. Consequently, the working liquid 2b can be smoothly drawn from the second vapor passage 52 into the second main flow groove 61b. Further, the width w14 of the first main flow groove 61a can be decreased, which allows for increased capillary action of the first main flow groove 61a located in the central area in the width direction. Consequently, the working liquid 2b drawn into the second main flow groove 61b is allowed to smoothly move to the first main flow groove 61a. This can facilitate movement of the working liquid 2b from the second vapor passage 52 to the first liquid channel part 60. Further, due to the capillary action of the first main flow groove 61a, the working liquid 2b can be smoothly transported from the first main flow groove 61a in the high-density region 68 toward the evaporation region SR. This can reduce stagnation of the working liquid 2b in the high-density region 68.

Alternatively, as illustrated in FIG. 36B, the width w15 of the second main flow groove 61b may be less than the width w14 of the first main flow groove 61a. The width w14 may be greater than the width w5. The width w15 may be less than the width w5. To make the width w15 less than the width w14, each projection 64 located in the high-density region 68 may be offset in the width direction relative to the corresponding projection 64 located in each of the low-density regions 66 and 67. More specifically, in the projection row 64A located between two mutually adjacent second main flow grooves 61b, each projection 64 located in the high-density region 68 may be offset toward the side edge 33e, relative to the corresponding projection 64 located in each of the low-density regions 66 and 67. In the projection row 64A located between the first main flow groove 61a and the second main flow groove 61b that are adjacent to each other, each projection 64 located in the high-density region 68 may be offset toward the side edge 33e, relative to the corresponding projection 64 located in each of the low-density regions 66 and 67.

According to the example illustrated in FIG. 36B, the width w15 of the second main flow groove 61b can be decreased, which allows for increased capillary action of the second main flow groove 61b located near the second vapor passage 52. Consequently, the working liquid 2b can be smoothly drawn from the second vapor passage 52 into the second main flow groove 61b. Further, the width of the first main flow groove 61a can be increased, which allows for reduced channel resistance for the working liquid 2b in the first main flow groove 61a that is located in the central area in the width direction. Consequently, the working liquid 2b drawn into the second main flow groove 61b is allowed to smoothly move to the first main flow groove 61a. This allows an increased amount of the working liquid 2b to be supplied from the first main flow groove 61a in the high-density region 68 toward the evaporation region SR. Further, due to the reduced channel resistance of the first main flow groove 61a, the working liquid 2b can be smoothly transported to the evaporation region SR. This can reduce stagnation of the working liquid 2b in the high-density region 68.

The foregoing description of the fourth embodiment is directed to the example in which the projections 64 located in the high-density region 68 have the same width. However, the present disclosure is not limited to such a configuration. For example, the projections 64 located in the high-density region 68 may have different widths.

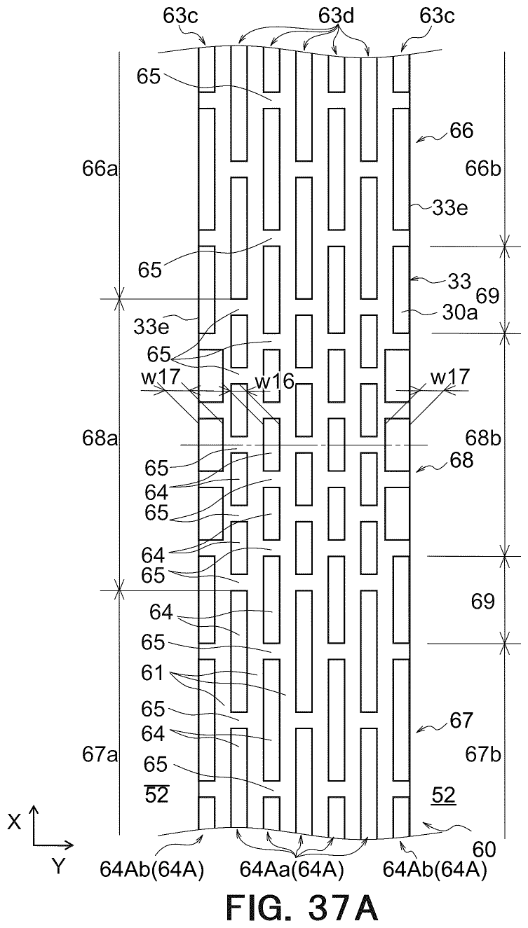

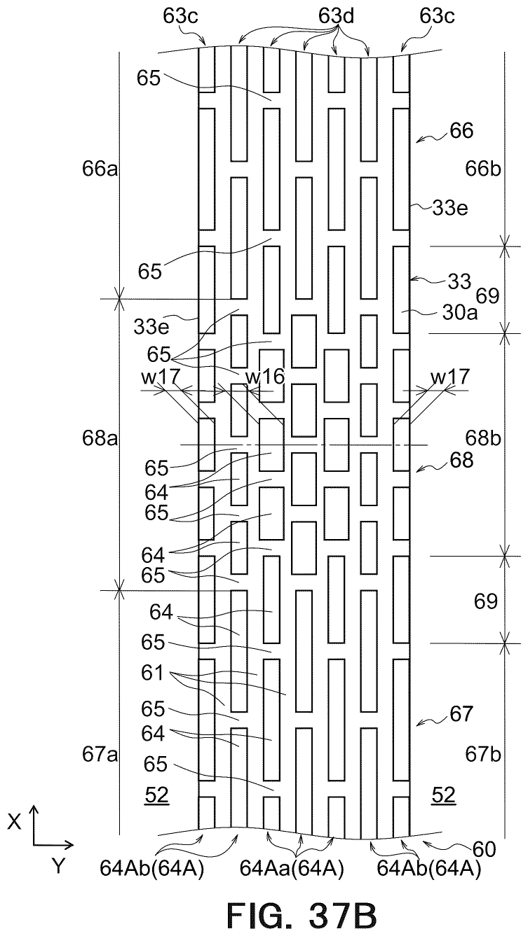

For example, as illustrated in FIG. 37A, the projection rows 64A on the land part 33 may include a plurality of first projection rows 64Aa, and a plurality of second projection rows 64Ab.

The first projection row 64Aa may be located in the central area of the land part 33 in the width direction. The second projection row 64Ab may be located to each side of the first projection row 64Aa in the width direction. The second projection row 64Ab is located at a position that is near the above-mentioned side edge 33e of the land part 33, and that is near the second vapor passage 52. One or more second projection rows 64Ab may be located to each side in the width direction of the first projection row 64Aa. Although FIG. 37A depicts an example in which five first projection rows 64Aa are present, any number of first projection rows 64Aa may be present. Although FIG. 37A depicts an example in which a single second projection row 64Ab is located to each side of the first projection row 64Aa in the width direction, any number of such second projection rows 64Ab may be present.

In each of the low-density regions 66 and 67, the width of the projections 64 of the first projection row 64Aa, and the width of the projections 64 of the second projection row 64Ab may be the same, which may be the width w7 (see FIG. 32). In the high-density region 68, the width of the projections 64 of the first projection row 64Aa, and the width of the projections 64 of the second projection row 64Ab may be different. As illustrated in FIG. 37A, in the high-density region 68, the projections 64 of the first projection row 64Aa have a width w16, and the projections 64 of the second projection row 64Ab have a width w17. The width w17 of the projections 64 of the second projection row 64Ab may be greater than the width w16 of the projections 64 of the first projection row 64Aa. The width w16 may be equal to the width w7. The width w17 may be greater than the width w7.

According to the example illustrated in FIG. 37A, the width w17 of the projections 64 of the second projection row 64Ab can be increased, and the projections 64 of the second projection row 64Ab located near the second vapor passage 52 can be thus improved in mechanical strength. This configuration can reduce bending-induced collapse of the communication groove 65 located between such projections 64. Due to the ability to reduce collapse of the channel defined by the communication groove 65, the working liquid 2b can be drawn smoothly from the second vapor passage 52 into the main flow groove 61. As a result, if the working liquid 2b evaporates in the first liquid channel part 160 located in the bend part BP, the evaporated working vapor 2a is allowed to smoothly diffuse to the vapor passages 151 and 152. Further, the increased width w17 of the projections 64 makes it possible to increase the dimension in the Y-direction of the communication groove 65 located between the projections 64, and consequently increase the capillary action of the communication groove 65 corresponding to the second projection row 64Ab. The working liquid 2b can be thus smoothly drawn from the second vapor passage 52 into the first liquid channel part 60. Further, the width w16 of the projections 64 of the first projection row 64Aa can be decreased. This can reduce impediment caused by the high-density region 68 to the flow of the working liquid 2b in the X-direction.

Alternatively, as illustrated in FIG. 37B, the width w16 of the projections 64 of the first projection row 64Aa may be greater than the width w17 of the projections 64 of the second projection row 64Ab. The width w16 may be greater than the width w7. The width w17 may be equal to the width w7. Although FIG. 37B depicts an example in which three first projection rows 64Aa are present, any number of first projection rows 64Aa may be present. Although FIG. 37B depicts an example in which two second projection rows 64Ab are located to each side of the first projection row 64Aa in the width direction, any number of such second projection rows 64Ab may be present.

According to the example illustrated in FIG. 37B, the width w16 of the projections 64 of the first projection row 64Aa can be increased, and the projections 64 of the first projection row 64Aa located in the central area in the width direction can be thus improved in mechanical strength. This configuration can reduce bending-induced collapse of the communication groove 65 located between such projections 64. This makes it possible to, even when air bubbles are generated in the main flow groove 61, draw the generated air bubbles into the communication groove 65, and consequently reduce stagnation of the working liquid 2b in the main flow groove 61. Further, the increased width w16 of the projections 64 makes it possible to increase the dimension in the Y-direction of the communication groove 65 located between the projections 64, and consequently increase the capillary action of the communication groove 65 corresponding to the first projection row 64Aa. Consequently, the working liquid 2b drawn into the first liquid channel part 60 is allowed to smoothly move to the central area in the width direction. This can facilitate movement of the working liquid 2b from the second vapor passage 52 to the first liquid channel part 60. Further, the increased width w16 of the projections 64 of each first projection row 64Aa makes it possible to reduce the width of the main flow groove 61 located between two mutually adjacent first projection rows 64Aa. This allows for increased capillary action. As a result, the working liquid 2b can be smoothly transported from the main flow groove 61 in the high-density region 68 to the evaporation region SR. This can reduce stagnation of the working liquid 2b in the high-density region 68. Further, the width w17 of the projections 64 of the second projection row 64Ab can be decreased. This can reduce impediment caused by the high-density region 68 to the flow of the working liquid 2b in the X-direction.

The foregoing description of the fourth embodiment is directed to the example in which the second body face 30b of the land part 33, and the second body face 30b of the frame part 32 are provided with no liquid channel part. However, the present disclosure is not limited to such a configuration. For example, the second body face 30b of the land part 33 may be provided with a liquid channel part (not illustrated). As with the first liquid channel part 60 described above, the liquid channel part may include the main flow grooves 61, and the communication grooves 65. Each groove of the liquid channel part provided in the second body face 30b may have a channel cross-sectional area equal to the channel cross-sectional area of each groove of the first liquid channel part 60, or may have a channel cross-sectional area greater than the channel cross-sectional area of each groove of the first liquid channel part 60. If the second body face 30b is provided with a liquid channel part, the first body face 30a may be provided with no first liquid channel part 60.

The foregoing description of the fourth embodiment is directed to the example in which the reinforcement region 7 (see, for example, FIG. 5) is not provided between the first region 5 and the second region 6, and the vapor passages 51 and 52 are provided with no reinforcement part 37. However, the present disclosure is not limited to such a configuration. For example, the reinforcement region 7 may be provided between the first region 5 and the second region 6. The vapor passages 51 and 52 may be provided with the reinforcement part 37.

### Fifth Embodiment

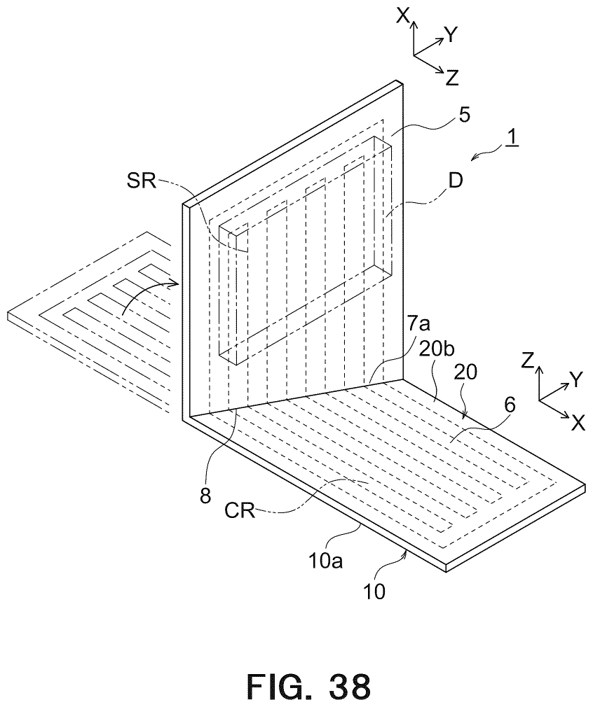

Now, reference is made to FIGS. 38 to 43 to describe a vapor chamber, an electronic apparatus, and a body sheet for a vapor chamber according to a fifth embodiment of the present disclosure.

The fifth embodiment illustrated in FIGS. 38 to 43 differs mainly in that the bend line extends in a direction inclined relative to the first direction. The fifth embodiment is otherwise substantially identical in configuration to the fourth embodiment illustrated in FIGS. 28 to 37B. Features in FIGS. 38 to 43 that are identical to those according to the fourth embodiment illustrated in FIGS. 28 to 37B are designated by the same reference signs and not described in further detail.

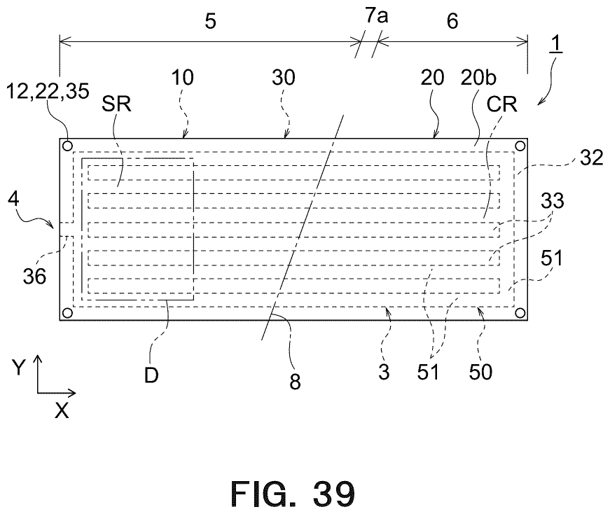

As illustrated in FIGS. 38 and 39, the vapor chamber 1 according to the fifth embodiment is bent along the bend line 8 that is inclined relative to the X-direction in plan view. The bend line 8 illustrated in FIGS. 38 and 39 extends in a direction inclined relative to the X-direction, and also extends in a direction inclined relative to the Y-direction. According to the fifth embodiment as well, the bend line 8 extends in a direction crossing the X-direction in plan view.

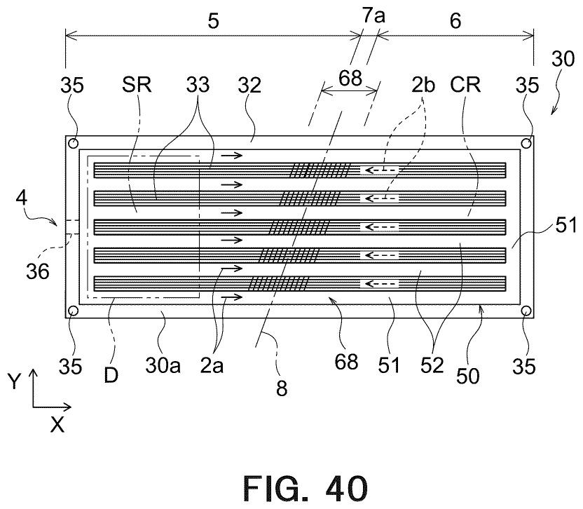

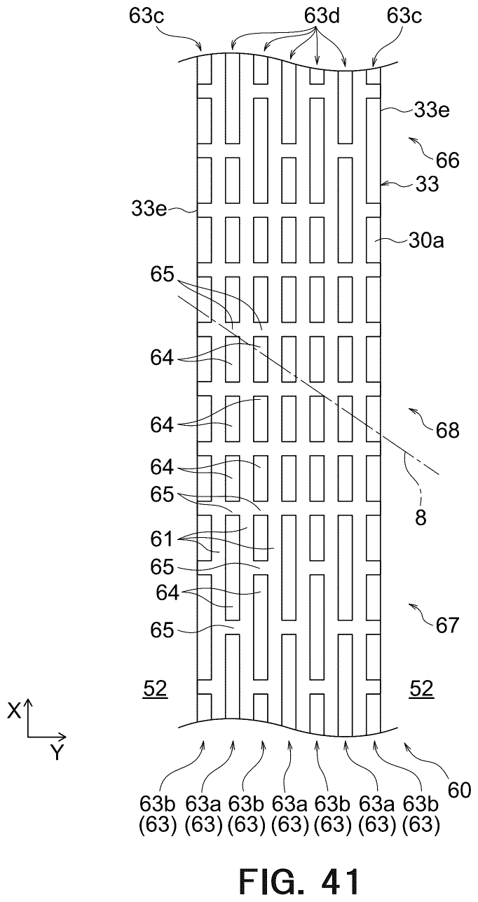

As illustrated in FIGS. 40 and 41, the high-density regions 68 located in the corresponding land parts 33 overlap the bend line 8. The high-density regions 68 may be arranged along a direction inclined relative to the X-direction. Although each high-density region 68 is schematically depicted in FIG. 40 as being sectioned off by linear boundary lines extending in a direction inclined relative to the X-direction, the present disclosure is not limited to such a configuration. As long as each high-density region 68 is sectioned off for each individual communication-groove row 63 as illustrated in FIG. 41, the high-density region 68 does not have to be sectioned off by the linear boundary lines as illustrated in FIG. 40. In the example illustrated in FIG. 41 as well, the high-density regions 68 overlap the bend line 8. This means that the high-density regions 68 are arranged along a direction inclined relative to the X-direction in plan view.

According to the fifth embodiment, as illustrated in FIG. 41, each communication groove 65 of the first communication-groove row 63a located in each of the first low-density region 66 and the second low-density region 67 is positioned offset relative to an extension of the communication groove 65 of the second communication-groove row 63b. In the high-density region 68, each communication groove 65 of the first communication-groove row 63a may be positioned on an extension of the corresponding communication groove 65 of the second communication-groove row 63b. In this case, the projections 64 are arrayed in parallel with each other, and the main flow grooves 61 and the communication grooves 65 are arranged in a lattice pattern. In each of the low-density regions 66 and 67 and the high-density region 68, the communication grooves 65 extend in the Y-direction, and are aligned with each other in the Y-direction.

As described above, according to the fifth embodiment, the bend line 8 extends in a direction inclined relative to the X-direction. The high-density region 68 of the adjacent communication-groove row 63c is located in the bend region 7a, and overlaps the bend line 8. Consequently, even when the vapor chamber 1 is bent along the bend line 8 extending in a direction inclined relative to the X-direction, the first liquid channel part 60 can exhibit increased capillary action in the Y-direction in the bend region 7a. This can reduce stagnation of the working liquid 2b in each of the vapor passages 51 and 52 in the bend region 7a. As a result, the vapor chamber 1 can exhibit improved heat dissipation efficiency even in its bent state.

According to the fifth embodiment, in the high-density region 68, each communication groove 65 of the first communication-groove row 63a is positioned on an extension of the corresponding communication groove 65 of the second communication-groove row 63b. Consequently, in the bend region 7a, the first liquid channel part 60 can exhibit increased capillary action in the Y-direction, and the condensed working liquid 2b can be thus smoothly drawn into the first liquid channel part 60.

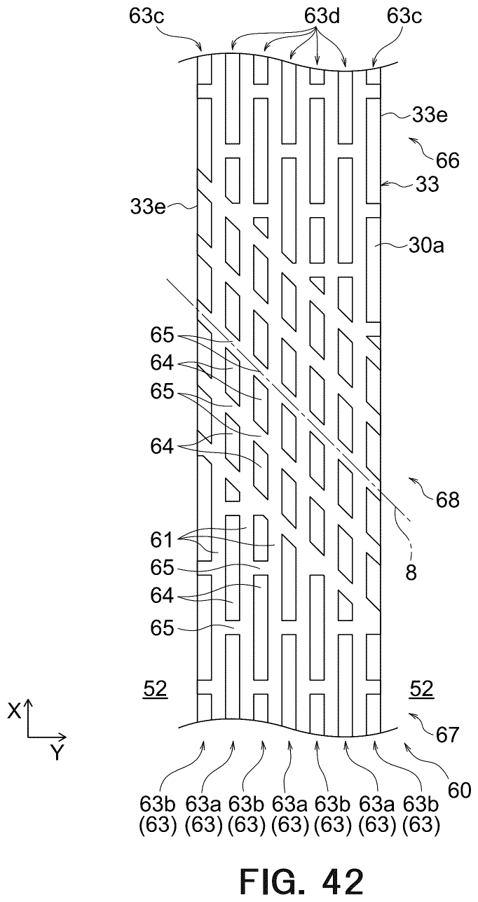

The foregoing description of the fifth embodiment is directed to the example in which the communication groove 65 of the first liquid channel part 60 located in the high-density region 68 extends in the Y-direction. However, the present disclosure is not limited to such a configuration. It may suffice that in the high-density region 68, the communication groove 65 extends in a direction different from the X-direction, for example, in a direction inclined relative to the X-direction as illustrated in FIG. 42. In this case as well, each communication groove 65 of the first communication-groove row 63a is positioned on an extension of the corresponding communication groove 65 of the second communication-groove row 63b. The communication grooves 65 are aligned with each other in a direction inclined relative to the X-direction. Consequently, the vapor chamber 1 can be easily bent along the bend line 8 extending in a direction inclined relative to the X-direction. Further, in the bend region 7a, the first liquid channel part 60 can exhibit increased capillary action in the direction inclined relative to the X-direction, and the condensed working liquid 2b can be thus smoothly drawn into the first liquid channel part 60.

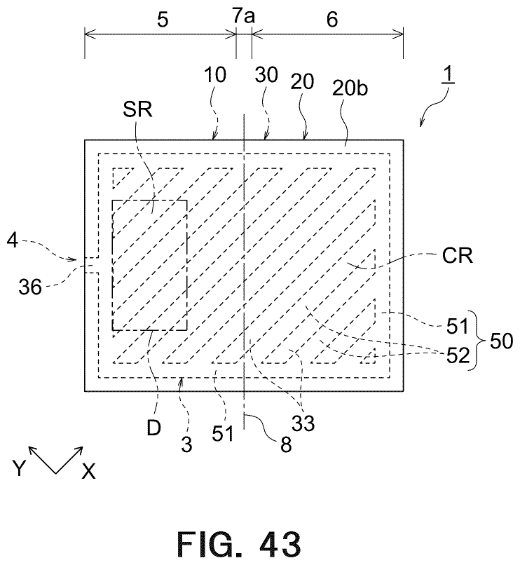

The foregoing description of the fifth embodiment is directed to the example in which the frame part 32 is in the form of a rectangular frame extending in the X-direction and the Y-direction. However, the present disclosure is not limited to such a configuration. For example, as illustrated in FIG. 43, the frame part 32 may be inclined relative to the land part 33 extending in the X-direction. The frame part 32 is in the form of a rectangular frame that is inclined relative to the X-direction and that is inclined relative to the Y-direction. The bend line 8 lies along the frame part 32. The bend line 8 extends in the transverse direction in FIG. 43. In this case as well, the bend line 8 extends in a direction crossing the X-direction in plan view. As in the example illustrated in FIGS. 38 to 41, in the example illustrated in FIG. 43 as well, the capillary action of the first liquid channel part 60 in the Y-direction can be increased in the bend region 7a. This can reduce stagnation of the working liquid 2b in each of the vapor passages 51 and 52 in the bend region 7a. As a result, the vapor chamber 1 can exhibit improved heat dissipation efficiency even in its bent state.

### Sixth Embodiment

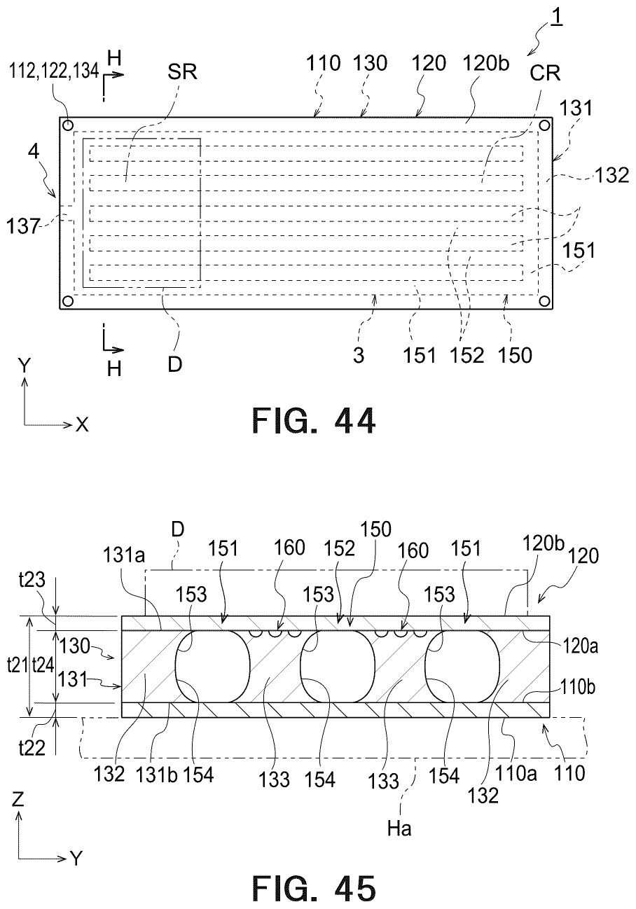

Now, reference is made to FIGS. 44 to 65 to describe a vapor chamber, an electronic apparatus, and a body sheet for a vapor chamber according to a sixth embodiment of the present disclosure.

The sixth embodiment illustrated in FIGS. 44 to 65 differs mainly in that an upper vapor channel recess increases in width with increasing distance from a first opening part toward an inner part. The sixth embodiment is otherwise substantially identical in configuration to the first embodiment illustrated in FIGS. 1 to 17C. Features in FIGS. 44 to 65 that are identical to those according to the first embodiment illustrated in FIGS. 1 to 17C are designated by the same reference signs and not described in further detail.

A vapor chamber has a thinner profile, and thus may undergo deformation when subjected to an external force. Consequently, a vapor channel part within the vapor chamber may partially collapse, which may result in reduced cross-sectional area of the vapor channel part. In this case, the vapor chamber may have a decreased capacity to transport the working vapor. This may potentially lead to deterioration of the performance of the vapor chamber.

The sixth embodiment is directed to addressing the above-mentioned circumstances. It is accordingly an object of the sixth embodiment to provide a body sheet for a vapor chamber capable of reducing performance deterioration of the vapor chamber, a vapor chamber, and an electronic apparatus.

As illustrated in FIGS. 44 and 45, the vapor chamber 1 according to the sixth embodiment includes a lower sheet 110, an upper sheet 120, and a body sheet 130, which is a body sheet used for a vapor chamber. The lower sheet 110 is an example of a second sheet. The upper sheet 120 is an example of a first sheet. The body sheet 130 is referred to also as wick sheet. The body sheet 130 is interposed between the lower sheet 110 and the upper sheet 120. The vapor chamber 1 according to the sixth embodiment is made up of the lower sheet 110, the upper sheet 120, and the body sheet 130. The lower sheet 110, the body sheet 130, and the upper sheet 120 are stacked in this order.

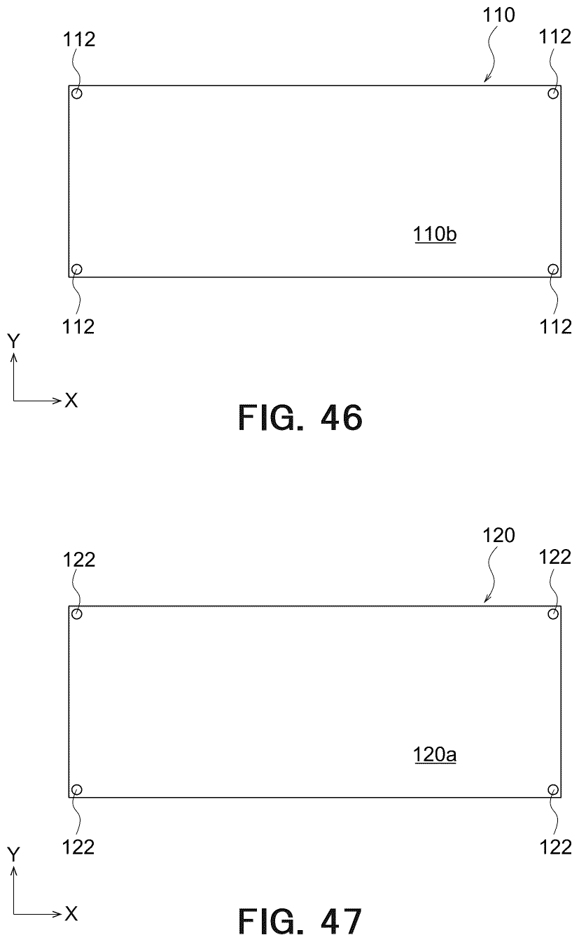

The vapor chamber 1 is generally in the form of a thin flat plate. Although the vapor chamber 1 may have any shape in plan view, the vapor chamber 1 may have a rectangular shape as illustrated in FIG. 44. The shape of the vapor chamber 1 in plan view may be, for example, a rectangle whose one side measures 10 mm or more and 200 mm or less and whose other side measures 50 mm or more and 600 mm or less, or may be a square whose one side measures 40 mm or more and 300 mm or less. The vapor chamber 1 may be of any dimensions in plan view. The following description of the sixth embodiment is directed by way of example to a case in which the shape of the vapor chamber 1 in plan view is a rectangle whose longitudinal direction is aligned with the X-direction and whose transverse direction is aligned with the Y-direction, which is orthogonal to the X-direction. In this case, as illustrated in FIGS. 46 to 48, the lower sheet 110, the upper sheet 120, and the body sheet 130 may likewise have a shape in plan view similar to that of the vapor chamber 1. The shape of the vapor chamber 1 in plan view is not limited to a rectangle but may be any shape, such as a circle, an ellipse, an L-shape, a T-shape, or a U-shape.

As illustrated in FIG. 44, the vapor chamber 1 includes the evaporation region SR where the working fluids 2a and 2b evaporate, and the condensation region CR where the working fluids 2a and 2b condense.

The evaporation region SR is a region that overlaps the electronic device D in plan view and to which the electronic device D is mounted. The evaporation region SR can be disposed at any location on the vapor chamber 1. In the illustrated example, the evaporation region SR is provided at the negative side in the X-direction of the vapor chamber 1. The negative side in the X-direction corresponds to the left side in FIG. 44. Heat from the electronic device D may be transferred not only to a region overlapping the electronic device D in plan view, but also to the vicinity of the region. Accordingly, the evaporation region SR can include a region overlapping the electronic device D, and the vicinity of the region. As used herein, the term “plan view” refers to viewing in a direction that is orthogonal to a face of the vapor chamber 1 that receives heat from the electronic device D, and that is orthogonal to a face of the vapor chamber 1 that releases the received heat. A face that receives heat corresponds to a first upper-sheet face 120a (described later) of the upper sheet 120. A face that releases heat corresponds to a first lower-sheet face 110a (described later) of the lower sheet 110. For example, as illustrated in FIG. 44, a plan view corresponds to a view of the vapor chamber 1 seen from above or from below.

The condensation region CR is a region that does not overlap the electronic device D in plan view, and that serves as a region where mainly the working vapor 2a releases its heat and condenses. The condensation region CR can be also said to be a region located around the evaporation region SR. In the illustrated example, the condensation region CR is provided at the positive side in the X-direction of the vapor chamber 1. The positive side in the X-direction corresponds to the right side in FIG. 44. In the condensation region CR, heat from the working vapor 2a is released to the lower sheet 110. The working vapor 2a is thus cooled and condenses in the condensation region CR.

If the vapor chamber 1 is installed inside a mobile terminal, the relative vertical positions mentioned above may be altered depending on how the mobile terminal is oriented. Nevertheless, according to the sixth embodiment, for convenience purposes, a sheet that receives heat from the electronic device D will be referred to as upper sheet 120, and a sheet that releases received heat will be referred to as lower sheet 110. The following description therefore assumes that the lower sheet 110 is disposed at a lower position, and the upper sheet 120 is disposed at an upper position.

As illustrated in FIG. 45, the lower sheet 110 has the first lower-sheet face 110a located opposite from the body sheet 130, and a second lower-sheet face 110b located opposite from the first lower-sheet face 110a. The second lower-sheet face 110b faces the body sheet 130. The lower sheet 110 may have a generally flat shape, and may have a generally constant thickness. The housing component Ha constituting a portion of the housing H of, for example, a mobile terminal is mounted to the first lower-sheet face 110a. A portion of the first lower-sheet face 110a may be covered by the housing component Ha. As illustrated in FIG. 46, an alignment hole 112 may be disposed at each of the four corners of the lower sheet 110.

As illustrated in FIG. 45, the upper sheet 120 includes the first upper-sheet face 120a facing the body sheet 130, and a second upper-sheet face 120b located opposite from the first upper-sheet face 120a. The upper sheet 120 may have a generally flat shape, and may have a generally constant thickness. The electronic device D mentioned above is mounted to the second upper-sheet face 120b. As illustrated in FIG. 47, an alignment hole 122 may be disposed at each of the four corners of the upper sheet 120.

As illustrated in FIG. 45, the body sheet 130 includes a sheet body 131, and a vapor channel part 150 disposed in the sheet body 131. The sheet body 131 includes a first body face 131a, and a second body face 131b located opposite from the first body face 131a. The first body face 131a faces the upper sheet 120. The second body face 131b faces the lower sheet 110.

The first upper-sheet face 120a of the upper sheet 120, and the first body face 131a of the sheet body 131 may be permanently bonded to each other through thermocompression bonding. Likewise, the second lower-sheet face 110b of the lower sheet 110, and the second body face 131b of the sheet body 131 may be permanently bonded to each other through thermocompression bonding. An example of thermocompression bonding is diffusion bonding. However, the method for bonding the lower sheet 110, the upper sheet 120, and the body sheet 130 to each other does not necessarily have to be diffusion bonding but may be any bonding method that allows these sheets to be permanently bonded to each other, such as brazing.

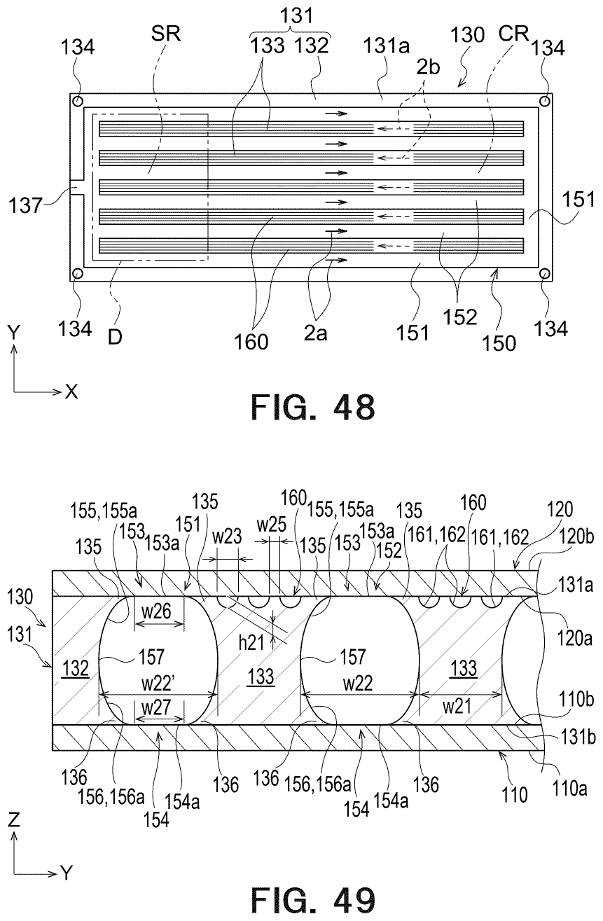

As illustrated in FIGS. 44 and 48, the sheet body 131 includes a frame part 132, which is in the form of a rectangular frame in plan view, and a plurality of land parts 133 disposed inside the frame part 132. The frame part 132 and the land part 133 are parts where the material of the body sheet 130 remains without being etched away in an etching step (described later).

In the illustrated example, the frame part 132 is in the form of a rectangular frame in plan view. The vapor channel part 150 is disposed inside the frame part 132. The vapor channel part 150 contains the working fluids 2a and 2b. The land parts 133 are disposed in the vapor channel part 150. The working vapor 2a flows around the land parts 133. The vapor channel part 150 includes the land parts 133 mentioned above, and the vapor passages 151 and 152 (described later). The vapor passages 151 and 152 are passages disposed around the land parts 133 and through which the working vapor 2a flows.

In the illustrated example, the land part 133 extends in the X-direction in plan view, and the land part 133 has an elongated rectangular shape in plan view. The X-direction corresponds to the left-right direction in FIG. 48. The land parts 133 are disposed in spaced parallel relation to each other in the Y-direction, which is orthogonal to the X-direction. The Y-direction corresponds to the up-down direction in FIG. 48. The land part 133 may have a width w21 (see FIG. 49) of, for example, 100 μm to 3000 μm. The width w21 of the land part 133 is a dimension of the land part 133 in the Y-direction. The width w21 means a dimension at a position in the Z-direction where an inner part 157 (described later) exists. The Z-direction corresponds to the thickness direction of the body sheet 130.

The frame part 132 and the land parts 133 are bonded to the lower sheet 110, and bonded to the upper sheet 120. A wall face 155 of an upper vapor channel recess 153 (described later), and a wall face 156 of a lower vapor channel recess 154 (described later) constitute a side wall of the land part 133. The first body face 131a and the second body face 131b of the sheet body 131 may have a flat shape extending across the frame part 132 and the land parts 133.

The vapor channel part 150 defines a channel through which mainly the working vapor 2a passes. The working liquid 2b may also pass through the vapor channel part 150. As illustrated in FIGS. 45 and 49, the vapor channel part 150 may extend from the first body face 131a of the sheet body 131 toward the second body face 131b, or may penetrate through the sheet body 131. The vapor channel part 150 may be covered at the first body face 131a by the upper sheet 120. The vapor channel part 150 may be covered at the second body face 131b by the lower sheet 110. A first opening part 153a of the upper vapor channel recess 153 (described later) is covered by the upper sheet 120, and a second opening part 154a of the lower vapor channel recess 154 (described later) is covered by the lower sheet 110.

As illustrated in FIG. 48, the vapor channel part 150 may include the first vapor passage 151, and a plurality of second vapor passages 152. The vapor channel part 150 is sectioned off by the land parts 133 into the first vapor passage 151 and the second vapor passages 152. The first vapor passage 151 is provided between the frame part 132 and the land part 133. The first vapor passage 151 is provided contiguously inside the frame part 132 and outside the land part 133. The first vapor passage 151 is in the form of a rectangular frame in plan view. The first vapor passage 151 may include a portion extending in the X-direction, and a portion extending in the Y-direction. The second vapor passage 152 is disposed between the land parts 133 that are adjacent to each other. The second vapor passage 152 extends in the X-direction in plan view. The second vapor passage 152 has an elongated rectangular shape in plan view.

As illustrated in FIG. 45, the first vapor passage 151 and the second vapor passage 152 may extend from the first body face 131a of the sheet body 131 toward the second body face 131b, or may penetrate through the sheet body 131. The first vapor passage 151 and the second vapor passage 152 are each defined by the upper vapor channel recess 153, and the lower vapor channel recess 154. The upper vapor channel recess 153 is disposed in the first body face 131a. The lower vapor channel recess 154 is disposed in the second body face 131b. The upper vapor channel recess 153 is an example of a first-body recess. The lower vapor channel recess 154 is an example of a second-body recess. The upper vapor channel recess 153 and the lower vapor channel recess 154 may extend in the X-direction. The upper vapor channel recess 153 and the lower vapor channel recess 154 communicate with each other to define each of the first vapor passage 151 and the second vapor passage 152.

The upper vapor channel recess 153 is formed in a recessed shape in the first body face 131a through etching of the first body face 131a of the body sheet 130 in an etching step (described later). As used herein, the expression “formed in a recessed shape in the first body face 131a” means being formed so as to recess from the first body face 131a. The upper vapor channel recess 153 thus includes the wall face 155 having a curved shape as illustrated in FIG. 49.

As illustrated in FIG. 49, the upper vapor channel recess 153 includes the first opening part 153a, and the inner part 157, which is located closer to the second body face 131b than is the first opening part 153a. The first opening part 153a is provided at the first body face 131a. The inner part 157 is located inside of the sheet body 131 in the thickness direction of the sheet body 131. The inner part 157 is located lower in FIG. 49 than is the first opening part 153a. As seen in cross-sectional view illustrated in FIG. 49, the inner part 157 is a part of the upper vapor channel recess 153 where the upper vapor channel recess 153 is widest. The inner part 157 is located at the lower end of the upper vapor channel recess 153. The term “cross-sectional view” in this case refers to viewing in a cross-section orthogonal to the X-direction in which the upper vapor channel recess 153 and the lower vapor channel recess 154 extends. FIG. 49 illustrates, as an example of such cross-sectional view, a cross-section of the vapor chamber 1, taken along a YZ cross-section extending in the Y-direction and the Z-direction and viewed in the X-direction orthogonal to the Z-direction.

As illustrated in FIG. 49, in cross-sectional view, the upper vapor channel recess 153 increases in width with increasing distance from the first opening part 153a toward the inner part 157. Due to the configuration mentioned above, the sheet body 131 of the body sheet 130 is provided with an upper-sheet support 135. The upper-sheet support 135 is provided at a location in the sheet body 131 near the upper sheet 120. The upper-sheet support 135 protrudes from the frame part 132 and the land part 133 toward the inside of the upper vapor channel recess 153. The upper-sheet support 135 abuts on the first upper-sheet face 120a and supports the upper sheet 120. This makes it possible to resist the bending stress that the upper sheet 120 experiences when subjected to an external force, and consequently reduce a deformation of the upper sheet 120 that causes the upper sheet 120 to extend into the upper vapor channel recess 153. This can reduce collapse of a portion of the upper vapor channel recess 153, and consequently reduce a decrease in the channel cross-sectional area of the upper vapor channel recess 153.

As illustrated in FIG. 49, in cross-sectional view, the wall face 155 of the upper vapor channel recess 153 includes a first boundary edge 155a, which extends from the first opening part 153a to the inner part 157. The first boundary edge 155a has a curved shape. The first boundary edge 155a is curved toward the outside of the upper vapor channel recess 153.

The upper vapor channel recess 153 configured as described above constitutes a portion of the first vapor passage 151, and a portion of the second vapor passage 152. The upper vapor channel recess 153 constitutes the upper half of the first vapor passage 151, and the upper half of the second vapor passage 152.

The lower vapor channel recess 154 is formed in a recessed shape in the second body face 131b through etching of the second body face 131b of the body sheet 130 in an etching step (described later). As used herein, the expression “formed in a recessed shape in the second body face 131b” means being formed so as to recess from the second body face 131b. The lower vapor channel recess 154 thus includes the wall face 156 having a curved shape as illustrated in FIG. 49.

As illustrated in FIG. 49, the lower vapor channel recess 154 includes the second opening part 154a. The second opening part 154a is provided at the second body face 131b. The inner part 157 mentioned above is located at the upper end of the lower vapor channel recess 154. It can thus be also said that the lower vapor channel recess 154 includes the inner part 157 that is shared in common with the upper vapor channel recess 153. The upper vapor channel recess 153 and the lower vapor channel recess 154 are connected at the inner part 157 and communicate with each other. The first opening part 153a of the upper vapor channel recess 153 may have a width w26 equal to a width w27 of the second opening part 154a of the lower vapor channel recess 154.

As illustrated in FIG. 49, in cross-sectional view, the lower vapor channel recess 154 increases in width with increasing distance from the second opening part 154a toward the inner part 157. Due to the configuration mentioned above, the sheet body 131 of the body sheet 130 is provided with a lower-sheet support 136. The lower-sheet support 136 is provided at a location in the sheet body 131 near the lower sheet 110. The lower-sheet support 136 protrudes from the frame part 132 and the land part 133 toward the inside of the lower vapor channel recess 154. The lower-sheet support 136 abuts on the second lower-sheet face 110b and supports the lower sheet 110. This makes it possible to resist the bending stress that the lower sheet 110 experiences when subjected to an external force, and consequently reduce a deformation of the lower sheet 110 that causes the lower sheet 110 to extend into the lower vapor channel recess 154. This can reduce collapse of a portion of the lower vapor channel recess 154, and consequently can reduce a decrease in the channel cross-sectional area of the lower vapor channel recess 154.

As illustrated in FIG. 49, in cross-sectional view, the wall face 156 of the lower vapor channel recess 154 includes a second boundary edge 156a, which extends from the second opening part 154a to the inner part 157. The second boundary edge 156a has a curved shape. The second boundary edge 156a is curved toward the outside of the lower vapor channel recess 154.

The lower vapor channel recess 154 configured as described above constitutes a portion of the first vapor passage 151, and a portion of the second vapor passage 152. The lower vapor channel recess 154 constitutes the lower half of the first vapor passage 151, and the lower half of the second vapor passage 152.

The first boundary edge 155a and the second boundary edge 156a are each curved toward the inner part 157, and may be smoothly connected with each other in a seamless manner at the inner part 157.

The shape of the first vapor passage 151 in plan view is defined by the first opening part 153a or the second opening part 154a. The shape of the second vapor passage 152 in plan view is defined by the first opening part 153a or the second opening part 154a.

In cross-sectional view as illustrated in FIG. 49, the upper vapor channel recess 153 and the lower vapor channel recess 154 are widest at the inner part 157. At the inner part 157, the upper vapor channel recess 153 and the lower vapor channel recess 154 may each have a width w22 or w22′ of, for example, 400 μm to 1600 μm. The width w22 is a dimension of the second vapor passage 152 in the Y-direction, which means a dimension at a position in the Z-direction where the inner part 157 exists. The width w22′ of the first vapor passage 151 is a dimension of the first vapor passage 151 in the X-direction or the Y-direction, which means a dimension at a position in the Z-direction where the inner part 157 exists. As with the width w22 mentioned above, the width w22′ may be, for example, 400 μm to 1600 μm.

The position of the inner part 157 in the Z-direction may be the midway position between the first body face 131a and the second body face 131b, or may be offset downward or upward from the midway position. The inner part 157 may be located at any position as long as the upper vapor channel recess 153 and the lower vapor channel recess 154 communicate with each other.

In the illustrated example, the first boundary edge 155a and the second boundary edge 156a extend in a curved manner toward the outside of the vapor channel part 150. This, however, is not intended to be limiting. For example, the first boundary edge 155a and the second boundary edge 156a may extend linearly from the opening parts 153a and 154a toward the inner part 157, or may extend in the shape of a convex curve toward the inside of the vapor channel part 150.

The vapor channel part 150 configured as described above constitutes a portion of the hermetically sealed space 3 mentioned above. As illustrated in FIG. 45, the first vapor passage 151 and the second vapor passage 152 of the vapor channel part 150 are defined mainly by the lower sheet 110, the upper sheet 120, and the frame part 132 and the land part 133 of the sheet body 131 mentioned above. The first vapor passage 151 and the second vapor passage 152 each have a relatively large channel cross-sectional area to allow passage of the working vapor 2a therethrough.

It is to be noted that for clarity of illustration, FIG. 45 depicts features such as the first vapor passage 151 and the second vapor passage 152 in enlarged scale. The numbers, locations, or other details of the features such as the vapor passages 151 and 152 in FIG. 45 differ from those illustrated in FIGS. 44 and 48.

A plurality of supports (not illustrated) for supporting the land part 133 to the frame part 132 may be disposed in the vapor channel part 150. A support for supporting the land parts 133 that are adjacent to each other may be provided. These supports may be disposed on both sides of the land part 133 in the X-direction, or may be disposed on both sides of the land part 133 in the Y-direction. Each support may be provided in a manner that does not obstruct the flow of the working vapor 2a that diffuses in the vapor channel part 150. For example, the support may be disposed at a position near one of the first body face 131a and the second body face 131b of the sheet body 131, and a space defining a vapor channel recess may be provided at a position near the other one of the first body face 131a and the second body face 131b. The support can be thus made thinner than the sheet body 131. This can prevent the first vapor passage 151 and the second vapor passage 152 from being split into separate parts in the X-direction and the Y-direction.

As illustrated in FIGS. 45, 48, and 49, the first liquid channel part 160 through which mainly the working liquid 2b passes may be disposed in the first body face 131a of the sheet body 131. More specifically, the first liquid channel part 160 may be disposed in the first body face 131a of each land part 133 of the sheet body 131. The working vapor 2a may also pass through the first liquid channel part 160. The first liquid channel part 160 constitutes a portion of the hermetically sealed space 3 mentioned above. The first liquid channel part 160 communicates with the vapor channel part 150. The first liquid channel part 160 is implemented as a capillary structure (wick) for transporting the working liquid 2b to the evaporation region SR. The first liquid channel part 160 may be provided across the entire first body face 131a of each land part 133 of the sheet body 131. In the illustrated example, the first liquid channel part 160 is not disposed in the second body face 131b of each land part 133 of the sheet body 131. Alternatively, however, the first liquid channel part 160 may be disposed in the second body face 131b of the land part 133 of the sheet body 131.

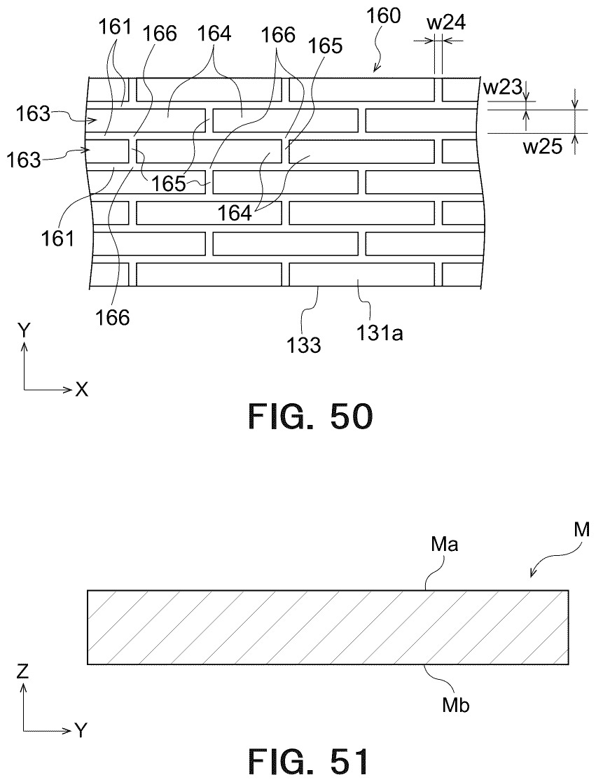

As illustrated in FIG. 50, the first liquid channel part 160 may include a plurality of grooves disposed in the first body face 131a. More specifically, the first liquid channel part 160 may include a plurality of main flow grooves 161 through which the working liquid 2b passes, and a plurality of communication grooves 165 communicating with the main flow grooves 161.

Each main flow groove 161 extends in the X-direction as illustrated in FIG. 50. To ensure that mainly the working liquid 2b flows through the main flow groove 161 due to capillary action, the main flow groove 161 has a channel cross-sectional area smaller than that of the first vapor passage 151 or the second vapor passage 152 of the vapor channel part 150. The main flow groove 161 is thus configured to transport, to the evaporation region SR, the working liquid 2b that has condensed from the working vapor 2a. The main flow grooves 161 may be spaced apart from each other in the Y-direction.

The main flow groove 161 is formed in an etching step (described later) through etching of the first body face 131a of the sheet body 131. The main flow groove 161 thus includes a curved wall face 162 as illustrated in FIG. 49. The wall face 162 defines the main flow groove 161, and has a curved shape that is recessed toward the second body face 131b.

The main flow groove 161 illustrated in FIGS. 49 and 50 may have a width w23 of, for example, 5 μm to 150 μm. The width w23 of the main flow groove 161 means a dimension at the location of the first body face 131a, and corresponds to a dimension in the Y-direction. The main flow groove 161 illustrated in FIG. 49 may have a depth h21 of, for example, 3 μm to 150 μm. The depth h21 corresponds to a dimension in the Z-direction.

As illustrated in FIG. 50, each communication groove 165 extends in a direction different from the X-direction. In the illustrated example, each communication groove 165 extends in the Y-direction, and is perpendicular to the main flow groove 161. Some communication grooves 165 are positioned to provide communication between two mutually adjacent liquid-channel main flow grooves 161. Other communication grooves 165 are positioned to provide communication between the vapor passage 151 or 152 and the main flow groove 161. That is, each of the other communication grooves 165 extends from an edge of the land part 133 in the Y-direction to the main flow groove 161 adjacent to the edge. In this way, each of the vapor passages 151 and 152, and the main flow groove 161 communicate with each other.

To ensure that mainly the working liquid 2b flows through the communication groove 165 due to capillary action, the communication groove 165 has a channel cross-sectional area smaller than the channel cross-sectional area of each of the vapor passages 151 and 152. The communication grooves 165 may be spaced apart from each other in the X-direction.

As with the main flow groove 161, the communication groove 165 is formed through etching, and includes a curved wall face (not illustrated) similar to that of the main flow groove 161. The communication groove 165 illustrated in FIG. 50 may have a width w24 equal to the width w23 of the main flow groove 161. Alternatively, however, the width w24 may be greater than the width w23, or may be less than the width w23. The width w24 corresponds to a dimension in the X-direction. The communication groove 165 may have a depth equal to the depth h21 of the main flow groove 161. Alternatively, however, the depth of the communication groove 165 may be greater than the depth h21, or may be less than the depth h21.

As illustrated in FIG. 50, the first liquid channel part 160 may include projection rows 163 disposed on the first body face 131a of the sheet body 131. Each projection row 163 is disposed between two mutually adjacent main flow grooves 161. Each projection row 163 includes a plurality of projections 164 arrayed in the X-direction. The projection 164 is disposed in the first liquid channel part 160, and abuts on the first upper-sheet face 120a of the upper sheet 120. Each projection 164 has a rectangular shape in plan view with its longitudinal direction aligned with the X-direction. The main flow groove 161 is interposed between two projections 164 that are adjacent to each other in the Y-direction. The communication groove 165 is interposed between two projections 164 that are adjacent to each other in the X-direction. The communication groove 165 extends in the Y-direction, and provides communication between two main flow grooves 161 that are adjacent to each other in the Y-direction. This allows the working liquid 2b to move back and forth between the main flow grooves 161.

The projection 164 is a part where the material of the body sheet 130 remains without being etched away in an etching step (described later). As illustrated in FIG. 50, the shape of the projection 164 in plan view may be a rectangle. The shape of the projection 164 in plan view may be the shape at the location of the first body face 131a.

As illustrated in FIG. 50, the projections 164 may be disposed in a staggered arrangement. More specifically, the respective projections 164 of two mutually adjacent projection rows 163 in the Y-direction may be positioned offset relative to each other in the X-direction. The amount of offset may be half the array pitch of the projections 164 in the X-direction. The projection 164 may have a width w25 of, for example, 5 μm to 500 μm. The width w25 corresponds to a dimension in the Y-direction. The width w25 of the projection 164 means a dimension at the location of the first body face 131a. The projections 164 are not necessarily disposed in a staggered arrangement. Alternatively, the projections 164 may be arrayed in parallel with each other. In this case, the respective projections 164 of two mutually adjacent projection rows 163 in the Y-direction are aligned with each other also in the X-direction.

The main flow groove 161 includes an intersection 166 communicating with the communication groove 165. At the intersection 166, the main flow groove 161 and the communication groove 165 communicate with each other by intersecting in a T-shape. This configuration makes it possible to avoid a situation in which, at the intersections 166, the intersections 166 located on opposite sides of the communication groove 165 both communicate with the main flow groove 161. Consequently, at the above-mentioned intersection 166, the wall face 162 of the main flow groove 161 can be prevented from being cut away on both sides in the Y-direction, and a portion of the wall face 162 opposite from the main flow groove 161 is thus allowed to remain. As a result, even at the intersection 166, capillary action can be imparted to the working liquid within the main flow groove 161. This can mitigate a decrease, at the intersection 166, of the magnitude of the propulsion force that causes the working liquid 2b to travel toward the evaporation region SR. The opposite sides in the Y-direction correspond to the upper and lower sides in FIG. 8.

As illustrated in FIG. 48, an alignment hole 134 may be disposed at each of the four corners of the sheet body 131 of the body sheet 130. Although the alignment hole 134 has a circular shape in plan view in the example illustrated in FIG. 48, this is not intended to be limiting. The alignment hole 134 may penetrate through the sheet body 131.

As illustrated in FIG. 44, the vapor chamber 1 may include the injection part 4 for injecting the working liquid 2b into the hermetically sealed space 3. In the example illustrated in FIG. 44, the injection part 4 may be disposed at an edge located at the negative side in the X-direction, or may be disposed near the evaporation region SR. The negative side in the X-direction corresponds to the left side in FIG. 2. The injection part 4 may include an injection channel 137 provided in the body sheet 130. The injection channel 137 may be sealed off after the working liquid 2b is injected.

The lower sheet 110, the upper sheet 120, and the body sheet 130 may each be made of any material without particular limitation, as long as the material has favorable thermal conductivity. For example, the lower sheet 110, the upper sheet 120, and the body sheet 130 may contain copper or a copper alloy. This configuration can improve the thermal conductivity of the sheets 110, 120, and 130, and consequently can improve the heat dissipation efficiency of the vapor chamber 1. This configuration can also prevent corrosion for cases where pure water is used as the working fluids 2a and 2b. The sheets 110, 120, and 130 can be each made of other metals such as aluminum or titanium, or other metallic alloys such as stainless steel, as long as use of such metallic materials allows a desired heat dissipation efficiency to be attained and also enables corrosion prevention. The lower sheet 110, the upper sheet 120, and the body sheet 130 may be each made of a material similar to the material of each of the first sheet 10, the second sheet 20, and the wick sheet 30 mentioned above.

The vapor chamber 1 illustrated in FIG. 45 may have a thickness t21 of, for example, 100 μm to 1000 μm. Making the thickness t21 of the vapor chamber 1 greater than or equal to 100 μm can ensure adequate space for the vapor channel part 150, and proper functioning of the vapor chamber 1. By contrast, making the thickness t21 less than or equal to 1000 μm can mitigate an increase in the thickness t21 of the vapor chamber 1.

The lower sheet 110 illustrated in FIG. 45 may have a thickness t22 of, for example, 6 μm to 100 μm. Making the thickness t22 of the lower sheet 110 greater than or equal to 6 μm can ensure mechanical strength of the lower sheet 110. By contrast, making the thickness t22 of the lower sheet 110 less than or equal to 100 μm can mitigate an increase in the thickness t21 of the vapor chamber 1. Likewise, the upper sheet 120 illustrated in FIG. 45 may have a thickness t23 that is set similarly to the thickness t22 of the lower sheet 110. The thickness t23 of the upper sheet 120, and the thickness t22 of the lower sheet 110 may be different.

The body sheet 130 illustrated in FIG. 45 may have a thickness t24 of, for example, 50 μm to 400 μm. Making the thickness t24 of the body sheet 130 greater than or equal to 50 μm can ensure adequate space for the vapor channel part 150, and proper functioning of the vapor chamber 1. By contrast, making the thickness t24 less than or equal to 400 μm can mitigate an increase in the thickness t21 of the vapor chamber 1.

A method for manufacturing the vapor chamber 1 configured as described above is now described with reference to FIGS. 51 to 55.

Now, reference is first made to a sheet preparing step, which is a step of preparing the sheets 110, 120, and 130. The sheet preparing step includes the following steps: a lower-sheet preparing step of preparing the lower sheet 110; an upper-sheet preparing step of preparing the upper sheet 120; and a body-sheet preparing step of preparing the body sheet 130.

In the lower-sheet preparing step, first, a lower-sheet base material with a desired thickness is prepared. The lower-sheet base material may be a rolled material. Subsequently, the lower sheet 110 having a desired shape in plan view is formed through etching of the lower-sheet base material. Alternatively, the lower sheet 110 having a desired shape in plan view may be formed through press working of the lower-sheet base material. In this way, the lower sheet 110 having an outline shape as illustrated in FIG. 46 can be prepared.

Likewise, in the upper-sheet preparing step, first, an upper-sheet base material with a desired thickness is prepared in a manner similar to the lower-sheet preparing step. The upper-sheet base material may be a rolled material. Subsequently, the upper sheet 120 having a desired shape in plan view is formed through etching of the upper-sheet base material. Alternatively, the upper sheet 120 having a desired shape in plan view may be formed through press working of the upper-sheet base material. In this way, the upper sheet 120 having an outline shape as illustrated in FIG. 47 can be prepared.

The body-sheet preparing step includes a material-sheet preparing step, a resist-pattern forming step, an etching step, and a resist-pattern removing step. The material-sheet preparing step is a step of preparing a metallic material sheet M. The resist-pattern forming step is a step of forming a resist pattern on the metallic material sheet M. The etching step is a step of etching the metallic material sheet M. The resist-pattern removing step is a step of removing a resist pattern.

First, in the material-sheet preparing step, the metallic material sheet M having a flat shape and including a first material face Ma and a second material face Mb is prepared as illustrated in FIG. 51. The metallic material sheet M may be a rolled material with a desired thickness.

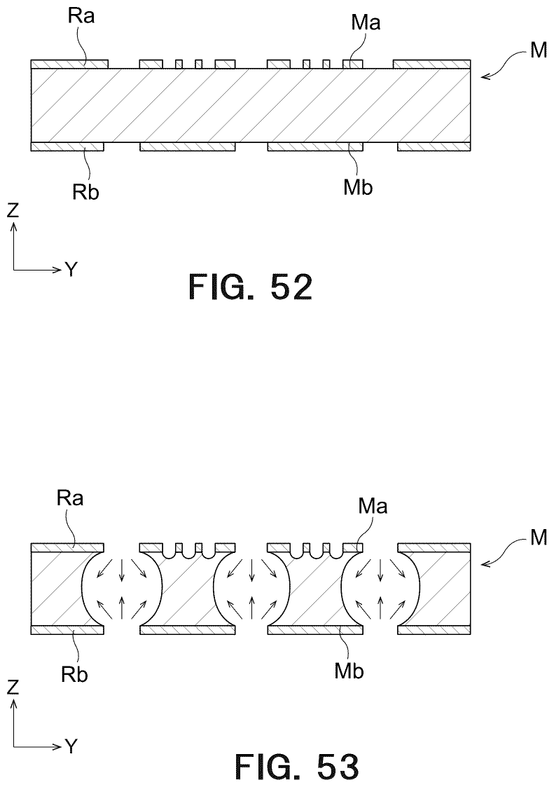

In the subsequent resist-pattern forming step, first, a resist film is formed on the first material face Ma and the second material face Mb of the metallic material sheet M. The resist film includes a photosensitive resist material. The resist film is a film on which patterns for the above-mentioned features such as the vapor channel part 150 and the first liquid channel part 160 are to be formed through exposure and development performed on the resist film. The resist film formed as described above is then subjected to exposure and development. Thus, as illustrated in FIG. 52, a first resist pattern Ra can be formed on the first material face Ma of the metallic material sheet M, and a second resist pattern Rb can be formed on the second material face Mb of the metallic material sheet M.

In the subsequent etching step, as illustrated in FIG. 53, the metallic material sheet M is etched to form the vapor channel part 150 and the first liquid channel part 160. More specifically, the first material face Ma and the second material face Mb of the metallic material sheet M are etched via openings provided in the resist patterns Ra and Rb. The first material face Ma and the second material face Mb of the metallic material sheet M are thus etched into a patterned shape, and the vapor channel part 150 and the first liquid channel part 160 are formed as illustrated in FIG. 53.

In the etching step, the pressure at which an etchant is supplied to a location where the vapor channel part 150 is to be formed may be higher than the pressure at which etchant is supplied to other locations, such as a location where the first liquid channel part 160 is to be formed. This makes it possible to form the upper vapor channel recess 153 and the lower vapor channel recess 154 that increase in width with increasing distance from the opening parts 153a and 154a, respectively, toward the inner part 157. A suitable example of the etchant may be an iron chloride etchant such as an aqueous ferric chloride solution, or a copper chloride etchant such as an aqueous copper chloride solution. For example, an etching process for forming the vapor channel part 150 may be performed as a step separate from an etching process performed to form the first liquid channel part 160.

In the etching step, the first material face Ma and the second material face Mb of the metallic material sheet M may be etched simultaneously. However, the present disclosure is not limited to such a configuration. Alternatively, etching of the first material face Ma, and etching of the second material face Mb may be performed individually as separate steps.

In the etching step, through etching of the first material face Ma and the second material face Mb of the metallic material sheet M, a predetermined outline shape as illustrated in FIG. 48 can be obtained. The body sheet 130 having outer edges as illustrated in FIG. 48 can be thus obtained.

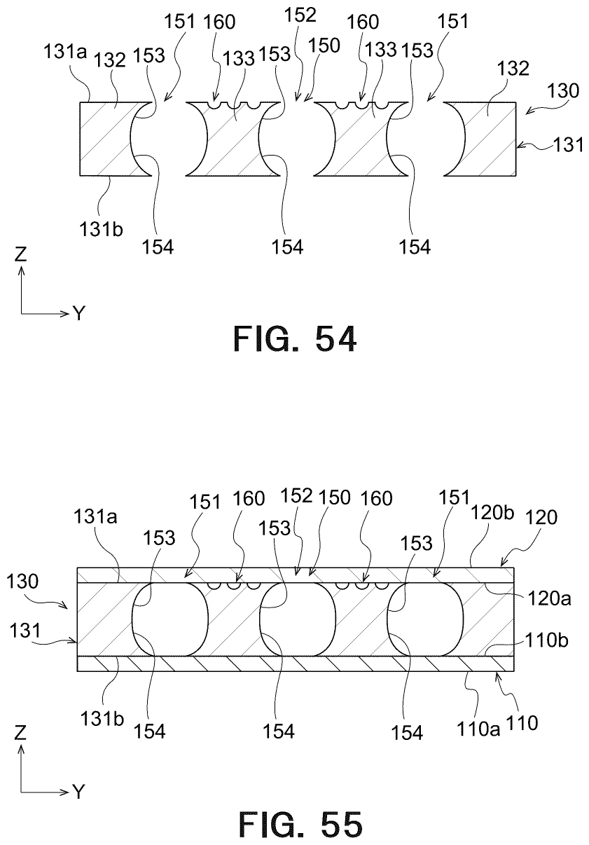

In the subsequent resist-pattern removing step, for example, the resist patterns Ra and Rb are removed from the body sheet 130 as illustrated in FIG. 54 by use of an alkaline stripping solution.

In this way, the body sheet 130 as illustrated in FIG. 48 can be prepared.

The preparing step is followed by a bonding step in which, as illustrated in FIG. 55, the lower sheet 110, the upper sheet 120, and the body sheet 130 are bonded to each other.

More specifically, first, the lower sheet 110, the body sheet 130, and the upper sheet 120 are stacked in this order. In this case, the second body face 131b of the body sheet 130 is overlaid on the second lower-sheet face 110b of the lower sheet 110, and the first upper-sheet face 120a of the upper sheet 120 is overlaid on the first body face 131a of the body sheet 130. Positioning of the sheets 110, 120, and 130 may be performed by using the alignment hole 112 of the lower sheet 110, the alignment hole 134 of the body sheet 130, and the alignment hole 122 of the upper sheet 120.

Subsequently, the lower sheet 110, the body sheet 130, and the upper sheet 120 are temporarily fastened together. For example, the sheets 110, 120, and 130 may be temporarily fastened together by resistance spot welding, or the sheets 110, 120, and 130 may be temporarily fastened together by laser welding.

Subsequently, the lower sheet 110, the upper sheet 120, and the body sheet 130 are permanently bonded to each other by thermocompression bonding. For example, the sheets 110, 120, and 130 may be permanently bonded to each other by diffusion bonding. Consequently, the hermetically sealed space 3 including the vapor channel part 150 and the first liquid channel part 160 is formed between the lower sheet 110 and the upper sheet 120. At this point, the hermetically sealed space 3 mentioned above has not yet been sealed off, and thus communicates with the external environment via the injection channel 137.

The bonding step is followed by an injection step, in which the working liquid 2b is injected into the hermetically sealed space 3 from the injection channel 137 of the injection part 4.

The injection step is followed by a sealing step, in which the injection channel 137 is sealed off. This cuts off communication between the hermetically sealed space 3 and the external environment, resulting in hermetic sealing of the hermetically sealed space 3. As a result, the hermetically sealed space 3 with the working liquid 2b sealed therein can be obtained. This can prevent external leakage of the working liquid 2b sealed in the hermetically sealed space 3.

In this way, the vapor chamber 1 according to the sixth embodiment can be obtained.

Reference is now made to how the vapor chamber 1 operates, that is, how the electronic device D is cooled.

The vapor chamber 1 obtained as described above is installed inside the housing H of, for example, a mobile terminal, and the electronic device D, which is a device to be cooled such as a CPU, is mounted to the second upper-sheet face 120b of the upper sheet 120. Alternatively, the vapor chamber 1 is mounted to the electronic device D. The working liquid 2b within the hermetically sealed space 3 adheres, due to its surface tension, to the wall face of the hermetically sealed space 3. More specifically, the working liquid 2b adheres to the following wall faces: the wall face 155 of the upper vapor channel recess 153; the wall face 156 of the lower vapor channel recess 154; the wall face 162 of the main flow groove 161 of the first liquid channel part 160; and the wall face of the communication groove 165 of the first liquid channel part 160. The working liquid 2b may also adhere to a portion of the second lower-sheet face 110b of the lower sheet 110 that is exposed to the lower vapor channel recess 154. The working liquid 2b may also adhere to portions of the first upper-sheet face 120a of the upper sheet 120 that are exposed to the following areas: the upper vapor channel recess 153, the main flow groove 161, and the communication groove 165.

When the electronic device D generates heat in this state, the working liquid 2b in the evaporation region SR (see FIG. 48) receives heat from the electronic device D.

As the received heat is absorbed as latent heat, the working liquid 2b evaporates, and the working vapor 2a is generated. As indicated by solid arrows in FIG. 48, most of the generated working vapor 2a diffuses within the upper vapor channel recess 153 and the lower vapor channel recess 154 that constitute the hermetically sealed space 3. The working vapor 2a within each of the vapor channel recesses 153 and 154 moves away from the evaporation region SR, and most of the working vapor 2a is transported to the condensation region CR, which corresponds to a region at the right side in FIG. 48 and is at a relatively low temperature. In the condensation region CR, the working vapor 2a is cooled by rejecting heat mainly to the lower sheet 110. The heat received by the lower sheet 110 from the working vapor 2a is transferred to the outside air via the housing component Ha (see FIG. 45).

As the working vapor 2a rejects heat to the lower sheet 110 in the condensation region CR, the working vapor 2a condenses by giving off the latent heat absorbed in the evaporation region SR, and the working liquid 2b is generated. The generated working liquid 2b adheres to the respective wall faces 155 and 156 of the vapor channel recesses 153 and 154, the second lower-sheet face 110b of the lower sheet 110, and the first upper-sheet face 120a of the upper sheet 120. At this time, the working liquid 2b keeps evaporating in the evaporation region SR. Accordingly, as indicated by dashed arrows in FIG. 48, the working liquid 2b in the condensation region CR of the first liquid channel part 160 is transported by the capillary action of each main flow groove 161 toward the evaporation region SR. Consequently, the working liquid 2b adhering on the wall faces 155 and 156, the second lower-sheet face 110b, and the first upper-sheet face 120a moves to the first liquid channel part 160, where the working liquid 2b passes through the communication groove 165 into the main flow groove 161. In this way, each main flow groove 161 and each communication groove 165 are filled with the working liquid 2b. The working liquid 2b now filling these grooves thus gains, due to the capillary action of each main flow groove 161, a propulsion force that causes the working liquid 2b to move toward the evaporation region SR. The working liquid 2b is thus smoothly transported toward the evaporation region SR.

In the first liquid channel part 160, each main flow groove 161 communicates with another adjacent main flow groove 161 via the corresponding communication groove 165. The working liquid 2b thus moves back and forth between the main flow grooves 161 that are adjacent to each other. This reduces the risk of dry-out in the main flow grooves 161. As a result, capillary action is imparted to the working liquid 2b within each main flow groove 161, and the working liquid 2b is thus smoothly transported toward the evaporation region SR.

Upon reaching the evaporation region SR, the working liquid 2b evaporates by receiving heat from the electronic device D again. The working vapor 2a evaporated from the working liquid 2b passes through the communication groove 165 within the evaporation region SR to the upper vapor channel recess 153 and the lower vapor channel recess 154, each of which has a large channel cross-sectional area. The working vapor 2a then diffuses within each of the vapor channel recesses 153 and 154. In this way, as the working fluids 2a and 2b undergo refluxing within the hermetically sealed space 3 while repeating phase changes, that is, evaporation and condensation, the heat from the electronic device D is transported and released. As a result, the electronic device D is cooled.

The vapor chamber 1 has a thinner profile, and thus may undergo deformation when subjected to an external force. A possible consequence of such deformation of the vapor chamber 1 is that the upper vapor channel recess 153 and the lower vapor channel recess 154 within the vapor chamber 1 may partially collapse, which may cause the upper vapor channel recess 153 and the lower vapor channel recess 154 to decrease in channel cross-sectional area. In this case, the vapor chamber 1 may have a decreased capacity to transport the working vapor 2a. This may potentially lead to deterioration of the performance of the vapor chamber 1.

In this regard, according to the sixth embodiment, in cross-sectional view, the upper vapor channel recess 153 increases in width with increasing distance from the first opening part 153a toward the inner part 157. Due to the configuration mentioned above, the sheet body 131 of the body sheet 130 is provided with the upper-sheet support 135, which supports the upper sheet 120. This configuration makes it possible to resist the bending stress that the upper sheet 120 experiences when subjected to an external force, and consequently reduce a deformation of the upper sheet 120 that causes the upper sheet 120 to extend into the upper vapor channel recess 153. This can reduce collapse of a portion of the upper vapor channel recess 153, and consequently can reduce a decrease in the channel cross-sectional area of the upper vapor channel recess 153. This in turn can reduce deterioration of the capacity with which the vapor chamber 1 transports the working vapor 2a, and consequently can reduce performance deterioration of the vapor chamber 1.

According to the sixth embodiment, the first boundary edge 155a of the upper vapor channel recess 153 is curved toward the outside of the upper vapor channel recess 153. The upper vapor channel recess 153 can thus have an increased channel cross-sectional area. This can further reduce deterioration of the capacity with which the vapor chamber 1 transports the working vapor 2a, and consequently can further reduce performance deterioration of the vapor chamber 1.

According to the sixth embodiment, in cross-sectional view, the lower vapor channel recess 154 increases in width with increasing distance from the second opening part 154a toward the inner part 157. Due to the configuration mentioned above, the sheet body 131 of the body sheet 130 is provided with the lower-sheet support 136, which supports the lower sheet 110. This configuration makes it possible to resist the bending stress that the lower sheet 110 experiences when subjected to an external force, and consequently reduce a deformation of the lower sheet 110 that causes the lower sheet 110 to extend into the lower vapor channel recess 154. This can reduce collapse of a portion of the lower vapor channel recess 154, and the consequent decrease in the channel cross-sectional area of the lower vapor channel recess 154. This in turn can further reduce deterioration of the capacity with which the vapor chamber 1 transports the working vapor 2a, and consequently can further reduce performance deterioration of the vapor chamber 1.

According to the sixth embodiment, the second boundary edge 156a of the lower vapor channel recess 154 is curved toward the outside of the lower vapor channel recess 154. This configuration makes it possible to increase the channel cross-sectional area of the lower vapor channel recess 154. This can further reduce deterioration of the capacity with which the vapor chamber 1 transports the working vapor 2a, and consequently can further reduce performance deterioration of the vapor chamber 1.

According to the sixth embodiment, the first boundary edge 155a of the upper vapor channel recess 153 is curved toward the outside of the upper vapor channel recess 153, and the second boundary edge 156a of the lower vapor channel recess 154 is curved toward the outside of the lower vapor channel recess 154. This configuration can ensure that the first boundary edge 155a and the second boundary edge 156a do not include a protrusion that protrudes toward the inside of the vapor channel part 150. This can ensure that within the vapor channel part 150, flow of the working vapor 2a is not obstructed by such a protrusion. The working vapor 2a can be thus smoothly transported. This in turn can further reduce deterioration of the capacity with which the vapor chamber 1 transports the working vapor 2a, and consequently can further reduce performance deterioration of the vapor chamber 1.

### First Modification

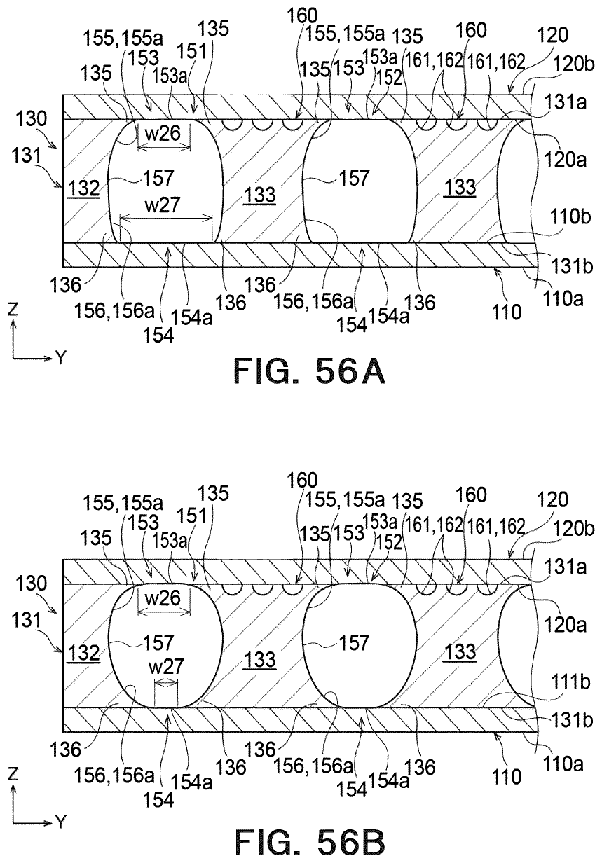

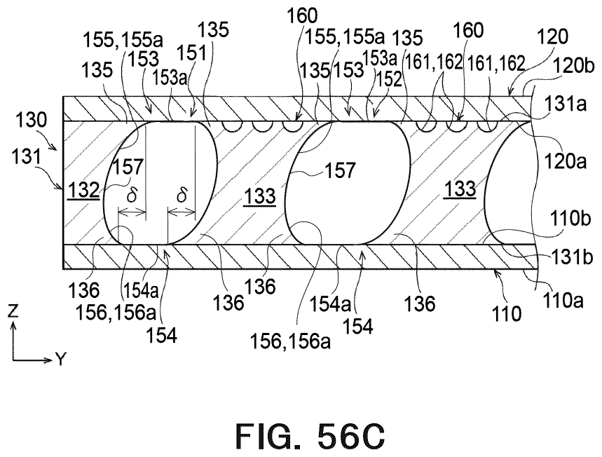

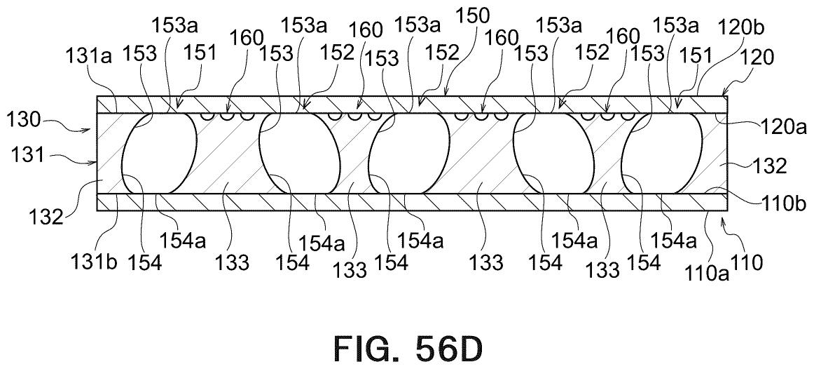

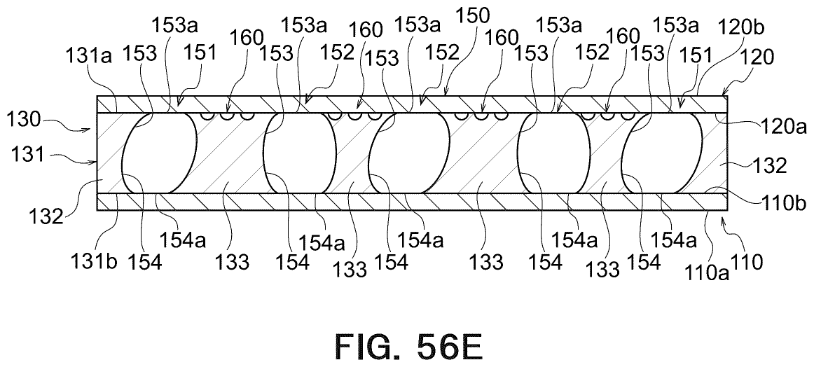

The foregoing description of the sixth embodiment is directed to the example in which, as illustrated in FIG. 49, the width w26 of the first opening part 153a of the upper vapor channel recess 153 is equal to the width w27 of the second opening part 154a of the lower vapor channel recess 154. However, the present disclosure is not limited to such a configuration. For example, as illustrated in FIG. 56A, the width w27 of the second opening part 154a may be greater than the width w26 of the first opening part 153a. In this case, the lower vapor channel recess 154 can be increased in channel cross-sectional area. This can improve the capacity with which the vapor chamber 1 transports the working vapor 2a. Since the width w26 of the first opening part 153a can be made less than the width w27 of the second opening part 154a, more first liquid channel parts 160 can be provided in the first body face 131a of the sheet body 131. This can improve the capacity with which the vapor chamber 1 transports the working liquid 2b. As described above, the first modification therefore allows for improved heat transport efficiency of the vapor chamber 1.

Alternatively, as illustrated in FIG. 56B, the width w27 of the second opening part 154a may be less than the width w26 of the first opening part 153a. In this case, the lower vapor channel recess 154 can be decreased in channel cross-sectional area. This makes it possible to improve the mechanical strength of the sheet body 131. Further, the lower-sheet support 136 can be extended toward the inside of the lower vapor channel recess 154. This makes it possible to resist the bending stress that the lower sheet 110 experiences when subjected to an external force, and consequently reduce a deformation of the lower sheet 110 that causes the lower sheet 110 to extend into the lower vapor channel recess 154.

### Second Modification

The foregoing description of the sixth embodiment is directed to the example in which, as illustrated in FIG. 49, the first opening part 153a of the upper vapor channel recess 153 overlaps the second opening part 154a of the lower vapor channel recess 154 in plan view. In this case, the first opening part 153a and the second opening part 154a are not offset relative to each other in the Y-direction. However, the present disclosure is not limited to such a configuration. For example, as illustrated in FIG. 56C, the first opening part 153a and the second opening part 154a may be offset relative to each other in the Y-direction. As illustrated in FIG. 56C, the first opening part 153a is located offset to one side relative to the second opening part 154a. In the example illustrated in FIG. 56C, the first opening part 153a of the first vapor passage 151 is offset to the right relative to the second opening part 154a of the first vapor passage 151. The first opening part 153a of the second vapor passage 152 adjacent to the first vapor passage 151 is offset to the right relative to the second opening part 154a of the second vapor passage 152. A dimension 6 denotes the amount of offset between the first opening part 153a and the second opening part 154a. In the example illustrated in FIG. 56C, the width w26 of the first opening part 153a may be equal to the width w27 of the second opening part 154a.

According to the second modification, the first opening part 153a and the second opening part 154a can be offset relative to each other. This configuration makes it possible to improve the mechanical strength of the sheet body 131. More specifically, this configuration makes it possible to reduce overlap between the first opening part 153a and the second opening part 154a in plan view, and consequently reduce the extent of area in the Y-direction where the material constituting the sheet body 131 does not exist. This makes it possible to reduce a decrease in mechanical strength resulting from the presence of the upper vapor channel recess 153 and the lower vapor channel recess 154. The sheet body 131 can be thus improved in mechanical strength.

Although the direction of offset of the first opening part 153a relative to the second opening part 154a may be the same between the vapor passages 151 and 152, the above-mentioned direction of offset may be different between the vapor passages 151 and 152. For example, as illustrated in FIG. 56D, for the first vapor passage 151, the above-mentioned direction of offset is rightward in FIG. 56D. For the second vapor passage 152 adjacent to the first vapor passage 151, the above-mentioned direction of offset is leftward in FIG. 56D. As illustrated in FIG. 56D, the second vapor passage 152 for which the above-mentioned direction of offset is rightward, and the second vapor passage 152 for which the above-mentioned direction of offset is leftward may coexist. This configuration can reduce occurrence of directionality in mechanical strength, and consequently can improve the mechanical strength of the sheet body 131. Alternatively, as illustrated in FIG. 56E, there may exist the vapor passage 151 or 152 for which the first opening part 153a and the second opening part 154a are not offset relative to each other in the Y-direction. This configuration as well can reduce occurrence of directionality in mechanical strength, and consequently can improve the mechanical strength of the sheet body 131.

### Third Modification

The foregoing description of the sixth embodiment is directed to the example in which, in cross-sectional view, both the upper vapor channel recess 153 and the lower vapor channel recess 154 increase in width with increasing distance from their respective opening parts 153a and 154a toward the inner part 157 as illustrated in FIG. 49. However, the present disclosure is not limited to such a configuration. For example, in cross-sectional view, one of the upper vapor channel recess 153 and the lower vapor channel recess 154 may increase in width with increasing distance from the opening part 153a or 154a toward the inner part 157. The other one of the upper vapor channel recess 153 and the lower vapor channel recess 154 may decrease in width with increasing distance from the opening part 153a or 154a toward the inner part 157.

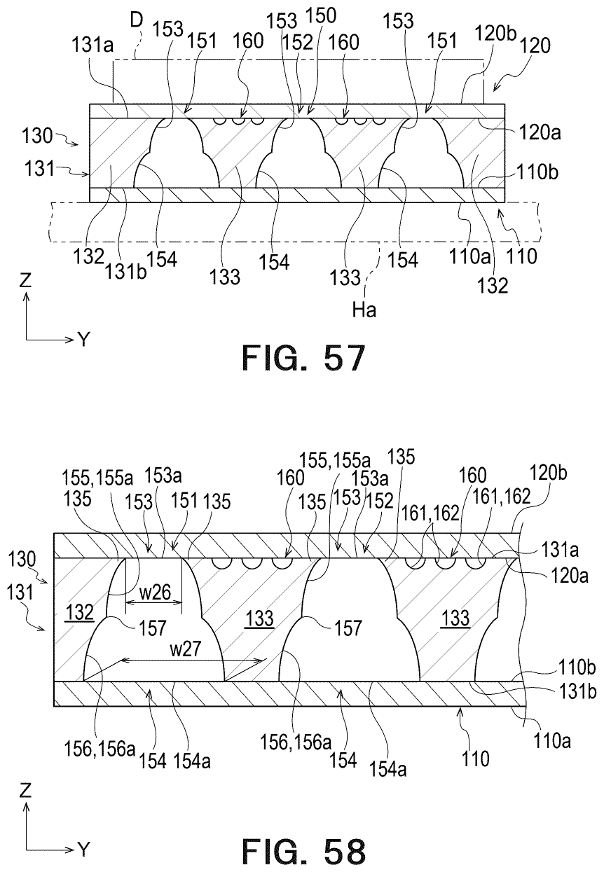

In the example illustrated in FIGS. 57 and 58, in cross-sectional view, the upper vapor channel recess 153 increases in width with increasing distance from the first opening part 153a toward the inner part 157. In contrast, the lower vapor channel recess 154 decreases in width with increasing distance from the second opening part 154a toward the inner part 157. The vapor channel part 150 is thus widest at the second opening part 154a. The width w27 of the second opening part 154a is greater than the width w26 of the first opening part 153a.

In the example illustrated in FIGS. 57 and 58, the first boundary edge 155a of the upper vapor channel recess 153 has a curved shape. The first boundary edge 155a is curved toward the outside of the upper vapor channel recess 153. Likewise, the second boundary edge 156a of the lower vapor channel recess 154 has a curved shape. The second boundary edge 156a is curved toward the outside of the upper vapor channel recess 153. The first boundary edge 155a and the second boundary edge 156a are connected at the inner part 157.

According to the third modification as well, in cross-sectional view, the upper vapor channel recess 153 increases in width with increasing distance from the first opening part 153a toward the inner part 157. Due to the configuration mentioned above, the sheet body 131 of the body sheet 130 is provided with the upper-sheet support 135, which supports the upper sheet 120. This can reduce collapse of a portion of the upper vapor channel recess 153, and the consequent decrease in the channel cross-sectional area of the upper vapor channel recess 153. This in turn can reduce deterioration of the capacity with which the vapor chamber 1 transports the working vapor 2a, and consequently can reduce performance deterioration of the vapor chamber 1.

According to the third modification, the lower vapor channel recess 154 can be increased in channel cross-sectional area. This can improve the capacity with which the vapor chamber 1 transports the working vapor 2a. In contrast, the upper vapor channel recess 153 can be decreased in channel cross-sectional area. More first liquid channel parts 160 can be thus provided in the first body face 131a of the sheet body 131. This can improve the capacity with which the vapor chamber 1 transports the working liquid 2b. As described above, the third modification therefore allows for improved heat transport efficiency of the vapor chamber 1.

### Fourth Modification

In the sixth embodiment mentioned above, the vapor chamber 1 may be bent. The vapor chamber 1 may include a bend part BP where the lower sheet 110, the upper sheet 120, and the body sheet 130 are bent.

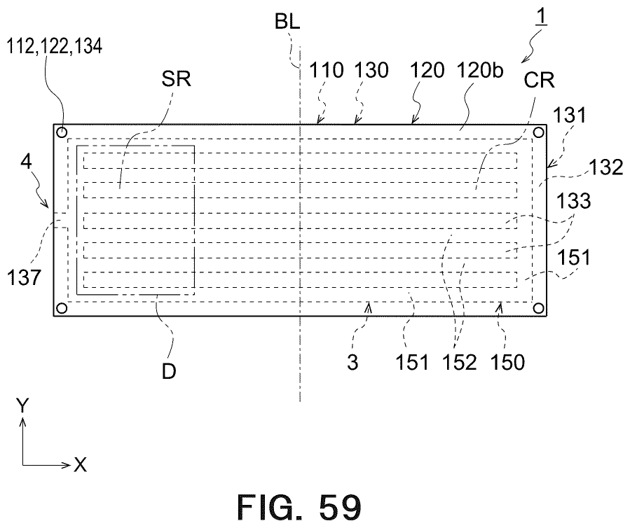

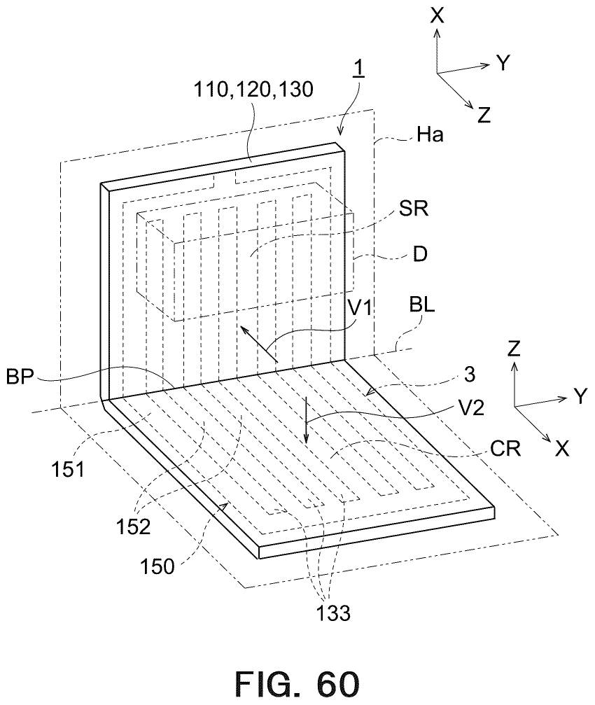

For example, the bend part BP may be formed by bending the vapor chamber 1 along the bend line BL illustrated in FIG. 59. In plan view, the bend line BL may extend in a direction crossing the X-direction, or may extend in the Y-direction orthogonal to the X-direction. In the example illustrated in FIG. 59, the bend line BL is provided in the central portion of the vapor chamber 1 in the X-direction so as to extend in the Y-direction. Bending the vapor chamber 1 along the bend line BL makes it possible to obtain the vapor chamber 1 as illustrated in FIG. 60 that has the bend part BP where the lower sheet 110, the upper sheet 120, and the body sheet 130 are bent. The bend line BL may extend in a direction inclined relative to the X-direction in plan view as illustrated in FIGS. 18 and 19.

In the example illustrated in FIG. 60, the vapor chamber 1 is bent in such a way that the upper sheet 120 is located at the inner side of the bend, with the lower sheet 110 located at the outer side of the bend. The bend part BP is a region including the bend line BL and having a predetermined width in the X-direction. The bend angle at the bend part BP may be any angle. In the example illustrated in FIG. 60, the bend angle is 90 degrees, that is, a right angle. The vapor chamber 1 is thus bent in a substantially L-shape. However, the present disclosure is not limited to such a configuration. In one alternative example, the vapor chamber 1 may be bent into a curve such that the vapor chamber 1 has a U-shaped cross-section. In another alternative example, the vapor chamber 1 may be bent a plurality of times such that the vapor chamber 1 has, for example, a rectangular U-shaped cross-section. Bending the vapor chamber 1 as described above allows for increased flexibility in where the vapor chamber 1 can be placed within the housing H.

The vapor chamber 1 having the bend part BP mentioned above may be produced by performing a bending step after a sealing step in manufacturing the vapor chamber 1. For example, in the bending step, the lower sheet 110, the upper sheet 120, and the body sheet 130 may be bent along the bend line BL.

In the vapor chamber 1 configured as described above, the upper vapor channel recess 153 and the lower vapor channel recess 154 mentioned above are disposed at least in the bend part BP. The upper vapor channel recess 153 and the lower vapor channel recess 154 may be disposed so as to cross the bend part BP. In the illustrated example, the bend part BP extends in the Y-direction, and the upper vapor channel recess 153 and the lower vapor channel recess 154 extend in the X-direction across the bend part BP. As with the vapor chamber 1 illustrated in FIG. 4, for a region located on each side in the X-direction of the bend part BP of the bent vapor chamber 1 illustrated in FIG. 60, a plan view of the region corresponds to a view seen in a direction represented by the arrow V1 or V2. In cross-sectional view taken at the bend part BP, as illustrated in FIGS. 45 and 49, the upper vapor channel recess 153 may increase in width with increasing distance from the first opening part 153a toward the inner part 157. The lower vapor channel recess 154 may increase in width with increasing distance from the second opening part 154a toward the inner part 157.

Upon bending of the vapor chamber 1, the upper sheet 120 located at the inner side of the bend may deform under compressive stress in the bend part BP so as to extend into the upper vapor channel recess 153. The lower sheet 110 located at the outer side of the bend may deform under tensile stress in the bend part BP so as to extend into the lower vapor channel recess 154. A possible consequence of such deformation is that the upper vapor channel recess 153 and the lower vapor channel recess 154 may partially collapse, which may cause the upper vapor channel recess 153 and the lower vapor channel recess 154 to decrease in channel cross-sectional area.

In this regard, according to the fourth modification, in cross-sectional view taken at the bend part BP, the upper vapor channel recess 153 increases in width with increasing distance from the first opening part 153a toward the inner part 157. Due to the configuration mentioned above, the sheet body 131 of the body sheet 130 is provided with the upper-sheet support 135, which supports the upper sheet 120. This configuration makes it possible to resist the stress that the upper sheet 120 experiences upon bending, and consequently reduce a deformation of the upper sheet 120 that causes the upper sheet 120 to extend into the upper vapor channel recess 153. This can reduce collapse of a portion of the upper vapor channel recess 153, and consequently can reduce a decrease in the channel cross-sectional area of the upper vapor channel recess 153. This in turn can reduce deterioration of the capacity with which the vapor chamber 1 transports the working vapor 2a, and consequently can reduce performance deterioration of the vapor chamber 1.

According to the fourth modification, in cross-sectional view taken at the bend part BP, the lower vapor channel recess 154 increases in width with increasing distance from the second opening part 154a toward the inner part 157. Due to the configuration mentioned above, the sheet body 131 of the body sheet 130 is provided with the lower-sheet support 136, which supports the lower sheet 110. This configuration makes it possible to resist the stress that the lower sheet 110 experiences upon bending, and consequently reduce a deformation of the lower sheet 110 that causes the lower sheet 110 to extend into the lower vapor channel recess 154. This can reduce collapse of a portion of the lower vapor channel recess 154, and consequently can reduce a decrease in the channel cross-sectional area of the lower vapor channel recess 154. This in turn can further reduce deterioration of the capacity with which the vapor chamber 1 transports the working vapor 2a, and consequently can further reduce performance deterioration of the vapor chamber 1.

At a location different from the bend part BP, the upper vapor channel recess 153 and the lower vapor channel recess 154 may have any shape. For example, in cross-sectional view taken at a location different from the bend part BP as well, the upper vapor channel recess 153 may likewise increase in width with increasing distance from the first opening part 153a toward the inner part 157 as illustrated in FIGS. 45 and 49. The lower vapor channel recess 154 may increase in width with increasing distance from the second opening part 154a toward the inner part 157.

In an alternative example, in cross-sectional view taken at a location different from the bend part BP, the upper vapor channel recess 153 may increase in width with increasing distance from the first opening part 153a toward the inner part 157 as illustrated in FIGS. 57 and 58. The lower vapor channel recess 154 may decrease in width with increasing distance from the second opening part 154a toward the inner part 157.

The configuration mentioned above as well can reduce partial collapse of the upper vapor channel recess 153 and the lower vapor channel recess 154 that are located in the bend part BP. This can reduce a decrease in the channel cross-sectional area of each of the upper vapor channel recess 153 and the lower vapor channel recess 154. At a location different from the bend part BP, the configuration mentioned above makes it possible to improve the capacity with which the vapor chamber 1 transports the working vapor 2a and the working liquid 2b. The configuration mentioned above therefore makes it possible to increase the heat transport efficiency of the vapor chamber 1 while reducing performance deterioration of the vapor chamber 1 caused by bending of the vapor chamber 1.

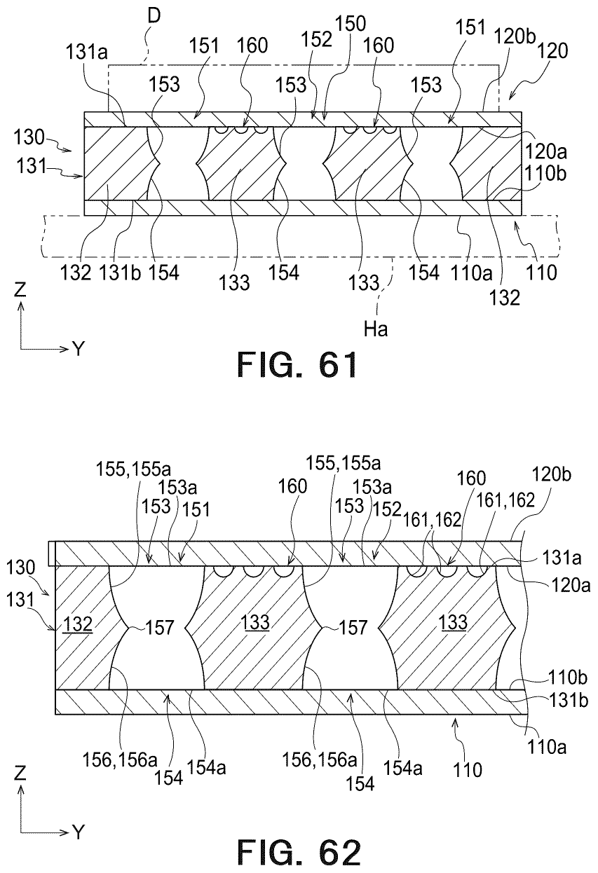

In another alternative example, in cross-sectional view taken at a location different from the bend part BP, the upper vapor channel recess 153 may decrease in width with increasing distance from the first opening part 153a toward the inner part 157 as illustrated in FIGS. 61 and 62. The lower vapor channel recess 154 may decrease in width with increasing distance from the second opening part 154a toward the inner part 157.

In the example illustrated in FIGS. 61 and 62, the first boundary edge 155a of the upper vapor channel recess 153 has a curved shape. The first boundary edge 155a is curved toward the outside of the upper vapor channel recess 153. Likewise, the second boundary edge 156a of the lower vapor channel recess 154 has a curved shape. The second boundary edge 156a is curved toward the outside of the upper vapor channel recess 153. The first boundary edge 155a and the second boundary edge 156a are connected at the inner part 157. The connection between the first boundary edge 155a and the second boundary edge 156a results in formation of the inner part 157 that protrudes toward the inside of the vapor channel part 150. In the example illustrated in FIGS. 61 and 62, the vapor passages 151 and 152 are narrowest at the inner part 157.

The configuration mentioned above as well can reduce partial collapse of the upper vapor channel recess 153 and the lower vapor channel recess 154 that are located in the bend part BP. This can reduce a decrease in the channel cross-sectional area of each of the upper vapor channel recess 153 and the lower vapor channel recess 154. At a location different from the bend part BP, the configuration mentioned above makes it possible to increase the capillary action exerted by a channel corner of the upper vapor channel recess 153 that is similar to the channel corner 56 illustrated in FIG. 11. More specifically, the first boundary edge 155a and the first upper-sheet face 120a can be made to form an angle less than 90 degrees, and the channel corner can be thus made to have an acute angle. The angle formed by the first boundary edge 155a and the first upper-sheet face 120a may be an angle formed by the following tangents: a tangent to the first boundary edge 155a that passes through the point of intersection between the first boundary edge 155a and the first upper-sheet face 120a; and a tangent to the first upper-sheet face 120a that passes through the above-mentioned point of intersection. Likewise, the configuration mentioned above makes it possible to increase the capillary action exerted by a channel corner of the lower vapor channel recess 154 that is similar to the channel corner 55 illustrated in FIG. 11. More specifically, the second boundary edge 156a and the second lower-sheet face 110b can be made to form an angle less than 90 degrees, that is, an acute angle. This allows for increased capillary action on the working liquid 2b adhering on the respective wall faces 155 and 156 of the vapor channel recesses 153 and 154. The working liquid 2b adhering on the wall faces 155 and 156 is thus allowed to smoothly move to the main flow groove 161 of the first liquid channel part 160. This can improve the capacity with which the vapor chamber 1 transports the working liquid 2b. The configuration mentioned above therefore makes it possible to increase the heat transport efficiency of the vapor chamber 1 while reducing performance deterioration of the vapor chamber 1 caused by bending of the vapor chamber 1.

In an alternative configuration, in cross-sectional view taken at the bend part BP, the upper vapor channel recess 153 may increase in width with increasing distance from the first opening part 153a toward the inner part 157 as illustrated in FIGS. 57 and 58. The lower vapor channel recess 154 may decrease in width with increasing distance from the second opening part 154a toward the inner part 157. As mentioned above, the upper sheet 120 may be located at the inner side of the bend. Alternatively, however, the lower sheet 110 may be located at the inner side of the bend.

With the configuration mentioned above as well, the sheet body 131 located at the bend part BP is provided with the upper-sheet support 135, which supports the upper sheet 120. The resulting ability to resist the stress that the upper sheet 120 experiences upon bending can reduce a deformation of the upper sheet 120 that causes the upper sheet 120 to extend into the upper vapor channel recess 153. This can reduce collapse of a portion of the upper vapor channel recess 153, and consequently can reduce a decrease in the channel cross-sectional area of the upper vapor channel recess 153. In the bend part BP, the lower vapor channel recess 154 can be increased in channel cross-sectional area. This can improve the capacity with which the vapor chamber 1 transports the working liquid 2b. The configuration mentioned above therefore makes it possible to increase the heat transport efficiency of the vapor chamber 1 while reducing performance deterioration of the vapor chamber 1 caused by bending of the vapor chamber 1. Further, the configuration mentioned above makes it possible to reduce a deformation of the upper sheet 120 that causes the upper sheet 120 to extend into the upper vapor channel recess 153. This can reduce the risk that the opening defined by the communication groove 165 in the vapor passages 151 and 152 may be blocked by the upper sheet 120. This means that if the working liquid 2b evaporates in the first liquid channel part 160 located in the bend part BP, the evaporated working vapor 2a is allowed to smoothly diffuse to the vapor passages 151 and 152.

The width w27 of the second opening part 154a can be made greater than the width w26 of the first opening part 153a. Consequently, a portion of the lower sheet 110 that overlaps the lower vapor channel recess 154 is allowed to deform so as to extend into the lower vapor channel recess 154. This makes it possible to increase the capillary action exerted by a channel corner of the lower vapor channel recess 154 that is similar to the channel corner 55 illustrated in FIG. 11. The resulting ability to reduce stagnation of the working liquid 2b in the lower vapor channel recess 154 can reduce impediment to the flow of the working vapor 2a. This means that if the first liquid channel part 160 is provided in the second body face 131b of the sheet body 131, the working liquid 2b is allowed to quickly move to the first liquid channel part 160.

If the vapor channel recesses 153 and 154 are configured as illustrated in FIGS. 57 and 58 in cross-sectional view taken at the bend part BP, the vapor channel recesses 153 and 154 may be configured as illustrated in FIGS. 57 and 58 in cross-sectional view taken at a location different from the bend part BP. Alternatively, the vapor channel recesses 153 and 154 may be configured as illustrated in FIGS. 61 and 62 in cross-sectional view taken at a location different from the bend part BP. The upper vapor channel recess 153 may decrease in width with increasing distance from the first opening part 153a toward the inner part 157. The lower vapor channel recess 154 may decrease in width with increasing distance from the second opening part 154a toward the inner part 157.

In this case, at a location different from the bend part BP, the angle formed by the first boundary edge 155a and the first upper-sheet face 120a, and the angle formed by the second boundary edge 156a and the second lower-sheet face 110b can be made less than 90 degrees, that is, an acute angle. This allows for increased capillary action on the working liquid 2b adhering on the respective wall faces 155 and 156 of the vapor channel recesses 153 and 154. The working liquid 2b adhering on the wall faces 155 and 156 is thus allowed to smoothly move to the main flow groove 161 of the first liquid channel part 160. This can improve the capacity with which the vapor chamber 1 transports the working liquid 2b.

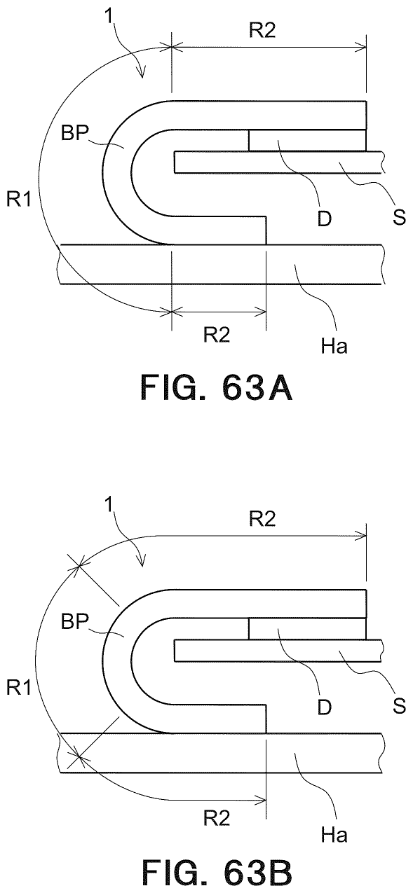

Further, as described above, the bend part BP is a region having a predetermined width in the X-direction. For example, as illustrated in FIGS. 63A and 63B, the bend part BP may have the shape of a circular arc. This configuration can reduce impediment to the flow of the working vapor 2a in the bend part BP. The bend part BP may have the shape of a quarter-circular arc as in the case of the vapor chamber 1 illustrated in each of FIGS. 2 and 15. Alternatively, the bend part BP may have the shape of a semi-circular arc as in the case of the vapor chamber 1 illustrated in FIG. 3. The circular arc of the bend part BP may form any angle. As illustrated in FIGS. 63A and 63B, in a region located on each side of the bend part BP in the X-direction, the vapor chamber 1 may have a flat shape. The region having a flat shape corresponds to a region R2 (described later) illustrated in FIG. 63A.

As described above, the cross-sectional shape that the vapor channel recesses 153 and 154 have in the bend part BP, and the cross-sectional shape that the vapor channel recesses 153 and 154 have at a location different from the bend part BP may be different. In FIGS. 63A and 63B, R1 represents a region where the vapor channel recesses 153 and 154 have the cross-sectional shape illustrated in each of FIGS. 45 and 49, and R2 represents a region where the vapor channel recesses 153 and 154 have the cross-sectional shape illustrated in each of FIGS. 57 and 58.

As illustrated in FIG. 63A, the region R1 may exist over the entire bend part BP. This configuration makes it possible to, over the entire bend part BP, reduce a deformation of the upper sheet 120 that causes the upper sheet 120 to extend into the upper vapor channel recess 153, and also reduce a deformation of the lower sheet 110 that causes the lower sheet 110 to extend into the lower vapor channel recess 154.

Alternatively, as illustrated in FIG. 63B, the region R1 may exist in a portion of the bend part BP, and the region R2 may exist in the remainder of the bend part BP. This configuration as well makes it possible to, in the bend part, reduce a deformation of the upper sheet 120 that causes the upper sheet 120 to extend into the upper vapor channel recess 153, and also reduce a deformation of the lower sheet 110 that causes the lower sheet 110 to extend into the lower vapor channel recess 154. For example, the region R1 may exist in the central portion of the bend part BP, and the region R2 may exist on each side of the region R1 in the X-direction. This configuration makes it possible to, in the central portion of the bend part BP where bending-induced stress tends to concentrate, reduce a deformation of the upper sheet 120 that causes the upper sheet 120 to extend into the upper vapor channel recess 153, and also reduce a deformation of the lower sheet 110 that causes the lower sheet 110 to extend into the lower vapor channel recess 154.

At the boundary between the region R1 and the region R2, a step may occur in the respective wall faces 155 and 156 of the vapor channel recesses 153 and 154. In this case, the number of such steps may be one, or may be two or more. That is, any number of such steps may exist. Alternatively, the wall faces 155 and 156 may be configured in such a way that no such step is present. For example, the respective wall faces 155 and 156 of the vapor channel recesses 153 and 154 in the region R1, and the respective wall faces 155 and 156 of the vapor channel recesses 153 and 154 in the region R2 may be smoothly connected in such a way that the vapor channel recesses 153 and 154 gradually change in cross-sectional shape.

### Fifth Modification

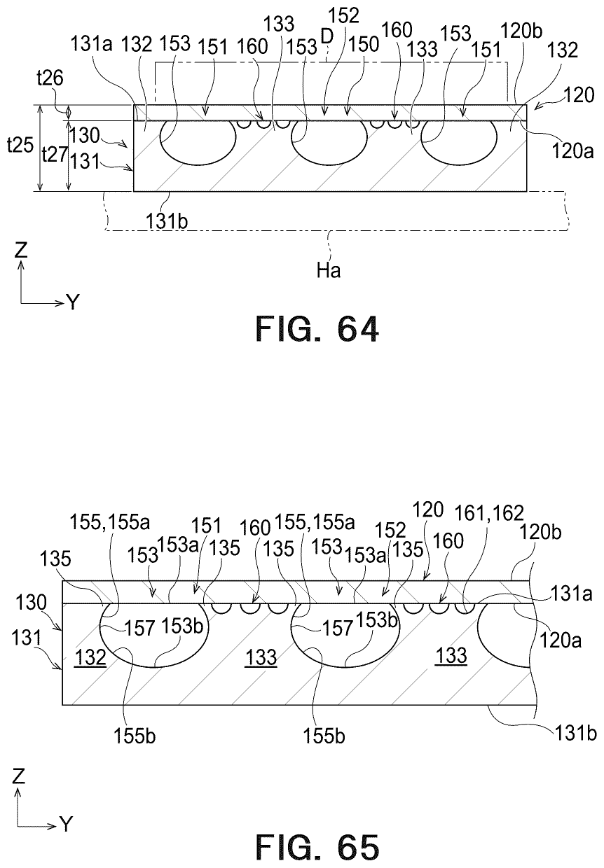

The foregoing description of the sixth embodiment is directed to the example in which the vapor chamber 1 is made up of the lower sheet 110, the upper sheet 120, and the body sheet 130 as illustrated in FIG. 45. However, the present disclosure is not limited to such a configuration. For example, as illustrated in FIGS. 64 and 65, the vapor chamber 1 may be made up of the upper sheet 120, and the body sheet 130.

In the example illustrated in FIGS. 64 and 65, the vapor chamber 1 includes the upper sheet 120 and the body sheet 130, but does not include the lower sheet 110. In this case, the housing component Ha may be mounted to the second body face 131b of the body sheet 130. The heat of the working vapor 2a is transferred from the body sheet 130 to the housing component Ha.

In the example illustrated in FIGS. 64 and 65, although the vapor channel part 150 is disposed in the first body face 131a, the vapor channel part 150 does not extend all the way to the second body face 131b. The vapor channel part 150 thus does not penetrate through the sheet body 131 of the body sheet 130. The first vapor passage 151 and the second vapor passage 152 of the vapor channel part 150 are each defined by the upper vapor channel recess 153, with no lower vapor channel recess 154 provided in the body sheet 130.

In the example illustrated in FIGS. 64 and 65, the upper vapor channel recess 153 includes the first opening part 153a, the inner part 157, and a bottom part 153b. The inner part 157 is located closer to the second body face 131b than is the first opening part 153a. In FIG. 65, the inner part 157 is located below the first opening part 153a. The bottom part 153b is located even closer to the second body face 131b than is the inner part 157. In FIG. 65, the bottom part 153b is located below the inner part 157. The first opening part 153a is provided at the first body face 131a. The inner part 157 is a part of the upper vapor channel recess 153 where the upper vapor channel recess 153 is widest as seen in cross-sectional view illustrated in FIG. 65. The bottom part 153b may be located at the lower end of the upper vapor channel recess 153.

In the example illustrated in FIGS. 64 and 65, in cross-sectional view, the upper vapor channel recess 153 increases in width with increasing distance from the first opening part 153a toward the inner part 157. Due to this configuration, the sheet body 131 of the body sheet 130 is provided with the upper-sheet support 135. In cross-sectional view, the upper vapor channel recess 153 decreases in width with increasing distance from the inner part 157 toward the bottom part 153b.

In the example illustrated in FIGS. 64 and 65, in cross-sectional view, the wall face 155 of the upper vapor channel recess 153 includes the first boundary edge 155a, and a second boundary edge 155b. The first boundary edge 155a extends from the first opening part 153a to the inner part 157. The second boundary edge 155b extends from the inner part 157 to the bottom part 153b. The first boundary edge 155a has a curved shape. The first boundary edge 155a is curved toward the outside of the upper vapor channel recess 153. The second boundary edge 155b likewise has a curved shape. The second boundary edge 155b is curved toward the outside of the upper vapor channel recess 153. The first boundary edge 155a and the second boundary edge 155b may be smoothly connected with each other in a seamless manner at the inner part 157. Two second boundary edges 155b that face each other may be likewise smoothly connected with each other in a seamless manner at the bottom part 153b.

Although not illustrated, the first upper-sheet face 120a of the upper sheet 120 may be provided with the vapor channel part 150. In this case, the vapor channel part 150 in the upper sheet 120 may be positioned to face the vapor channel part 150 in the body sheet 130. The first upper-sheet face 120a of the upper sheet 120 may be provided with the first liquid channel part 160. In this case, the first liquid channel part 160 in the upper sheet 120 may be positioned to face the first liquid channel part 160 in the body sheet 130.

The vapor chamber 1 illustrated in FIG. 64 may have a thickness t25 of, for example, 100 μm to 1000 μm. The upper sheet 120 illustrated in FIG. 64 may have a thickness t26 of, for example, 6 μm to 200 μm. The body sheet 130 illustrated in FIG. 64 may have a thickness t27 of, for example, 50 μm to 800 μm.

According to the fifth modification as well, in cross-sectional view, the upper vapor channel recess 153 increases in width with increasing distance from the first opening part 153a toward the inner part 157. Due to this configuration, the sheet body 131 of the body sheet 130 is provided with the upper-sheet support 135, which supports the upper sheet 120. This can reduce collapse of a portion of the upper vapor channel recess 153, and consequently can reduce a decrease in the channel cross-sectional area of the upper vapor channel recess 153. This in turn can reduce deterioration of the capacity with which the vapor chamber 1 transports the working vapor 2a, and consequently can reduce performance deterioration of the vapor chamber 1.

According to the fifth modification, the vapor chamber 1 is made up of the upper sheet 120, and the body sheet 130. This configuration can further reduce the thickness of the vapor chamber 1.

### Sixth Modification

In the fifth embodiment mentioned above, the vapor chamber 1 may be bent as in the case of the fourth modification mentioned above. The vapor chamber 1 may include the bend part BP where the upper sheet 120 and the body sheet 130 are bent.

In the vapor chamber 1 configured as described above, the upper vapor channel recess 153 and the lower vapor channel recess 154 illustrated in FIGS. 64 and 65 may be disposed at least in the bend part BP. For example, the upper vapor channel recess 153 and the lower vapor channel recess 154 may be disposed so as to cross the bend part BP.

According to the sixth modification as well, in cross-sectional view taken at the bend part BP, the upper vapor channel recess 153 increases in width with increasing distance from the first opening part 153a toward the inner part 157. Due to the configuration mentioned above, the sheet body 131 of the body sheet 130 is provided with the upper-sheet support 135, which supports the upper sheet 120. This configuration makes it possible to resist the stress that the upper sheet 120 experiences upon bending, and consequently reduce a deformation of the upper sheet 120 that causes the upper sheet 120 to extend into the upper vapor channel recess 153. This can reduce collapse of a portion of the upper vapor channel recess 153, and consequently can reduce a decrease in the channel cross-sectional area of the upper vapor channel recess 153. This in turn can reduce deterioration of the capacity with which the vapor chamber 1 transports the working vapor 2a, and consequently can reduce performance deterioration of the vapor chamber 1.

As with the fourth modification previously mentioned, the upper vapor channel recess 153 may have any shape at a location different from the bend part BP. In one example, in cross-sectional view taken at a location different from the bend part BP as well, the upper vapor channel recess 153 may likewise increase in width with increasing distance from the first opening part 153a toward the inner part 157 as illustrated in FIGS. 53 and 65. In another example (not illustrated), in cross-sectional view taken at a location different from the bend part BP, the upper vapor channel recess 153 may decrease in width with increasing distance from the first opening part 153a toward the inner part 157.

The present disclosure is not limited to the foregoing embodiments and modifications as specifically described. Rather, the present disclosure can in practice be implemented with modifications or changes to its constituent elements without departing from the scope and sprit of the disclosure. Various inventions can be made by suitable combinations of a plurality of constituent elements disclosed in the foregoing embodiments and modifications. Of all the constituent elements described in the foregoing embodiments and modifications, some constituent elements may be omitted.

1-25. (canceled)

26. A vapor chamber in which a working fluid is sealed, the vapor chamber comprising:
a body sheet including
a first body face,
a second body face opposite from the first body face,
a first-body recess disposed in the first body face; and
a second-body recess disposed in the second body face;
a first sheet that is stacked over the first body face;
a second sheet that is stacked over the second body face, and
a bend part where the body sheet, the first sheet and the second sheet are bent,
wherein the first-body recess includes
a first opening part provided at the first body face, and
an inner part located closer to the second body face than is the first opening part,
wherein the second-body recess includes a second opening part provided at the second body face,
wherein the first-body recess and the second-body recess are disposed at least in the bend part,
wherein the first-body recess and the second-body recess are connected at the inner part and communicate with each other, and
wherein in cross-sectional view taken at the bend part, the first-body recess increases in width with increasing distance from the first opening part toward the inner part and the second-body recess increases in width with increasing distance from the second opening part toward the inner part.

27. The vapor chamber according to claim 26,
wherein a capillary structure is disposed in the first body face, and
wherein a width of the second opening part is larger than a width of the first opening part.

28. The vapor chamber according to claim 26,
wherein a width of the second opening part is smaller than a width of the first opening part.

29. The vapor chamber according to claim 26,
wherein in cross-sectional view taken at the bend part, the first opening and the second opening are offset relative to each other.

30. The vapor chamber according to claim 26,
wherein the first-body recess is disposed also at a location different from the bend part, and
wherein in cross-sectional view taken at the location different from the bend part, the first-body recess increases in width with increasing distance from the first opening part toward the inner part, and the second-body recess decreases in width with increasing distance from the second opening part toward the inner part.

31. The vapor chamber according to claim 26,
wherein the first-body recess is disposed also at a location different from the bend part, and
wherein in cross-sectional view taken at the location different from the bend part, the first-body recess decreases in width with increasing distance from the first opening part toward the inner part, and the second-body recess decreases in width with increasing distance from the second opening part toward the inner part.

32. An electronic apparatus comprising:
a device; and
the vapor chamber according to claim 26, the vapor chamber being in thermal contact with the device.

33. A body sheet for a vapor chamber in which a working fluid is sealed, the body sheet comprising:
a first body face,
a second body face opposite from the first body face,
a first-body recess disposed in the first body face; and
a second-body recess disposed in the second body face;
wherein the first-body recess includes
a first opening part provided at the first body face, and
an inner part located closer to the second body face than is the first opening part,
wherein the second-body recess includes a second opening part provided at the second body face,
wherein the first-body recess and the second-body recess are connected at the inner part and communicate with each other, and
wherein in cross-sectional view, the first-body recess increases in width with increasing distance from the first opening part toward the inner part and the second-body recess increases in width with increasing distance from the second opening part toward the inner part.

34. The body sheet for the vapor chamber according to claim 33,
wherein a capillary structure is disposed in the first body face, and
wherein a width of the second opening part is larger than a width of the first opening part.

35. The body sheet for the vapor chamber according to claim 33,
wherein a width of the second opening part is smaller than a width of the first opening part.

36. The body sheet for the vapor chamber according to claim 33,
wherein in cross-sectional view, the first opening and the second opening are offset relative to each other.

37. A vapor chamber comprising:
the body sheet for the vapor chamber according to claim 33,
a first sheet that is stacked over the first body face; and
a second sheet that is stacked over the second body face.

38. An electronic apparatus comprising:
a device; and
the vapor chamber according to claim 37, the vapor chamber being in thermal contact with the device.

39. A body sheet for a vapor chamber in which a working fluid is sealed, the body sheet comprising:
a first body face,
a second body face opposite from the first body face,
a first-body recess disposed in the first body face; and
wherein the first-body recess includes
a first opening part provided at the first body face,
an inner part located closer to the second body face than is the first opening part, and
a bottom part located closer to the second body face than is the inner part, and
wherein in cross-sectional view, the first-body recess increases in width with increasing distance from the first opening part toward the inner part.

40. The body sheet for the vapor chamber according to claim 39,
wherein a capillary structure is disposed in the first body face.

41. The body sheet for the vapor chamber according to claim 39,
wherein in cross-sectional view, the first-body recess decreases in width with increasing distance from the inner part toward the bottom part.

42. A vapor chamber comprising:
the body sheet for the vapor chamber according to claim 39, and
a first sheet that is stacked over the first body face.

43. An electronic apparatus comprising:
a device; and
the vapor chamber according to claim 42, the vapor chamber being in thermal contact with the device.
